(19) United States
(12) Patent Application Publication
(10) Pub. No.: US 2024/0415005 A1
(43) Pub. Date: Dec. 12, 2024

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Ming Sang, Beijing (CN); Chunliang Zhao, Beijing (CN); Xuechao Tian, Beijing (CN); Liuhuan Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/678,493

(22) Filed: May 30, 2024

(30) Foreign Application Priority Data
May 31, 2023 (CN) 202310635132.0

(51) Int. Cl. H10K 85/30; C07F 15/00; C09K 11/06; H10K 50/11; H10K 101/00

(52) U.S. Cl. CPC H10K 85/346; C07F 15/0086; C09K 11/06; C07B 2200/05; C09K 2211/1044; C09K 2211/185; H10K 50/11; H10K 2101/90

(57) ABSTRACT

Provided are an organic electroluminescent material and device. The organic electroluminescent material is a compound having a structure of Formula 1. The compound has bluer and more saturated luminescence. These novel compounds may be used as light-emitting materials in organic electroluminescent devices and can provide better device performance such as higher current efficiency. Further provided are an organic electroluminescent device and compound composition comprising the compound having the structure of Formula 1.

### CROSS-REFERENCE TO RELATED APPLICATION(S)

This application claims priority to Chinese Patent Application No. 202310635132.0 filed on May 31, 2023, the disclosure of which is incorporated herein by reference in its entirety.

### TECHNICAL FIELD

The present disclosure relates to compounds for organic electronic devices such as organic light-emitting devices. In particular, the present disclosure relates to a compound having a particular substituent, an organic electroluminescent device comprising the compound and a compound composition comprising the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20210284672A1 discloses a metal complex having a structure of the following general formula:

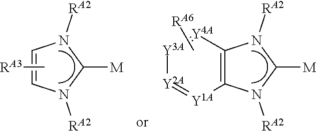

and a use of the metal complex in an organic electroluminescent device, wherein at least one of R^{A1}, R^{A2}, R^{A4}, R^{A5} and R^{A6} comprises a structure represented by

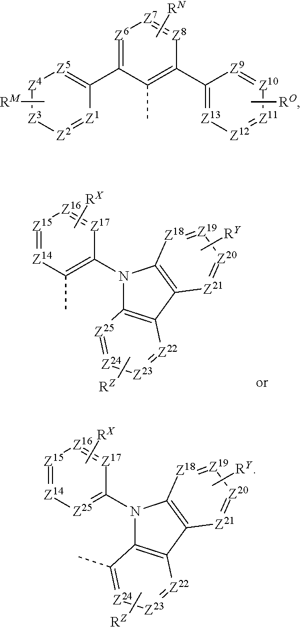

When the compound is selected from the structure

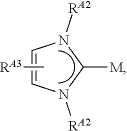

one of R^{A1} and R^{A2}

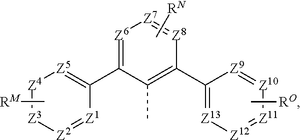

and at least one of R^{M}, R^{N} and R^{O} is selected from deuterium, alkyl, cycloalkyl, heteroalkyl, heterocycloalkyl, aryl, heteroaryl or a combination thereof. Substituents on rings of a specific platinum complex disclosed in this application are all alkyl, phenyl substituents, carbazolyl substituents, etc., for example, the following specific compounds are disclosed;

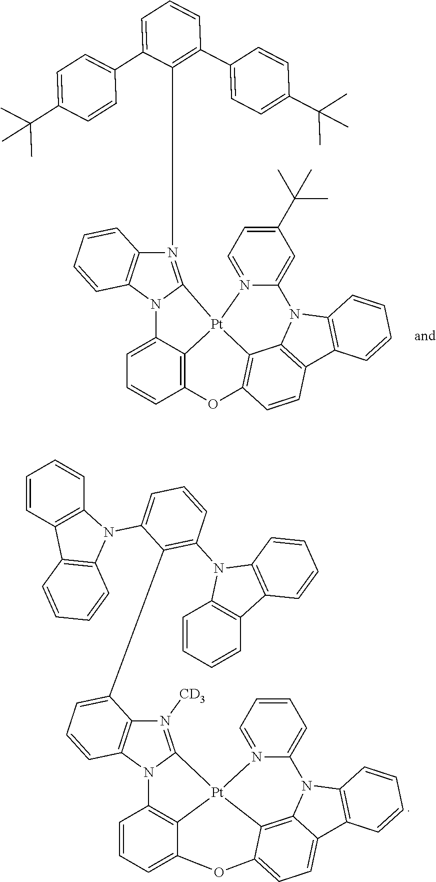

However, neither a compound with other substituents in the platinum complex nor a use of the compound in an organic electroluminescent device is disclosed and taught.

US20210359227A1 discloses an organic electroluminescent device, wherein a light-emitting guest metal material has the following general formula:

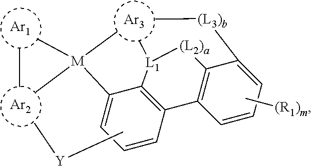

wherein Ar₁ to Ar₃ each represent substituted or unsubstituted aryl having 6 to 30 ring carbon atoms or substituted or unsubstituted heteroaryl having 2 to 30 ring carbon atoms, Ar₁ comprises substituted aryl, and the aryl is substituted with hydrogen, deuterium, alkyl, aryl or another group. Substituents on rings of a specific platinum complex disclosed in this application are all alkyl, cycloalkyl, boron-nitrogen heterocycles or substituted phenyl, for example, the following specific compounds are disclosed:

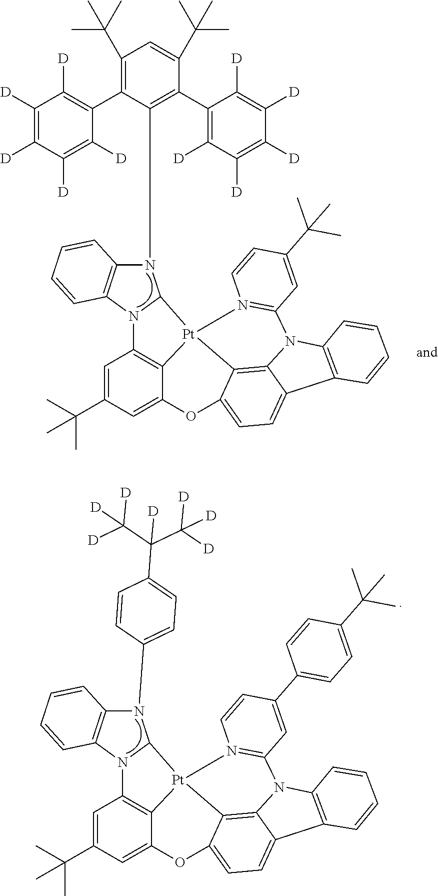

However, neither a compound with other substituents in the platinum complex nor a use of the compound in an organic electroluminescent device is disclosed and taught.

Some blue phosphorescent metal complexes are disclosed in the related art, which comprise mostly studied alkyl, phenyl substituents or carbazolyl substituents. However, neither blue phosphorescent metal complexes with other different substituents nor an effect of the blue phosphorescent metal complexes on the performance of blue phosphorescent light-emitting devices is disclosed in the related art. Moreover, in the study of blue phosphorescent devices, their emitted colors, device efficiency and the like still have certain limitations. As a result, the application potential of such materials deserves deeper research and development.

### SUMMARY

The present disclosure aims to provide a series of compounds each having a structure of Formula 1 to solve at least part of the preceding problems. The compounds have bluer and more saturated luminescence and may be used as light-emitting materials in organic electroluminescent devices. These novel compounds can provide better device performance such as higher current efficiency. These advantages are of great help in improving the level of blue phosphorescent devices.

According to an embodiment of the present disclosure, disclosed is a compound having a structure of Formula 1:

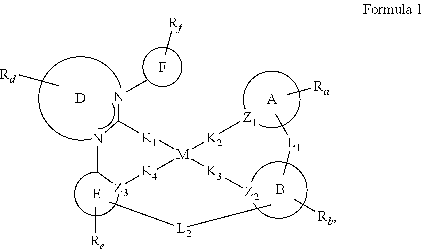

wherein in Formula 1,
the ring A, the ring B, the ring E and the ring F are, at each occurrence identically or differently, selected from an unsaturated carbocyclic ring having 5 to 30 carbon atoms, an unsaturated heterocyclic ring having 3 to 30 carbon atoms or a combination thereof;
the ring D is, at each occurrence identically or differently, selected from an unsaturated heterocyclic ring having 1 to 30 carbon atoms;
the metal M is selected from a metal with a relative atomic mass greater than 40;
L₁ and L₂ are, at each occurrence identically or differently, selected from a single bond, O, S, Se, (SiR′R′)_{y}, PR′, NR′, (CR′R′)_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
K₁ to K₄ are, at each occurrence identically or differently, selected from a single bond, O or S;
Z₁ to Z₃ are, at each occurrence identically or differently, selected from C or N;
Rₐ, R_{b}, R_{d}, Rₑ and R_{f} represent, at each occurrence identically or differently, mono-substitution, multiple substitutions or non-substitution;
at least one of Rₐ, R_{b}, R_{d}, Rₑ and R_{f} is present and is a substituent R, wherein the substituent R has a structure represented by Formula 2:

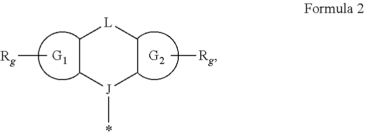

wherein in Formula 2, “*” represents a position where Formula 2 is joined;
R_{g} represents, at each occurrence identically or differently, mono-substitution, multiple substitutions or non-substitution;
the ring G₁ and the ring G₂ are, at each occurrence identically or differently, selected from a carbocyclic ring having 3 to 30 ring atoms, a heterocyclic ring having 3 to 30 ring atoms or a combination thereof,
J is, at each occurrence identically or differently, selected from P, P(O), CR″, SiR″ or GeR″;
L is selected from a single bond, O, S, SO₂, Se, NR″′, CR″′R″′, SiR″′R″′, GeR″′R″′, BR″′, PR″′, P(O)R″′, substituted or unsubstituted alkylene having 2 to 20 carbon atoms, substituted or unsubstituted heteroalkylene having 1 to 20 carbon atoms, substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;
Rₐ, R_{b}, R_{d}, Rₑ, R_{f}, R_{g}, R′, R″ and R″′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents Rₐ, R_{b}, R_{d}, Rₑ, R_{f}, R_{g}, R′, R″, R″′ can be optionally joined to form a ring.

According to an embodiment of the present disclosure, disclosed is an electroluminescent device comprising an anode, a cathode and an organic layer disposed between the anode and the cathode, wherein the organic layer comprises the compound having a structure of Formula 1.

According to an embodiment of the present disclosure, disclosed is a compound composition comprising the compound having a structure of Formula 1.

The present disclosure discloses a series of compounds each having a structure of Formula 1. The compounds have bluer and more saturated luminescence and may be used as light-emitting materials in organic electroluminescent devices. These novel compounds can provide better device performance such as higher current efficiency. These advantages are of great help in improving the level of blue phosphorescent devices.

### BRIEF DESCRIPTION OF DRAWINGS

FIG. 1 is a schematic diagram of an organic light-emitting apparatus that may comprise a compound and a compound composition disclosed herein.

FIG. 2 is a schematic diagram of another organic light-emitting apparatus that may comprise a compound and a compound composition disclosed herein.

### DETAILED DESCRIPTION

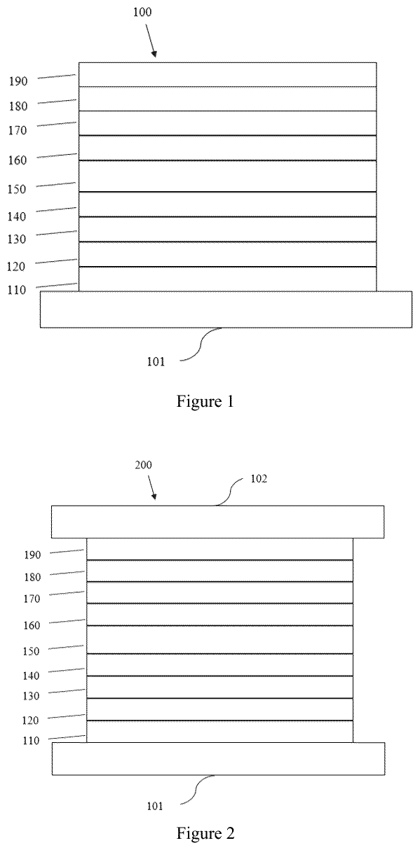

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

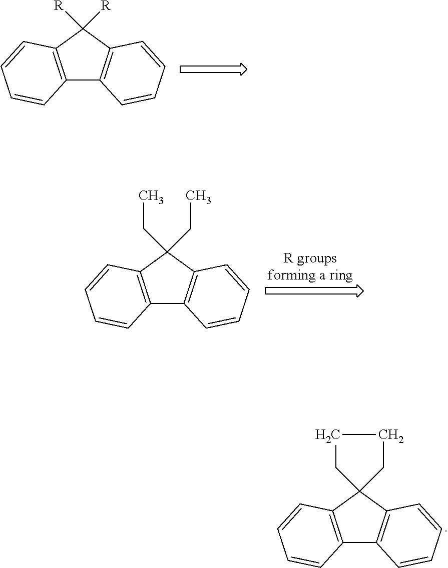

The expression that adjacent substituents can be optionally joined to form a ring is also intended to mean that two substituents bonded to carbon atoms which are directly bonded to each other are joined to each other via a chemical bond to form a ring, which can be exemplified by the following formula:

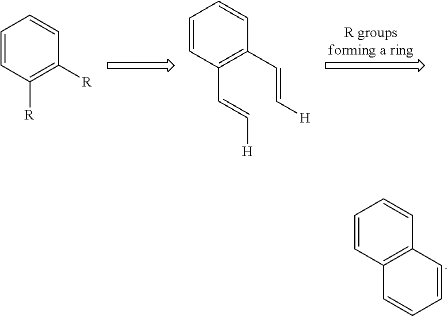

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

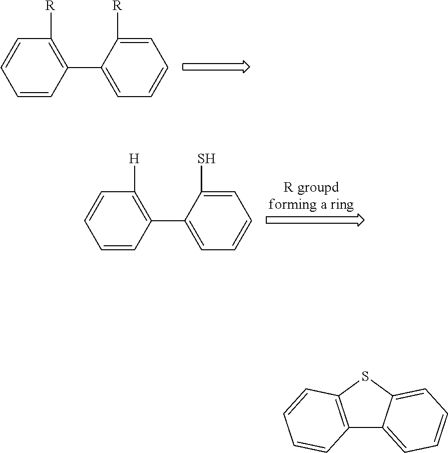

According to an embodiment of the present disclosure, disclosed is a compound having a structure of Formula 1:

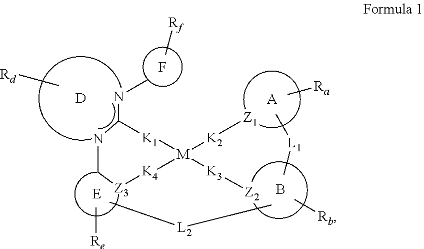

wherein in Formula 1,
the ring A, the ring B, the ring E and the ring F are, at each occurrence identically or differently, selected from an unsaturated carbocyclic ring having 5 to 30 carbon atoms, an unsaturated heterocyclic ring having 3 to 30 carbon atoms or a combination thereof;
the ring D is, at each occurrence identically or differently, selected from an unsaturated heterocyclic ring having 1 to 30 carbon atoms;
the metal M is selected from a metal with a relative atomic mass greater than 40;
L₁ and L₂ are, at each occurrence identically or differently, selected from a single bond, O, S, Se, (SiR′R′)_{y}, PR′, NR′, (CR′R′)_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
K₁ to K₄ are, at each occurrence identically or differently, selected from a single bond, O or S;
Z₁ to Z₃ are, at each occurrence identically or differently, selected from C or N;
Rₐ, R_{b}, R_{d}, Rₑ and R_{f} represent, at each occurrence identically or differently, mono-substitution, multiple substitutions or non-substitution;
at least one of Rₐ, R_{b}, R_{d}, Rₑ and R_{f} is present and is a substituent R, wherein the substituent R has a structure represented by Formula 2:

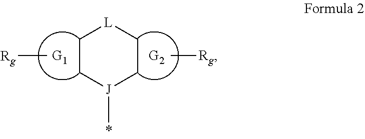

wherein in Formula 2, “*” represents a position where Formula 2 is joined;
R_{g} represents, at each occurrence identically or differently, mono-substitution, multiple substitutions or non-substitution;
the ring G₁ and the ring G₂ are, at each occurrence identically or differently, selected from a carbocyclic ring having 3 to 30 ring atoms, a heterocyclic ring having 3 to 30 ring atoms or a combination thereof,
J is, at each occurrence identically or differently, selected from P, P(O), CR″, SiR″ or GeR″;
L is selected from a single bond, O, S, SO₂, Se, NR″′, CR″R″′, SiR″R″′, GeR″R″′, BR″′, PR″′, P(O)R″′, substituted or unsubstituted alkylene having 2 to 20 carbon atoms, substituted or unsubstituted heteroalkylene having 1 to 20 carbon atoms, substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;
Rₐ, R_{b}, R_{d}, Rₑ, R_{f}, R_{g}, R′, R″ and R″′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents Rₐ, R_{b}, R_{d}, Rₑ, R_{f}, R_{g}, R′, R″, R″′ can be optionally joined to form a ring.

In the present disclosure, the “unsaturated carbocyclic ring” comprises an aromatic unsaturated carbocyclic ring and a non-aromatic unsaturated carbocyclic ring; and the “unsaturated heterocyclic ring” comprises an aromatic unsaturated heterocyclic ring and a non-aromatic unsaturated heterocyclic ring.

In the present disclosure, the “carbocyclic ring” comprises a saturated carbocyclic ring and an unsaturated carbocyclic ring; and the “heterocyclic ring” comprises a saturated heterocyclic ring and an unsaturated heterocyclic ring.

In the present disclosure, the expression that “adjacent substituents Rₐ, R_{b}, R_{d}, Rₑ, R_{f}, R_{g}, R′, R″, R″′ can be optionally joined to form a ring” is intended to mean that any one or more of groups of adjacent substituents, such as two substituents Rₐ, two substituents R_{b}, two substituents R_{d}, two substituents Rₑ, two substituents R_{f}, two substituents R_{g}, two substituents R′, two substituents R″′, substituents Rₐ and R′, substituents R_{b} and R′, substituents Rₑ and R′, substituents R″ and R_{g}, and substituents R″′ and R_{g}, can be joined to form a ring. Obviously, it is possible that none of these adjacent substituents are joined to form a ring.

According to an embodiment of the present disclosure, at least one of the ring G₁ and the ring G₂ is selected from an aromatic ring having 6 to 30 carbon atoms, a heteroaromatic ring having 3 to 30 carbon atoms or a combination thereof.

According to an embodiment of the present disclosure, one or two of the Rₐ, R_{b}, R_{d}, Rₑ and R_{f} are the substituent R, wherein the substituent R has the structure represented by Formula 2.

According to an embodiment of the present disclosure, at least one of the Rₐ is present and is the substituent R, wherein the substituent R has the structure represented by Formula 2. For example, one or two of the Rₐ are the substituent R.

According to an embodiment of the present disclosure, at least one of the Rₑ is present and is the substituent R, wherein the substituent R has the structure represented by Formula 2. For example, one or two of the Rₑ are the substituent R.

According to an embodiment of the present disclosure, at least one of the R_{f} is present and is the substituent R, wherein the substituent R has the structure represented by Formula 2. For example, one or two of the R_{f} are the substituent R.

According to an embodiment of the present disclosure, M is selected from Cu, Ag, Au, Ru, Rh, Pd, Os, Ir or Pt.

According to an embodiment of the present disclosure, M is selected from Pt or Pd.

According to an embodiment of the present disclosure, M is selected from Pt.

According to an embodiment of the present disclosure, the ring A, the ring B, the ring E and the ring F are, at each occurrence identically or differently, selected from a five-membered unsaturated carbocyclic ring, an aromatic ring having 6 to 30 carbon atoms or a heteroaromatic ring having 3 to 30 carbon atoms.

According to an embodiment of the present disclosure, the ring A, the ring B, the ring E and the ring F are, at each occurrence identically or differently, selected from a five-membered unsaturated carbocyclic ring, an aromatic ring having 6 to 18 carbon atoms or a heteroaromatic ring having 3 to 18 carbon atoms.

According to an embodiment of the present disclosure, the ring A, the ring B, the ring E and the ring F are, at each occurrence identically or differently, selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring, an imidazole ring or a combination thereof.

According to an embodiment of the present disclosure, the ring D is, at each occurrence identically or differently, selected from an unsaturated heterocyclic ring having 1 to 18 carbon atoms.

According to an embodiment of the present disclosure, the ring D is, at each occurrence identically or differently, selected from an unsaturated heterocyclic ring having 1 to 12 carbon atoms.

According to an embodiment of the present disclosure, the ring D is, at each occurrence identically or differently, selected from an imidazolecarbene ring or a benzimidazolecarbene ring.

According to an embodiment of the present disclosure, the ring G₁ and the ring G₂ are, at each occurrence identically or differently, selected from a carbocyclic ring having 5 to 18 ring atoms, an unsaturated heterocyclic ring having 5 to 18 ring atoms or a combination thereof.

According to an embodiment of the present disclosure, the ring G₁ and the ring G₂ are, at each occurrence identically or differently, selected from a cyclopentane ring, a cyclohexane ring, a benzene ring, a pyridine ring, an indene ring, a fluorene ring, an indole ring, a carbazole ring, a benzofuran ring, a benzosilole ring, a benzothiophene ring, a cyclopentadiene ring, a furan ring, a thiophene ring, a silole ring or a combination thereof.

According to an embodiment of the present disclosure, L₁ is selected from a single bond, O, S, (SiR′R′)_{y}, NR′, (CR′R′)_{y} or a combination thereof.

According to an embodiment of the present disclosure, y is 1 or 2.

According to an embodiment of the present disclosure, L₁ is selected from a single bond, O or S.

According to an embodiment of the present disclosure, L₁ is selected from a single bond.

According to an embodiment of the present disclosure, K₁ to K₄ are selected from a single bond.

According to an embodiment of the present disclosure, Z₁ is selected from N, and Z₂ and Z₃ are selected from C.

According to an embodiment of the present disclosure, the compound has a structure represented by one of Formula 1-1 to Formula 1-15:

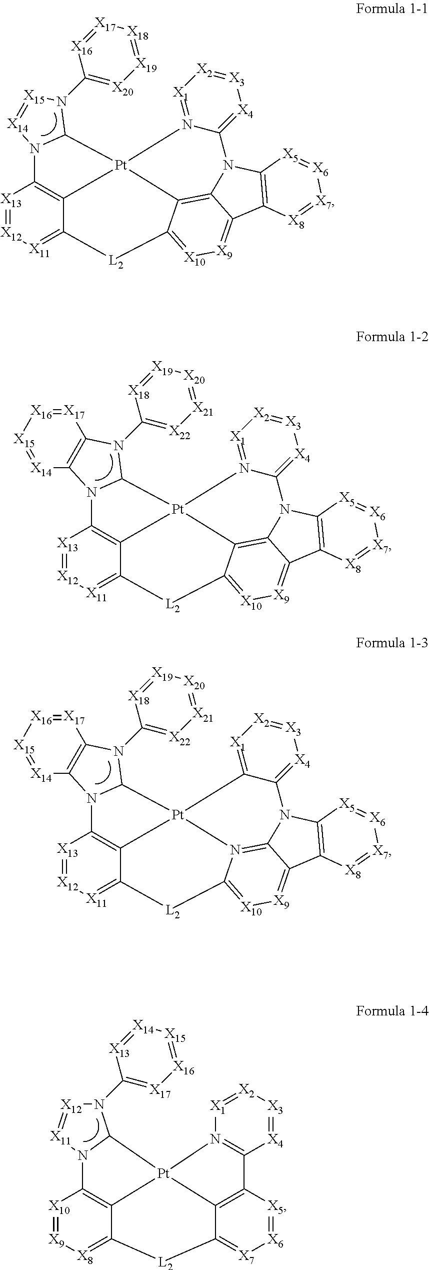

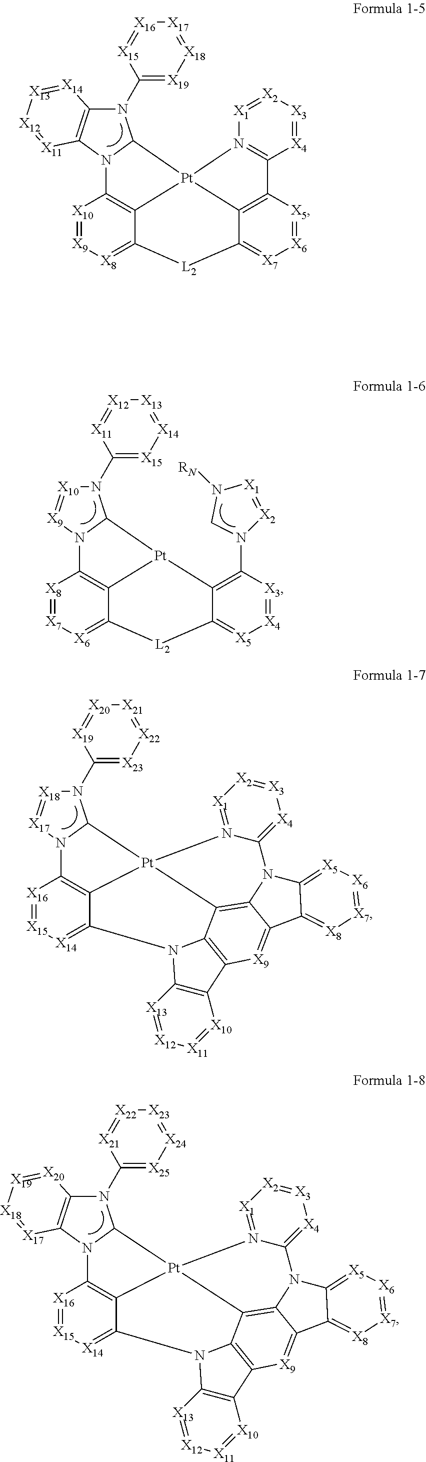

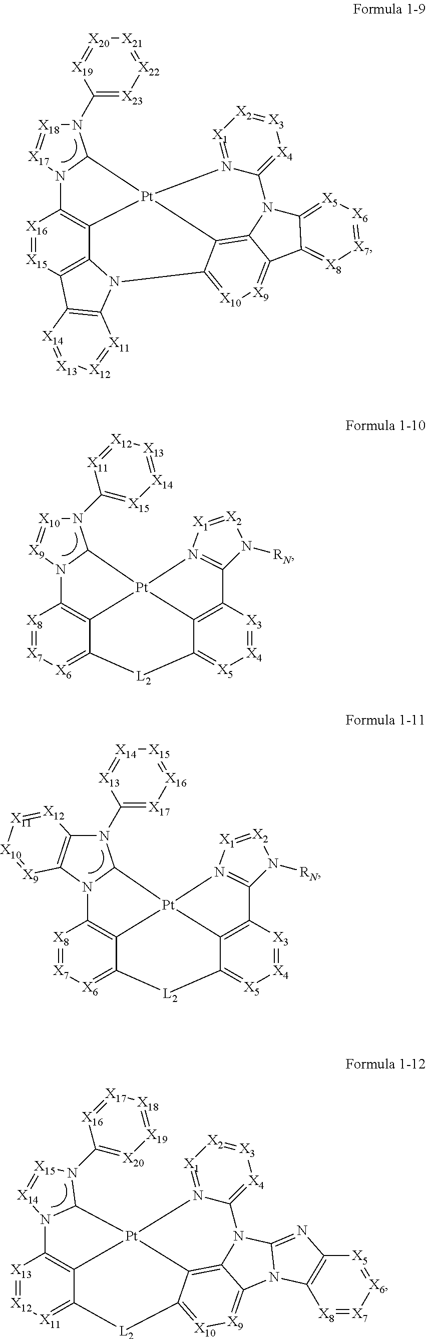

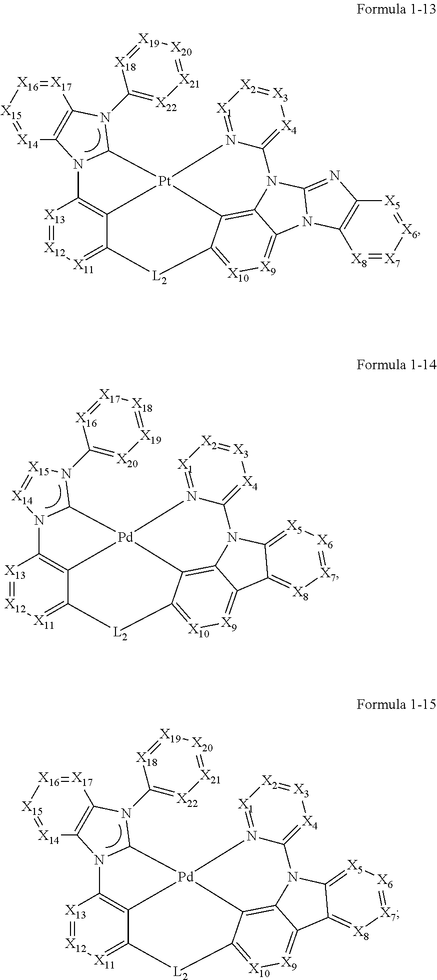

wherein in Formula 1-1 to Formula 1-15,
L₂ is, at each occurrence identically or differently, selected from a single bond, O, S, Se, (SiR′R′)_{y}, PR′, NR′, (CR′R′)_{y}, substituted or unsubstituted arylene having 6 to 30 carbon atoms, substituted or unsubstituted heteroarylene having 3 to 30 carbon atoms or a combination thereof;
y is, at each occurrence identically or differently, selected from 1, 2, 3, 4 or 5;
X₁ to X₂₅ are, at each occurrence identically or differently, selected from CR, CRₓ or N, and at least one of X₁ to Xᵢ is selected from CR, wherein the R has a structure represented by Formula 2-1, and Xᵢ corresponds to one of X₁ to X₂₅ that has the largest serial number in any one of Formula 1-1 to Formula 1-15:

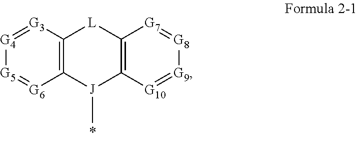

G₃ to G₁₀ are, at each occurrence identically or differently, selected from CR_{g} or N;
J is, at each occurrence identically or differently, selected from CR″ or SiR″;
L is selected from a single bond, O, S, SO₂, Se, NR″′, CR″R″′, SiR″R″′, GeR″R″′, BR″′, PR″′, P(O)R″′, substituted or unsubstituted alkylene having 2 to 20 carbon atoms, substituted or unsubstituted heteroalkylene having 1 to 20 carbon atoms, substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;
R′, R″, R″′, Rₓ, R_{g} and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents R′, R″, R″′, Rₓ, R_{g}, R_{N} can be optionally joined to form a ring.

In this embodiment, the expression that “adjacent substituents R′, R″, R″′, Rₓ, R_{g}, R_{N} can be optionally joined to form a ring” is intended to mean that any one or more of groups of adjacent substituents, such as two substituents Rₓ, two substituents R_{g}, two substituents R′, two substituents R″′, substituents R, and R′, substituents R″ and R_{g}, and substituents R″′ and R_{g}, can be joined to form a ring. Obviously, it is possible that none of these adjacent substituents are joined to form a ring.

In the present disclosure, for Formula 1-1, Xᵢ corresponds to X₂₀ which is the largest serial number among X₁ to X₂₅ in Formula 1-1; for Formula 1-2, Xᵢ corresponds to X₂₂ which is the largest serial number among X₁ to X₂₅ in Formula 1-2; for Formula 1-3, Xᵢ corresponds to X₂₂ which is the largest serial number among X₁ to X₂₅ in Formula 1-3; for Formula 1-4, Xᵢ corresponds to X₁₇ which is the largest serial number among X₁ to X₂₅ in Formula 1-4; for Formula 1-5, Xᵢ corresponds to X₁₉ which is the largest serial number among X₁ to X₂₅ in Formula 1-5; for Formula 1-6, X; corresponds to X₁₅ which is the largest serial number among X₁ to X₂₅ in Formula 1-6; for Formula 1-7, X; corresponds to X₂₃ which is the largest serial number among X₁ to X₂₅ in Formula 1-7; for Formula 1-8, Xᵢ corresponds to X₂₅ which is the largest serial number among X₁ to X₂₅ in Formula 1-8; for Formula 1-9, Xᵢ corresponds to X₂₃ which is the largest serial number among X₁ to X₂₅ in Formula 1-9; for Formula 1-10, Xᵢ corresponds to X₁₅ which is the largest serial number among X₁ to X₂₅ in Formula 1-10; for Formula 1-11, X; corresponds to X₁₇ which is the largest serial number among X₁ to X₂₅ in Formula 1-11; for Formula 1-12, X; corresponds to X₂₀ which is the largest serial number among X₁ to X₂₅ in Formula 1-12; for Formula 1-13, Xᵢ corresponds to X₂₂ which is the largest serial number among X₁ to X₂₅ in Formula 1-13; for Formula 1-14, Xᵢ corresponds to X₂₀ which is the largest serial number among X₁ to X₂₅ in Formula 1-14; and for Formula 1-15, Xᵢ corresponds to X₂₂ which is the largest serial number among X₁ to X₂₅ in Formula 1-15.

According to an embodiment of the present disclosure, the compound has a structure represented by Formula 1-1 or Formula 1-2.

According to an embodiment of the present disclosure, the compound has a structure represented by Formula 1-1, wherein at least one of X₁ to X₄ is selected from CR, and the R has the structure represented by Formula 2-1.

According to an embodiment of the present disclosure, the compound has a structure represented by Formula 1-1, wherein at least one of X₅ to X₁₀ is selected from CR, and the R has the structure represented by Formula 2-1.

According to an embodiment of the present disclosure, the compound has a structure represented by Formula 1-1, wherein at least one of X₁₁ to X₁₃ is selected from CR, and the R has the structure represented by Formula 2-1.

According to an embodiment of the present disclosure, the compound has a structure represented by Formula 1-1, wherein at least one of X₁₄ and X₁₅ is selected from CR, and the R has the structure represented by Formula 2-1.

According to an embodiment of the present disclosure, the compound has a structure represented by Formula 1-1, wherein at least one of X₁₆ to X₂₀ is selected from CR, and the R has the structure represented by Formula 2-1.

According to an embodiment of the present disclosure, the compound has a structure represented by Formula 1-2, wherein at least one of X₁ to X₄ is selected from CR, and the R has the structure represented by Formula 2-1.

According to an embodiment of the present disclosure, the compound has a structure represented by Formula 1-2, wherein at least one of X₅ to X₁₀ is selected from CR, and the R has the structure represented by Formula 2-1.

According to an embodiment of the present disclosure, the compound has a structure represented by Formula 1-2, wherein at least one of X₁₁ to X₁₃ is selected from CR, and the R has the structure represented by Formula 2-1.

According to an embodiment of the present disclosure, the compound has a structure represented by Formula 1-2, wherein at least one of X₁₄ to X₁₇ is selected from CR, and the R has the structure represented by Formula 2-1.

According to an embodiment of the present disclosure, the compound has a structure represented by Formula 1-2, wherein at least one of X₁₈ to X₂₂ is selected from CR, and the R has the structure represented by Formula 2-1.

According to an embodiment of the present disclosure, the compound has a structure represented by Formula 3:

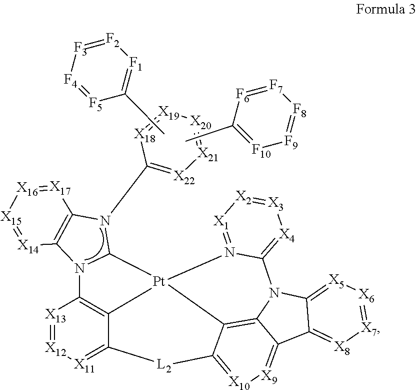

wherein in Formula 3,
L₂ is, at each occurrence identically or differently, selected from a single bond, O, S, Se, (SiR′R′)_{y}, PR′, NR′, (CR′R′)_{y}, substituted or unsubstituted arylene having 6 to 30 carbon atoms, substituted or unsubstituted heteroarylene having 3 to 30 carbon atoms or a combination thereof;
y is, at each occurrence identically or differently, selected from 1, 2, 3, 4 or 5;
F₁ to F₁₀ are, at each occurrence identically or differently, selected from CR_{f} or N;
X₁₈ to X₂₂ are, at each occurrence identically or differently, selected from C, CRₓ or N;
X₁ to X₁₇ are, at each occurrence identically or differently, selected from CR, CRₓ or N, and at least one of X₁ to X₁₇ is selected from CR, wherein the R has a structure represented by Formula 2-1:

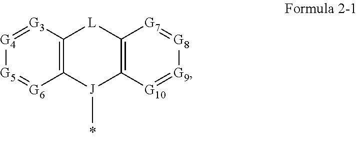

G₃ to G₁₀ are, at each occurrence identically or differently, selected from CR_{g} or N;
J is, at each occurrence identically or differently, selected from CR″ or SiR″;
L is selected from a single bond, O, S, SO₂, Se, NR″′, CR″R″′, SiR″R″′, GeR″R″′, BR″′, PR″′, P(O)R″′, substituted or unsubstituted alkylene having 2 to 20 carbon atoms, substituted or unsubstituted heteroalkylene having 1 to 20 carbon atoms, substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;
R′, R″, R″′, Rₓ, R_{g} and R_{f} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents R′, R″, R″′, Rₓ, R_{g}, R_{f} can be optionally joined to form a ring.

In this embodiment, the expression that “adjacent substituents R′, R″, R″′, Rₓ, R_{g}, R_{f} can be optionally joined to form a ring” is intended to mean that any one or more of groups of adjacent substituents, such as two substituents Rₓ, two substituents R_{g}, two substituents R′, two substituents R″′, two substituents R_{f}, substituents Rₓ and R′, substituents R″ and R_{g}, substituents R″′ and R_{g}, and substituents Rₓ and R_{f}, can be joined to form a ring. Obviously, it is possible that none of these adjacent substituents are joined to form a ring.

According to an embodiment of the present disclosure, in Formula 3, X₁₈ is selected from C and joined to the ring comprising F₁ to F₅, and X₂₂ is selected from C and joined to the ring comprising F₆ to F₁₀.

According to an embodiment of the present disclosure, in Formula 3, X₂₀ is selected from CRₓ, and the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 3, X₂₀ is selected from CRₓ, and the Rₓ is selected from the group consisting of: deuterium, halogen, substituted or unsubstituted alkyl having 1 to 20 carbon atoms, substituted or unsubstituted cycloalkyl having 3 to 20 ring carbon atoms and combinations thereof.

According to an embodiment of the present disclosure, in Formula 1-1 to Formula 1-15, X₁ to X₂₅ are, at each occurrence identically or differently, selected from CR or CRₓ, and at least one of X₁ to Xᵢ is selected from CR, wherein the R has the structure represented by Formula 2-1, Xᵢ corresponds to one of X₁ to X₂₅ that has the largest serial number in any one of Formula 1-1 to Formula 1-15, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, L₂ is selected from a single bond, O, S, (SiR′R′)_{y}, NR′, (CR′R′)_{y} or a combination thereof, wherein y is 1 or 2, and the R′ is, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, L₂ is selected from a single bond, O or S.

According to an embodiment of the present disclosure, L₂ is selected from O.

According to an embodiment of the present disclosure, L is selected from a single bond, O, S, Se, NR″′, CR″R″′, SiR″R″′, GeR″R″′, PR″′ or P(O)R″′, and the R″′ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, L is selected from a single bond.

According to an embodiment of the present disclosure, G₃ to G₁₀ are, at each occurrence identically or differently, selected from CR_{g}.

According to an embodiment of the present disclosure, the R_{g} is, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the R_{g} is, at each occurrence identically or differently, selected from the group consisting of: hydrogen, deuterium, fluorine, cyano, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, the R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, the R″ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, substituted or unsubstituted phenyl, substituted or unsubstituted pyridyl and combinations thereof.

According to an embodiment of the present disclosure, the substituent R is, at each occurrence identically or differently, selected from the group consisting of structures Jn-1 to Jn-70. For the specific structures of Jn-1 to Jn-70, see claim 14.

According to an embodiment of the present disclosure, hydrogens in the structures Jn-1 to Jn-70 can be partially or fully substituted with deuterium.

According to an embodiment of the present disclosure, the compound is selected from the group consisting of: Compound Pt1-1 to Compound Pt1-164, Compound Pt2-1 to Compound Pt2-176, Compound Pt3-1 to Compound Pt3-80, and Compound Pt4-1 to Compound Pt4-32. For the specific structures of Compound Pt1-1 to Compound Pt1-164, Compound Pt2-1 to Compound Pt2-176, Compound Pt3-1 to Compound Pt3-80, and Compound Pt4-1 to Compound Pt4-32, see claim 15.

According to an embodiment of the present disclosure, disclosed is an electroluminescent device. The electroluminescent device comprises:
an anode,
a cathode, and
an organic layer disposed between the anode and the cathode, wherein the organic layer comprises a compound having a structure of Formula 1, wherein the compound having the structure of Formula 1 is as shown in any one of the preceding embodiments.

According to an embodiment of the present disclosure, the organic layer is a light-emitting layer and the compound is a light-emitting material.

According to an embodiment of the present disclosure, the device emits blue light.

According to an embodiment of the present disclosure, the device emits white light.

According to an embodiment of the present disclosure, the light-emitting layer comprises at least one host material.

According to an embodiment of the present disclosure, the light-emitting layer comprises at least two host materials.

According to an embodiment of the present disclosure, the host material comprises a chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, the at least one host material has a structure represented by Formula 4:

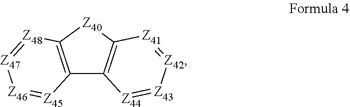

wherein in Formula 4,
Z₄₀ is selected from O or S;
Z₄₁ to Z₄₈ are, at each occurrence identically or differently, selected from CR₄, CR₄′ or N, at least one of Z₄₁ to Z₄₈ is selected from N, and at least one of Z₄₁ to Z₄₈ is selected from CR₄′;
the R₄′ is, at each occurrence identically or differently, selected from substituted or unsubstituted aryl having 6 to 30 carbon atoms, substituted or unsubstituted heteroaryl having 3 to 30 carbon atoms or a combination thereof; and
the R₄ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 4, at least one of Z₄₁ to Z₄₈ is selected from N, and at least two of Z₄₁ to Z₄₈ are selected from CR₄′.

According to an embodiment of the present disclosure, in Formula 4, only one of Z₄₁ to Z₄₈ is selected from N, and only two of Z₄₁ to Z₄₈ are selected from CR₄′.

According to an embodiment of the present disclosure, in Formula 4, Z₄₂ is selected from N, and Z₄₁ and Z₄₆ are selected from CR₄′.

According to another embodiment of the present disclosure, disclosed is a compound composition comprising a compound having a structure of Formula 1, wherein the compound having the structure of Formula 1 is as shown in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, materials disclosed herein may be used in combination with a wide variety of dopants, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

A method for preparing the compound of the present disclosure is not limited herein. Typically, the following compounds are used as examples without limitation, and synthesis routes and preparation methods thereof are described below.

### Synthesis Example 1: Synthesis of Compound Pt1-41

### Step 1 Synthesis of Intermediate 1

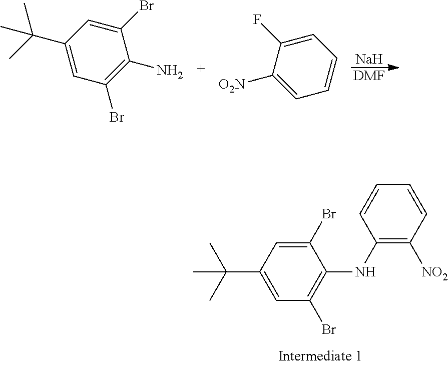

Under a nitrogen condition, 2,6-dibromo-4-t-butylaniline (61.4 g, 200 mmol) was dissolved in DMF (300 mL), and NaH (12 g, 300 mmol) was added and reacted for 0.5 h at 0° C. Then, o-fluoronitrobenzene (42.3 g, 300 mmol) was added slowly, and the reaction was warmed to room temperature and conducted overnight. After the reaction was completed, the reaction solution was extracted with DCM and an aqueous sodium chloride solution to obtain an organic layer. The organic layer was washed twice with an aqueous sodium chloride solution, dried over anhydrous magnesium sulfate, concentrated under reduced pressure, and purified through column chromatography to obtain Intermediate 1 (49.2 g, 115 mmol).

### Step 2: Synthesis of Intermediate 2

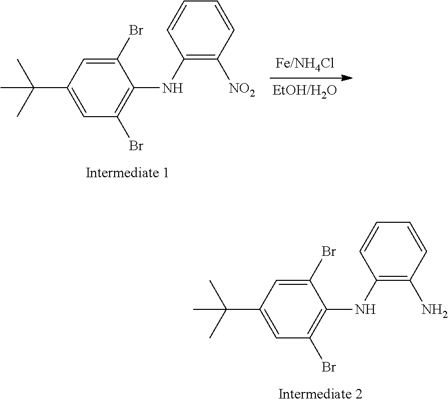 [SMILES: CC(C)(C)c1cc(Br)c(Nc2ccccc2[N+](=O)[O-])c(Br)c1 ; CC(C)(C)c1cc(Br)c(Nc2ccccc2N)c(Br)c1]

Intermediate 1 (49.2 g, 115 mmol) was dissolved in EtOH (200 mL) and water (200 mL), Fe (19.4 g, 345 mmol) and NH₄Cl (0.61 g, 11.5 mmol) were added, and the reaction was warmed to reflux and conducted overnight. After the reaction was completed, the reaction solution was filtered through Celite, and the filtrate was evaporated to dryness under reduced pressure and extracted with EA and water to obtain an organic layer. The organic layer was washed twice with an aqueous sodium chloride solution, dried over anhydrous magnesium sulfate, concentrated under reduced pressure, and purified through column chromatography to obtain Intermediate 2 (40.6 g, 102 mmol).

### Step 3: Synthesis of Intermediate 3

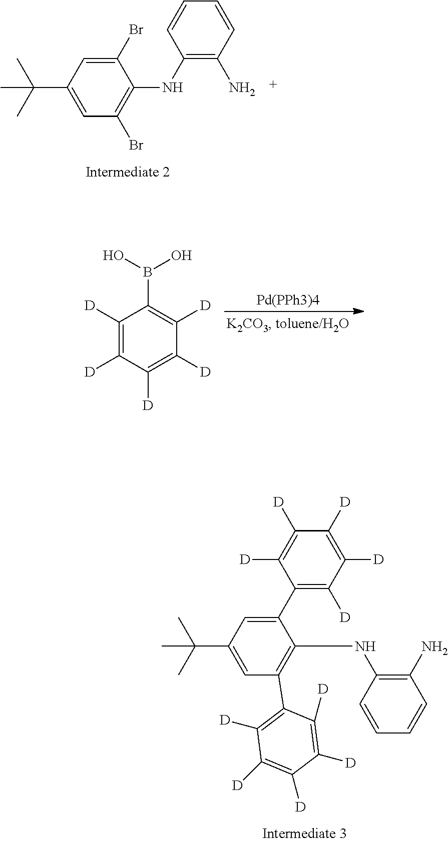 [SMILES: CC(C)(C)c1cc(Br)c(Nc2ccccc2N)c(Br)c1 ; [2H]c1c([2H])c([2H])c(B(O)O)c([2H])c1[2H] ; [2H]c1c([2H])c([2H])c(-c2cc(C(C)(C)C)cc(-c3c([2H])c([2H])c([2H])c([2H])c3[2H])c2Nc2ccccc2N)c([2H])c1[2H] ; "Pd(PPh3)4"]

Under a nitrogen condition, Intermediate 2 (19.8 g, 50 mmol), phenyl-D5-boronic acid (14.1 g, 120 mmol), Pd(PPh₃)₄ (2.9 g, 2.5 mmol) and potassium carbonate (10.4 g, 75 mmol) were dissolved in toluene (150 mL) and water (50 mL), and the reaction was warmed to reflux and conducted overnight. After the reaction was completed, the reaction solution was extracted with EA and water to obtain an organic layer. The organic layer was washed twice with an aqueous sodium chloride solution, dried over anhydrous magnesium sulfate, concentrated under reduced pressure, and purified through column chromatography to obtain Intermediate 3 (17.3 g, 43 mmol).

### Step 4: Synthesis of Intermediate 4

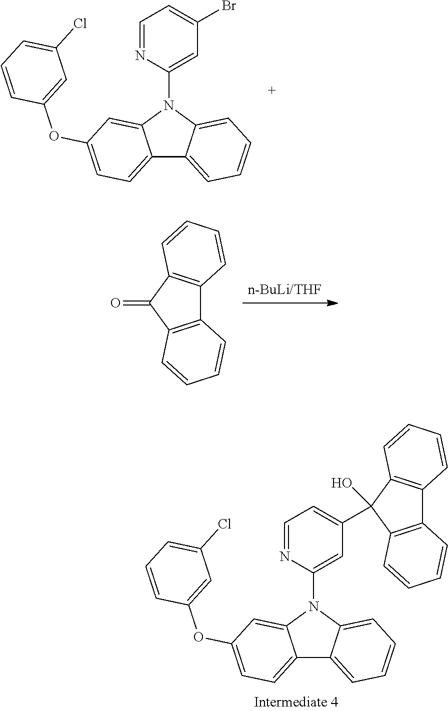

Under nitrogen protection, 9-(4-bromo-pyridin-2-yl)-2-(3-chlorophenoxy)-9H-carbazole (2.7 g, 6.0 mmol) was dissolved in THE (40 mL), and n-butyl lithium (2.6 mL, 6.6 mmol) was added and reacted for 1 h at −72° C. Then, 9-fluorenone (1.4 g, 7.8 mmol) was added slowly, and the reaction was warmed to room temperature and conducted overnight. After the reaction was completed, the reaction solution was extracted with DCM and an aqueous sodium chloride solution to obtain an organic layer. The organic layer was washed twice with an aqueous sodium chloride solution, dried over anhydrous magnesium sulfate, concentrated under reduced pressure, and purified through column chromatography to obtain Intermediate 4 (2.0 g, 3.6 mmol).

### Step 5: Synthesis of Intermediate 5

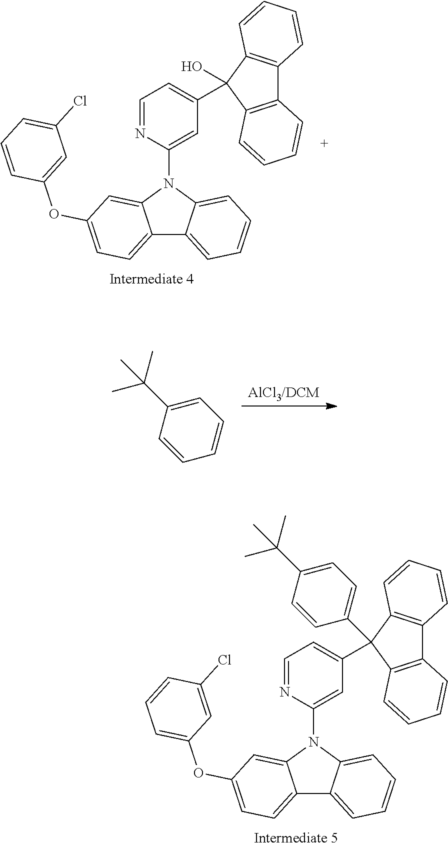

Under nitrogen protection, Intermediate 4 (2.0 g, 3.6 mmol) was dissolved in DCM (30 mL) and t-butyl benzene (15 mL), and aluminum trichloride (0.72 g, 5.4 mmol) was added and reacted completely at 0° C. The reaction was quenched with water and extracted with DCM and an aqueous sodium chloride solution to obtain an organic layer. The organic layer was washed twice with an aqueous sodium chloride solution, dried over anhydrous magnesium sulfate, concentrated under reduced pressure, and purified through column chromatography to obtain Intermediate 5 (1.4 g, 2.3 mmol).

### Step 6: Synthesis of Intermediate 6

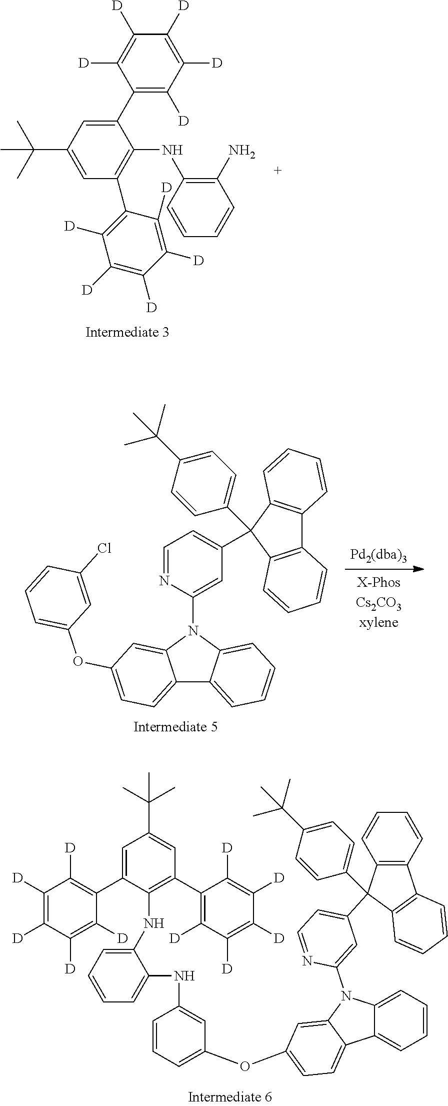 [SMILES: [2H]c1c([2H])c([2H])c(-c2cc(C(C)(C)C)cc(-c3c([2H])c([2H])c([2H])c([2H])c3[2H])c2Nc2ccccc2N)c([2H])c1[2H] ; CC(C)(C)c1ccc(C2(c3ccnc(-n4c5ccccc5c5ccc(Oc6cccc(Cl)c6)cc54)c3)c3ccccc3-c3ccccc32)cc1 ; [2H]c1c([2H])c([2H])c(-c2cc(C(C)(C)C)cc(-c3c([2H])c([2H])c([2H])c([2H])c3[2H])c2Nc2ccccc2Nc2cccc(Oc3ccc4c5ccccc5n(-c5cc(C6(c7ccc(C(C)(C)C)cc7)c7ccccc7-c7ccccc76)ccn5)c4c3)c2)c([2H])c1[2H]]

Under a nitrogen condition, Intermediate 3 (0.88 g, 2.18 mmol), Intermediate 5 (1.4 g, 2.3 mmol), Pd₂(dba)₃ (0.1 g, 0.1 mmol), X-Phos (0.1 g, 0.2 mmol), cesium carbonate (1.4 g, 4.4 mmol) and xylene (30 mL) were added to a flask, and the reaction was heated to 130° C., stirred overnight, cooled to room temperature, concentrated, and purified through column chromatography to obtain Intermediate 6 (0.8 g, 0.77 mmol).

### Step 7: Synthesis of Intermediate 7

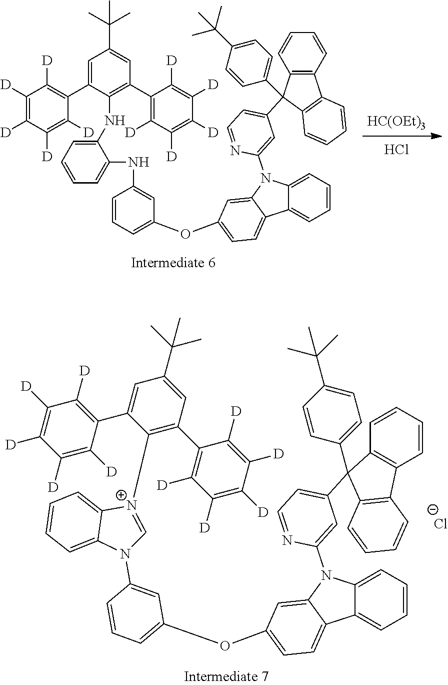 [SMILES: [2H]c1c([2H])c([2H])c(-c2cc(C(C)(C)C)cc(-c3c([2H])c([2H])c([2H])c([2H])c3[2H])c2Nc2ccccc2Nc2cccc(Oc3ccc4c5ccccc5n(-c5cc(C6(c7ccc(C(C)(C)C)cc7)c7ccccc7-c7ccccc76)ccn5)c4c3)c2)c([2H])c1[2H] ; Cl ; [2H]c1c([2H])c([2H])c(-c2cc(C(C)(C)C)cc(-c3c([2H])c([2H])c([2H])c([2H])c3[2H])c2-[n+]2cn(-c3cccc(Oc4ccc5c6ccccc6n(-c6cc(C7(c8ccc(C(C)(C)C)cc8)c8ccccc8-c8ccccc87)ccn6)c5c4)c3)c3ccccc32)c([2H])c1[2H] ; [Cl-] ; "HC(OEt)3"]

Under a nitrogen condition, Intermediate 6 (0.8 g, 0.77 mmol), triethyl orthoformate (5.7 g, 38.5 mmol) and concentrated hydrochloric acid (0.5 mL) were added to a flask, and the reaction was heated to 100° C. and stirred overnight. After TLC showed that the reaction was completed, the reaction solution was cooled to room temperature, concentrated, and purified through column chromatography to obtain Intermediate 7 (0.5 g, 0.48 mmol).

### Step 8: Synthesis of Compound Pt1-41

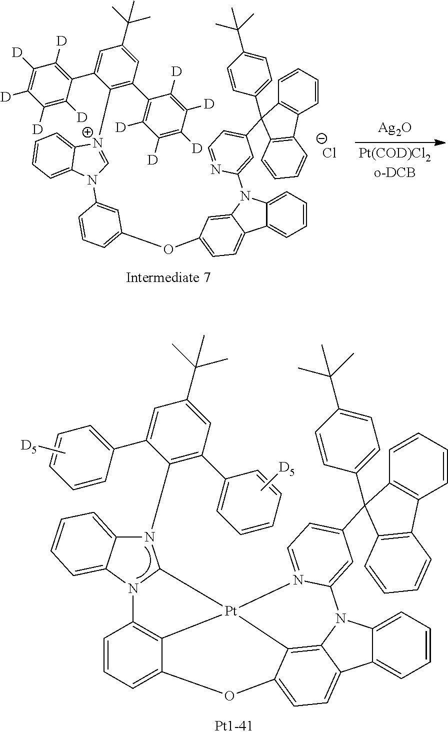

Under a nitrogen condition, Intermediate 7 (0.5 g, 0.48 mmol) and Ag₂O (0.1 g, 0.43 mmol) were added to DCE (20 mL) and reacted for 12 h at room temperature. After the reaction was completed, the reaction solution was evaporated under reduced pressure to remove the solvent, and (1,5-cyclooctadiene)platinum dichloride (0.17 g, 0.45 mmol) was added. After o-dichlorobenzene (o-DCB, 20 mL) was added, the reaction was heated to 190° C., stirred for 72 h, cooled to room temperature, and purified through column chromatography to obtain Pt1-41 (0.08 g, 0.065 mmol). The product was identified as the target product with a molecular weight of 1235.5.

### Synthesis Example 2: Synthesis of Compound Pt2-39

### Step 1 Synthesis of Intermediate 8

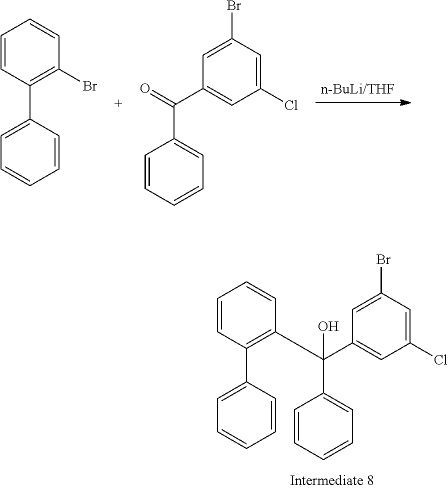 [SMILES: Brc1ccccc1-c1ccccc1 ; O=C(c1ccccc1)c1cc(Cl)cc(Br)c1 ; OC(c1ccccc1)(c1cc(Cl)cc(Br)c1)c1ccccc1-c1ccccc1]

Under nitrogen protection, 2-bromo-1,1′-biphenyl (12.8 g, 55 mmol) was dissolved in THE (110 mL), and n-butyl lithium (24 mL, 60.5 mmol) was added and reacted for 1 h at −72° C. Then, (3-bromo-5-chlorophenyl)-benzophenone (16 g, 54 mmol) was added slowly, and the reaction was warmed to room temperature and conducted overnight. After the reaction was completed, the reaction solution was extracted with DCM and an aqueous sodium chloride solution to obtain an organic layer. The organic layer was washed twice with an aqueous sodium chloride solution, dried over anhydrous magnesium sulfate, and concentrated under reduced pressure to obtain Intermediate 8 (20.2 g, 45 mmol), which was directly used in the next step without further purification.

### Step 2: Synthesis of Intermediate 9

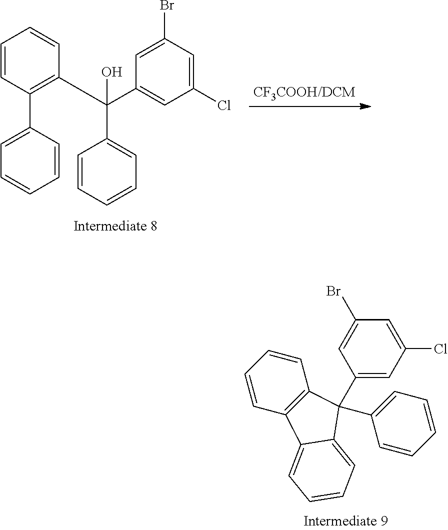 [SMILES: OC(c1ccccc1)(c1cc(Cl)cc(Br)c1)c1ccccc1-c1ccccc1 ; Clc1cc(Br)cc(C2(c3ccccc3)c3ccccc3-c3ccccc32)c1]

Under nitrogen protection, Intermediate 8 (20.2 g, 45 mmol) was dissolved in DCM (110 mL), and trifluoroacetic acid (10 mL) was added and reacted for 1 h at 0° C. Then, the reaction solution was extracted with DCM and an aqueous sodium chloride solution. The organic layer was washed twice with an aqueous sodium chloride solution, dried over anhydrous magnesium sulfate, and concentrated under reduced pressure to obtain Intermediate 9 (12 g, 27.8 mmol).

### Step 3: Synthesis of Intermediate 10

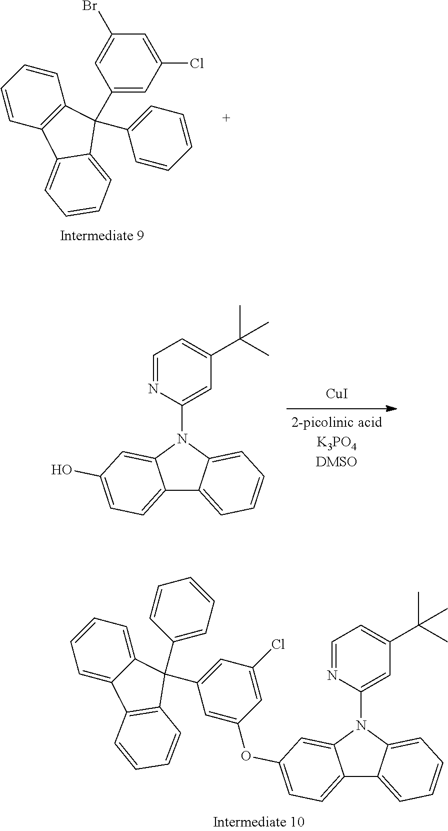 [SMILES: Clc1cc(Br)cc(C2(c3ccccc3)c3ccccc3-c3ccccc32)c1 ; CC(C)(C)c1ccnc(-n2c3ccccc3c3ccc(O)cc32)c1 ; "CuI" ; CC(C)(C)c1ccnc(-n2c3ccccc3c3ccc(Oc4cc(Cl)cc(C5(c6ccccc6)c6ccccc6-c6ccccc65)c4)cc32)c1]

Under a nitrogen condition, Intermediate 9 (4.2 g, 9.7 mmol), 9-(4-(t-butyl)pyridin-2-yl)-9H-carbazol-2-ol (3.0 g, 9.7 mmol), cuprous iodide (0.19 g, 0.97 mmol), 2-pyridinecarboxylic acid (0.24 g, 2.0 mmol) and potassium phosphate (4.2 g, 20 mmol) were added to a 500 mL flask, and dimethyl sulfoxide (30 mL) was added. The reaction was heated to 120° C. and stirred overnight. After the reaction was completed, the reaction solution was purified through column chromatography to obtain Intermediate 10 (5.1 g, 7.6 mmol).

### Step 4: Synthesis of Intermediate 11

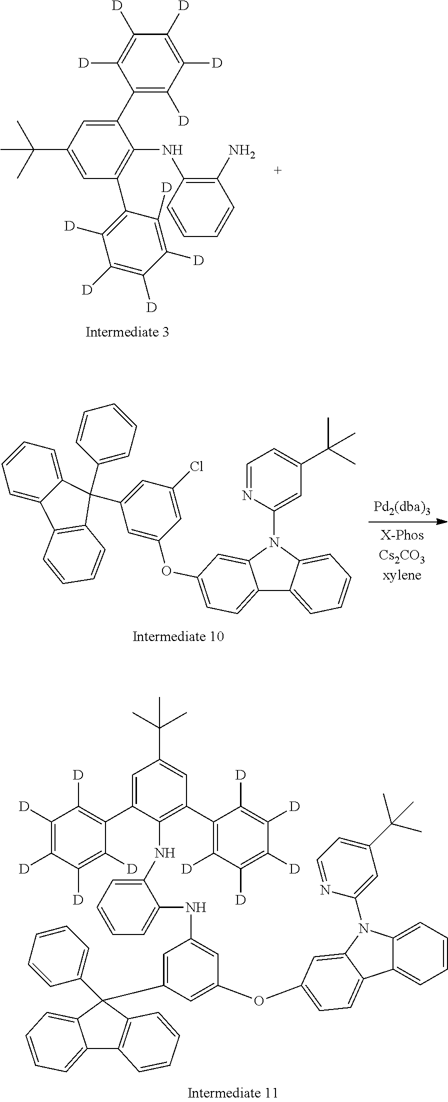 [SMILES: [2H]c1c([2H])c([2H])c(-c2cc(C(C)(C)C)cc(-c3c([2H])c([2H])c([2H])c([2H])c3[2H])c2Nc2ccccc2N)c([2H])c1[2H] ; CC(C)(C)c1ccnc(-n2c3ccccc3c3ccc(Oc4cc(Cl)cc(C5(c6ccccc6)c6ccccc6-c6ccccc65)c4)cc32)c1 ; [2H]c1c([2H])c([2H])c(-c2cc(C(C)(C)C)cc(-c3c([2H])c([2H])c([2H])c([2H])c3[2H])c2Nc2ccccc2Nc2cc(Oc3ccc4c5ccccc5n(-c5cc(C(C)(C)C)ccn5)c4c3)cc(C3(c4ccccc4)c4ccccc4-c4ccccc43)c2)c([2H])c1[2H]]

Under a nitrogen condition, Intermediate 3 (2.0 g, 5.0 mmol), Intermediate 10 (3.67 g, 5.5 mmol), Pd₂(dba)₃ (0.23 g, 0.25 mmol), X-Phos (0.24 g, 0.5 mmol), cesium carbonate (3.25 g, 10 mmol) and xylene (30 mL) were added to a flask, and the reaction was heated to 130° C., stirred overnight, cooled to room temperature, concentrated, and purified through column chromatography to obtain Intermediate 11 (3.0 g, 2.9 mmol).

### Step 5: Synthesis of Intermediate 12

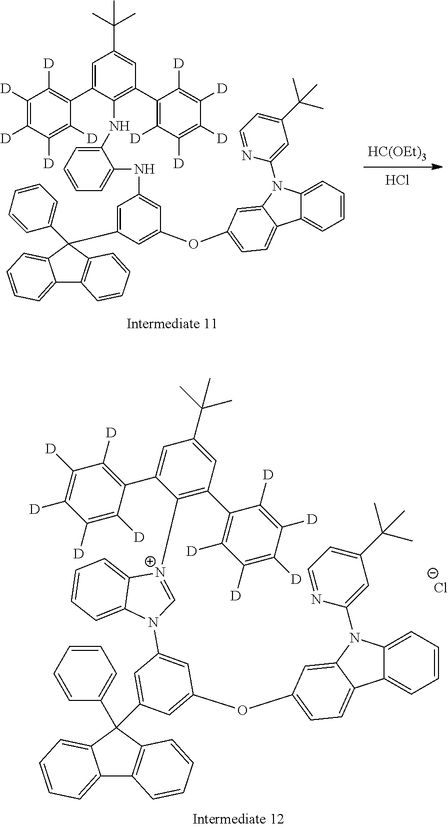 [SMILES: [2H]c1c([2H])c([2H])c(-c2cc(C(C)(C)C)cc(-c3c([2H])c([2H])c([2H])c([2H])c3[2H])c2Nc2ccccc2Nc2cc(Oc3ccc4c5ccccc5n(-c5cc(C(C)(C)C)ccn5)c4c3)cc(C3(c4ccccc4)c4ccccc4-c4ccccc43)c2)c([2H])c1[2H] ; Cl ; [2H]c1c([2H])c([2H])c(-c2cc(C(C)(C)C)cc(-c3c([2H])c([2H])c([2H])c([2H])c3[2H])c2-[n+]2cn(-c3cc(Oc4ccc5c6ccccc6n(-c6cc(C(C)(C)C)ccn6)c5c4)cc(C4(c5ccccc5)c5ccccc5-c5ccccc54)c3)c3ccccc32)c([2H])c1[2H] ; [Cl-] ; "HC(OEt)3"]

Under a nitrogen condition, Intermediate 11 (3.0 g, 2.9 mmol), triethyl orthoformate (20.6 g, 145 mmol) and concentrated hydrochloric acid (1 mL) were added to a flask, and the reaction was heated to 100° C. and stirred overnight. After TLC showed that the reaction was completed, the reaction solution was cooled to room temperature, concentrated, and purified through column chromatography to obtain Intermediate 12 (2.8 g, 2.68 mmol).

### Step 6: Synthesis of Compound Pt2-39

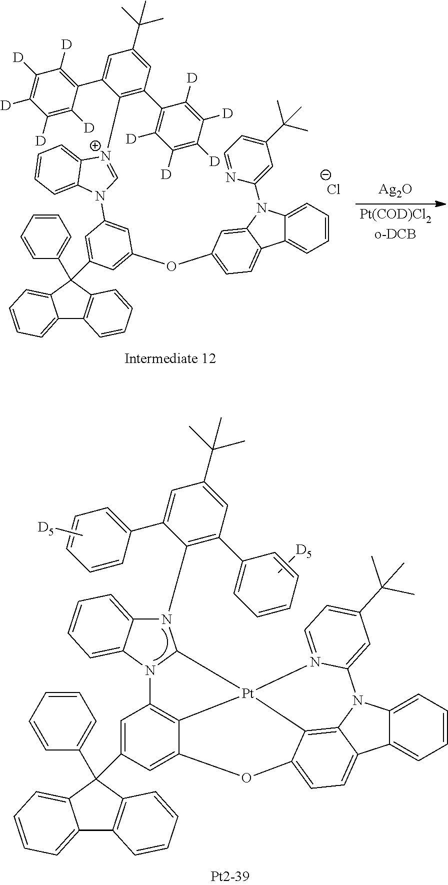

Under a nitrogen condition, Intermediate 12 (2.8 g, 2.68 mmol) and Ag₂O (0.34 g, 1.47 mmol) were added to DCE (30 mL) and reacted for 12 h at room temperature. After the reaction was completed, the reaction solution was evaporated under reduced pressure to remove the solvent, and (1,5-cyclooctadiene)platinum dichloride (0.95 g, 2.54 mmol) was added. After o-dichlorobenzene (20 mL) was added, the reaction was heated to 190° C., stirred for 72 h, cooled to room temperature, and purified through column chromatography to obtain Pt2-39 (1.27 g, 1.02 mmol). The product was identified as the target product with a molecular weight of 1235.5.

### Synthesis Example 3: Synthesis of Compound Pt3-5

### Step 1: Synthesis of Intermediate 15

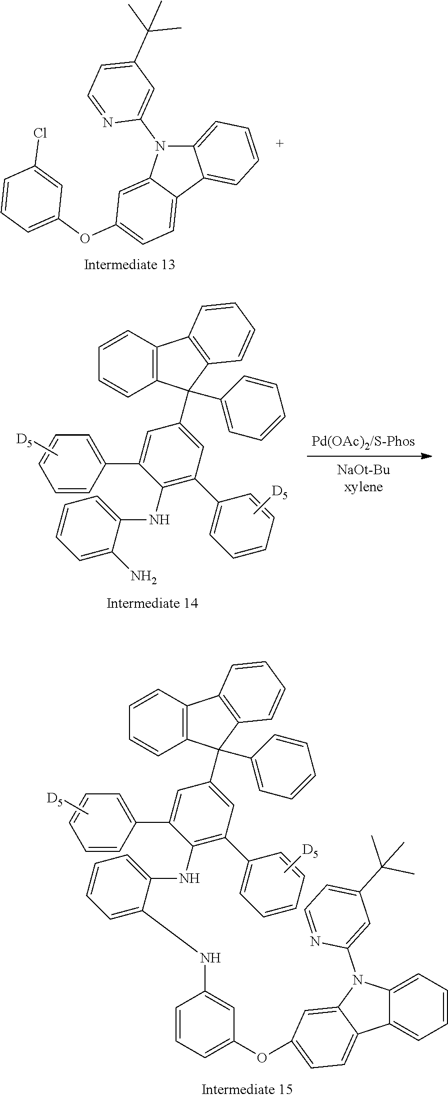

Under a nitrogen condition, Intermediate 13 (3.0 g, 7.0 mmol), Intermediate 14 (4.4 g, 7.0 mmol), Pd(OAc)₂ (68 mg, 0.3 mmol), S-Phos (250 mg, 0.6 mmol), NaOt-Bu (1.5 g, 15 mmol) and xylene (60 mL) were added to a flask, and the reaction was heated to 130° C., stirred overnight, cooled to room temperature, concentrated, and purified through column chromatography to obtain Intermediate 15 (2.0 g, 2.0 mmol).

### Step 2: Synthesis of Intermediate 16

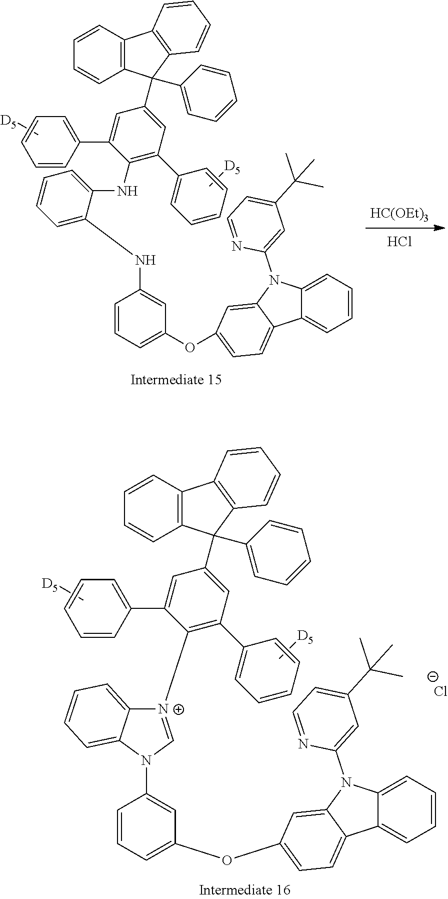

Under a nitrogen condition, Intermediate 15 (2.0 g, 2.0 mmol), triethyl orthoformate (14.8 g, 100 mmol) and concentrated hydrochloric acid (0.5 mL) were added to a flask, and the reaction was heated to 100° C. and stirred overnight. After TLC showed that the reaction was completed, the reaction solution was cooled to room temperature, concentrated, and purified through column chromatography to obtain Intermediate 16 (2.0 g, 1.9 mmol).

### Step 3: Compound Pt3-5

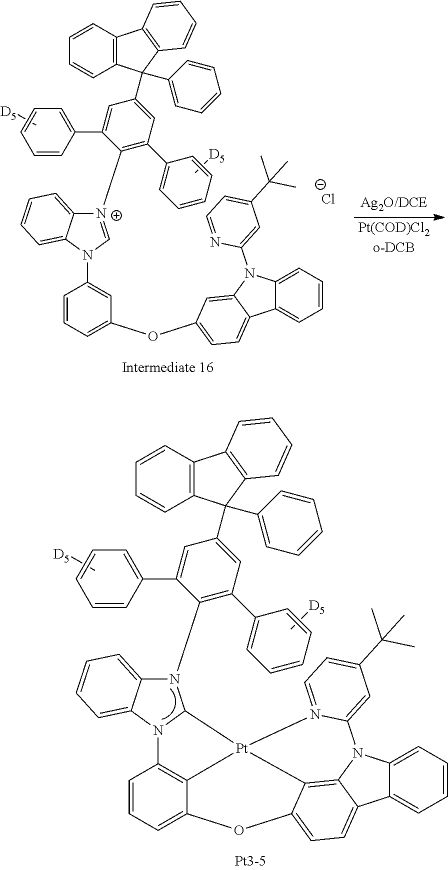

Under a nitrogen condition, Intermediate 16 (2.0 g, 1.9 mmol), Ag₂O (0.24 g, 1.0 mmol) and DCE (20 mL) were added to a flask and reacted for 12 h at room temperature. After the reaction was completed, the reaction solution was evaporated under reduced pressure to remove the solvent, and (1,5-cyclooctadiene)platinum dichloride (0.64 g, 1.7 mmol) was added. After o-dichlorobenzene (30 mL) was added, the reaction was heated to 190° C., stirred for 72 h, cooled to room temperature, and purified through column chromatography to obtain Compound Pt3-5 (0.85 g, 0.72 mmol). The product was identified as the target product with a molecular weight of 1179.4.

Those skilled in the art will appreciate that the above preparation methods are merely exemplary. Those skilled in the art can obtain other compound structures of the present disclosure through the modifications of the preparation methods.

Since the compound of Formula 1 of the present disclosure has a particular substituent having a structure represented by Formula 2, the compound achieves bluer and more saturated luminescence. The photoluminescence (PL) spectrum data provided below proves that the compound of the present disclosure has bluer and more saturated luminescence.

The photoluminescence (PL) spectrum data of Compound Pt1-41 of the present disclosure and Comparative Compounds Pt-A and Pt-B were measured using a fluorescence spectrophotometer F98 produced by SHANGHAI LENGGUANG TECHNOLOGY CO., LTD. Compounds in an example and comparative examples were each prepared into a solution with a concentration of 3×10⁻⁵ mol/L by using HPLC-grade toluene and then excited at room temperature (298 K) using light with a wavelength of 400 nm, and their emission spectrums were measured. Measurement results are shown in Table 1.

TABLE 1
PL spectrum data

| | Maximum Emission | Full Width at |
|---|---|---|
| Compound to | Wavelength | Half Maximum |
| be Measured | λₘₐₓ (nm) | (FWHM) (nm) |
| Pt1-41 | 465 | 26.84 |
| Pt-A | 523 | 84.23 |
| Pt-B | 474 | 36.97 |

The compounds to be measured have the following structures:

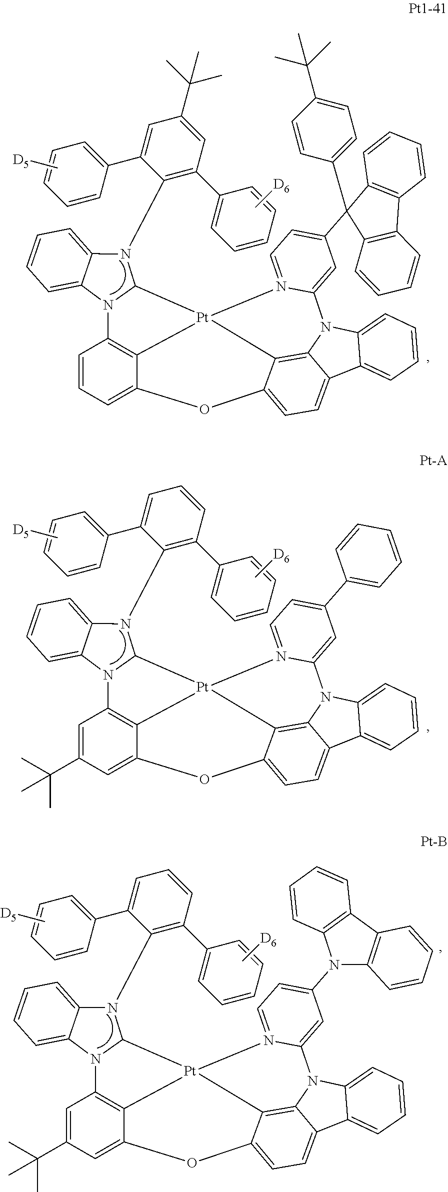

### DISCUSSION

Comparative Compound Pt-A is a Pt complex disclosed in the related art that has a phenyl substituent on the pyridine ring. Comparative Compound Pt-B is a Pt complex disclosed in the related art that has a carbazolyl substituent on the pyridine ring. As can be seen from the PL data in Table 1, Compound Pt1-41 of the present disclosure achieved blue phosphorescence emission due to its particular substituent of Formula 2. Compared with Compound Pt1-41 of the present disclosure, Comparative Compound Pt-A had a maximum emission wavelength greatly red-shifted by 58 nm and thus emitted green light and cannot achieve blue phosphorescence emission, and had a FWHM 57 nm wider. Compared with Compound Pt1-41 of the present disclosure, Comparative Compound Pt-B had a maximum emission wavelength red-shifted by 9 nm, and a FWHM 10 nm wider. It indicates that the compound of the present disclosure achieves bluer and more saturated luminescence due to its particular substituent of Formula 2, proving the uniqueness of the compound of Formula 1 of the present disclosure, which is difficult to predict for those skilled in the art and has a potential application value in blue phosphorescence.

A method for preparing an electroluminescent device is not limited herein. The preparation methods in the following examples are merely examples and are not to be construed as limiting. Based on the related art, those skilled in the art can make reasonable improvements on the preparation methods in the following examples. Exemplarily, the proportions of various materials in a light-emitting layer are not particularly limited. Those skilled in the art can reasonably select the proportions within a certain range based on the related art. For example, taking the total weight of the materials in the light-emitting layer as reference, a host material may account for 80% to 99% and a light-emitting material may account for 1% to 20%; or the host material may account for 85% to 99% and the light-emitting material may account for 1% to 15%. Additionally, the host material may include one material or two materials, where the ratio of two host materials may be 99:1 to 1:99; or the ratio may be 80:20 to 20:80. In embodiments of a device, the characteristics of the device are tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to those skilled in the art.

### Device Example

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms per second and a vacuum degree of about 10⁻⁸ Torr. Compound HT and Compound HI were co-deposited (at a weight ratio of 97:3) for use as a hole injection layer (HIL) with a thickness of 100 Å. Compound HT was used as a hole transporting layer (HTL) with a thickness of 250 Å. Compound EB was used as an electron blocking layer (EBL) with a thickness of 50 Å. Then, Compound N-1 as a first host, Compound P-1 as a second host and a first compound Pt1-41 as a dopant were co-deposited (at a weight ratio of 26.4:61.6:12) for use as an emissive layer (EML) with a thickness of 350 Å. Compound N-1 was used as a hole blocking layer (HBL) with a thickness of 50 Å. On the HBL, Compound ET and 8-hydroxyquinolinolato-lithium (Liq) were co-deposited (at a weight ratio of 40:60) for use as an electron transporting layer (ETL) with a thickness of 310 Å. Finally, LiF was deposited for use as an electron injection layer with a thickness of 15 Å and Al was deposited for use as a cathode with a thickness of 1200 Å. The device was transferred back to the glovebox and encapsulated with a glass lid and a moisture getter to complete the device.

### Device Example 2

Device Example 2 was prepared by the same method as Device Example 1, except that Compound Pt1-41 was replaced with Compound Pt2-39 in the emissive layer (EML).

### Device Comparative Example 1

Device Comparative Example 1 was prepared by the same method as Device Example 1, except that Compound Pt1-41 was replaced with Compound Pt-C in the emissive layer (EML).

Detailed structures and thicknesses of layers of the devices are shown in the following table. A layer using more than one material is obtained by doping different compounds at their weight ratio as recorded.

TABLE 2
Part of device structures of the device examples and comparative example

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | EB | P-1:Compound | N-1 | ET:Liq |
| | HI (97:3) | (250 Å) | (50 Å) | N-1:Compound | (50 Å) | (40:60) |
| | (100 Å) | | | Pt1-41 | | (310 Å) |
| | | | | (61.6:26.4:12) | | |
| | | | | (350 Å) | | |
| Example 2 | Compound | Compound | Compound | Compound | Compound | Compound |
| | HT:Compound | HT | EB | P-1:Compound | N-1 | ET:Liq |
| | HI (97:3) | (250 Å) | (50 Å) | N-1:Compound | (50 Å) | (40:60) |
| | (100 Å) | | | Pt2-39 | | (310 Å) |
| | | | | (61.6:26.4:12) | | |
| | | | | (350 Å) | | |
| Comparative | Compound | Compound | Compound | Compound | Compound | Compound |
| Example 1 | HT:Compound | HT | EB | P-1:Compound | N-1 | ET:Liq |
| | HI (97:3) | (250 Å) | (50 Å) | N-1:Compound | (50 Å) | (40:60) |
| | (100 Å) | | | Pt-C | | (310 Å) |
| | | | | (61.6:26.4:12) | | |
| | | | | (350 Å) | | |

The materials used in the devices have the following structures:

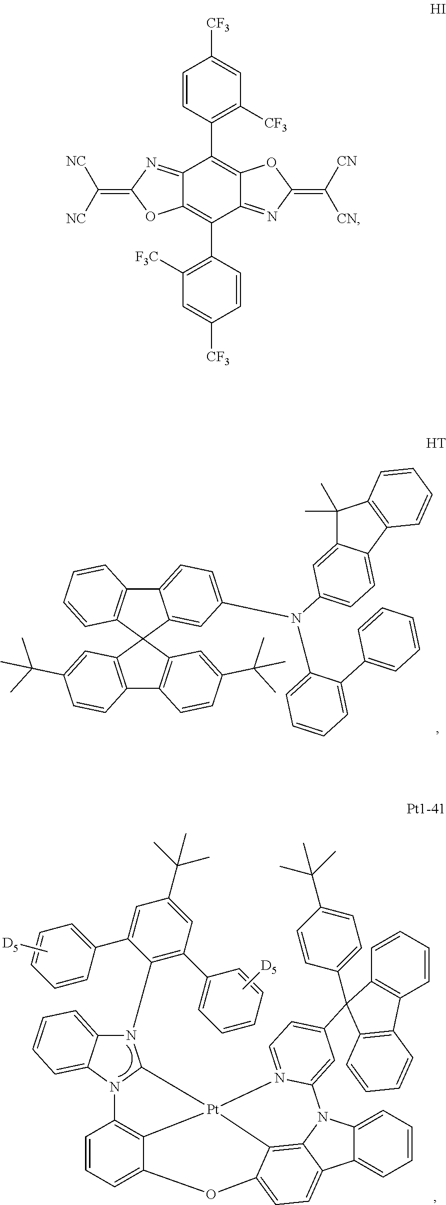

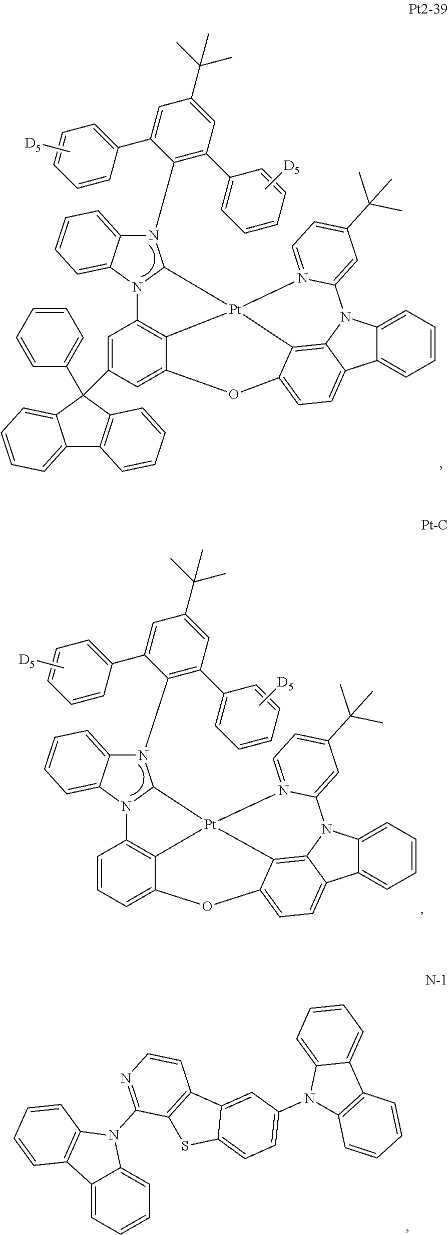

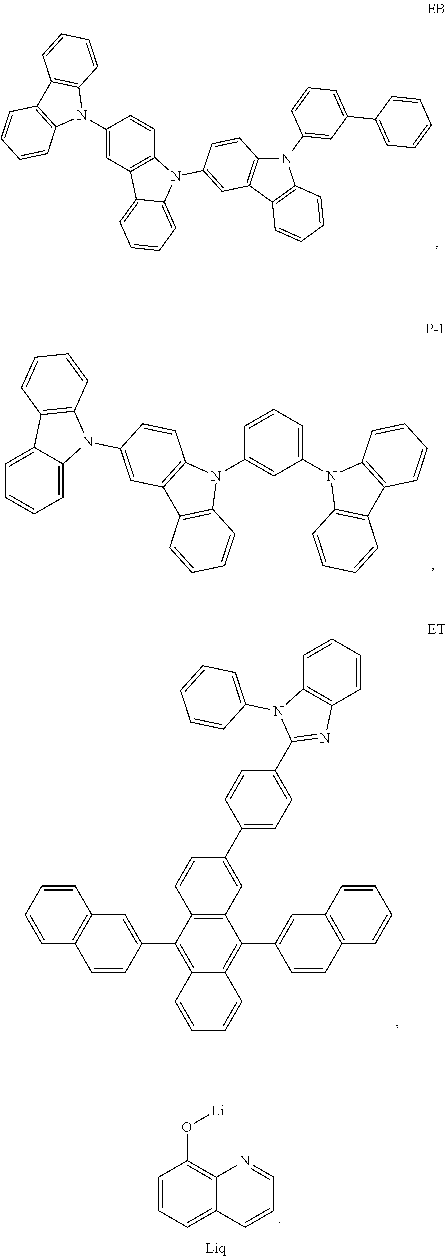

The CIE values and current efficiency (CE, cd/A) of Examples 1 and 2 and Comparative Example 1 were measured at 1000 cd/in². The related data are shown in Table 3.

TABLE 3
Device data

| Device ID | CIE (x, y) | CE (cd/A) |
|---|---|---|
| Example 1 | 0.127, 0.181 | 30.55 |
| Example 2 | 0.130, 0.191 | 27.59 |
| Comparative Example 1 | 0.132, 0.131 | 21.56 |

As can be seen from the data in Table 3, the examples achieved blue phosphorescence emission. Comparative Example 1 used Comparative Compound Pt-C disclosed in the related art that has an alkyl substitution, and had relatively high CE among blue phosphorescent devices. Example 1 used Compound Pt1-41 of the present disclosure that has a particular substitution structure of Formula 2, and further improved the CE by 41.7% based on the relatively high CE of Comparative Example 1 and achieved a significant improvement. Example 2 used another compound Pt2-39 of the present disclosure, and improved the CE by 27.9% compared with Comparative Example 1. Such significant improvements in current efficiency are unexpected. These compounds of the present disclosure that have high CE have a potential application value in blue phosphorescence.

The above results indicate that the compound of Formula 1 of the present disclosure that has a particular substitution of Formula 2, as a light-emitting material, can achieve the device performance of high efficiency, which is of great help in improving the level of blue phosphorescent devices.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A compound having a structure of Formula 1: 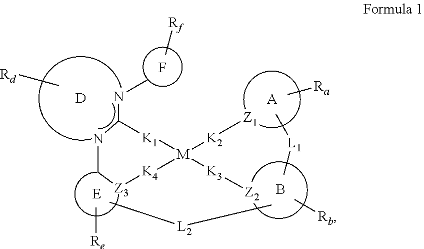
wherein in Formula 1,
the ring A, the ring B, the ring E and the ring F are, at each occurrence identically or differently, selected from an unsaturated carbocyclic ring having 5 to 30 carbon atoms, an unsaturated heterocyclic ring having 3 to 30 carbon atoms or a combination thereof;
the ring D is, at each occurrence identically or differently, selected from an unsaturated heterocyclic ring having 1 to 30 carbon atoms;
the metal M is selected from a metal with a relative atomic mass greater than 40;
L₁ and L₂ are, at each occurrence identically or differently, selected from a single bond, O, S, Se, (SiR′R′)_{y}, PR′, NR′, (CR′R′)_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
K₁ to K₄ are, at each occurrence identically or differently, selected from a single bond, O or S;
Z₁ to Z₃ are, at each occurrence identically or differently, selected from C or N;
Rₐ, R_{b}, R_{d}, Rₑ and R_{f} represent, at each occurrence identically or differently, mono-substitution, multiple substitutions or non-substitution;
at least one of Rₐ, R_{b}, R_{d}, Rₑ and R_{f} is present and is a substituent R, wherein the substituent R has a structure represented by Formula 2: 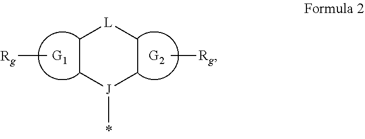
wherein in Formula 2, “*” represents a position where Formula 2 is joined;
R_{g} represents, at each occurrence identically or differently, mono-substitution, multiple substitutions or non-substitution;
the ring G₁ and the ring G₂ are, at each occurrence identically or differently, selected from a carbocyclic ring having 3 to 30 ring atoms, a heterocyclic ring having 3 to 30 ring atoms or a combination thereof,
J is, at each occurrence identically or differently, selected from P, P(O), CR″, SiR″ or GeR″;
L is selected from a single bond, O, S, SO₂, Se, NR″′, CR″R″′, SiR″R″′, GeR″R″′, BR″′, PR″′, P(O)R″′, substituted or unsubstituted alkylene having 2 to 20 carbon atoms, substituted or unsubstituted heteroalkylene having 1 to 20 carbon atoms, substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;
Rₐ, R_{b}, R_{d}, Rₑ, R_{f}, R_{g}, R′, R″ and R″′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{d}, Rₑ, R_{f}, R_{g}, R′, R″, R″′ can be optionally joined to form a ring.

2. The compound of claim 1, wherein at least one of the Rₐ is present and is the substituent R; at least one of the Rₑ is present and is the substituent R; or at least one of the R_{f} is present and is the substituent R.

3. The compound of claim 1, wherein M is selected from Cu, Ag, Au, Ru, Rh, Pd, Os, Ir or Pt; preferably, M is selected from Pt or Pd; more preferably, M is selected from Pt.

4. The compound of claim 1, wherein the ring A, the ring B, the ring E and the ring F are, at each occurrence identically or differently, selected from a five-membered unsaturated carbocyclic ring, an aromatic ring having 6 to 30 carbon atoms or a heteroaromatic ring having 3 to 30 carbon atoms; and the ring D is, at each occurrence identically or differently, selected from an unsaturated heterocyclic ring having 1 to 18 carbon atoms;
preferably, the ring A, the ring B, the ring E and the ring F are, at each occurrence identically or differently, selected from a five-membered unsaturated carbocyclic ring, an aromatic ring having 6 to 18 carbon atoms or a heteroaromatic ring having 3 to 18 carbon atoms; and the ring D is, at each occurrence identically or differently, selected from an unsaturated heterocyclic ring having 1 to 12 carbon atoms;
more preferably, the ring A, the ring B, the ring E and the ring F are, at each occurrence identically or differently, selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring, an imidazole ring or a combination thereof; and the ring D is, at each occurrence identically or differently, selected from an imidazolecarbene ring or a benzimidazolecarbene ring.

5. The compound of claim 1, wherein the ring G₁ and the ring G₂ are, at each occurrence identically or differently, selected from a carbocyclic ring having 5 to 18 ring atoms, an unsaturated heterocyclic ring having 5 to 18 ring atoms or a combination thereof;
preferably, the ring G₁ and the ring G₂ are, at each occurrence identically or differently, selected from a cyclopentane ring, a cyclohexane ring, a benzene ring, a pyridine ring, an indene ring, a fluorene ring, an indole ring, a carbazole ring, a benzofuran ring, a benzosilole ring, a benzothiophene ring, a cyclopentadiene ring, a furan ring, a thiophene ring, a silole ring or a combination thereof.

6. The compound of claim 1, wherein L₁ is selected from a single bond, O, S, (SiR′R′)_{y}, NR′, (CR′R′)_{y} or a combination thereof, wherein y is 1 or 2;
preferably, L₁ is selected from a single bond, O or S;
more preferably, L₁ is selected from a single bond.

7. The compound of claim 1, wherein K₁ to K₄ are selected from a single bond.

8. The compound of claim 1, wherein Z₁ is selected from N, and Z₂ and Z₃ are selected from C.

9. The compound of claim 1, wherein the compound has a structure represented by one of Formula 1-1 to Formula 1-15: 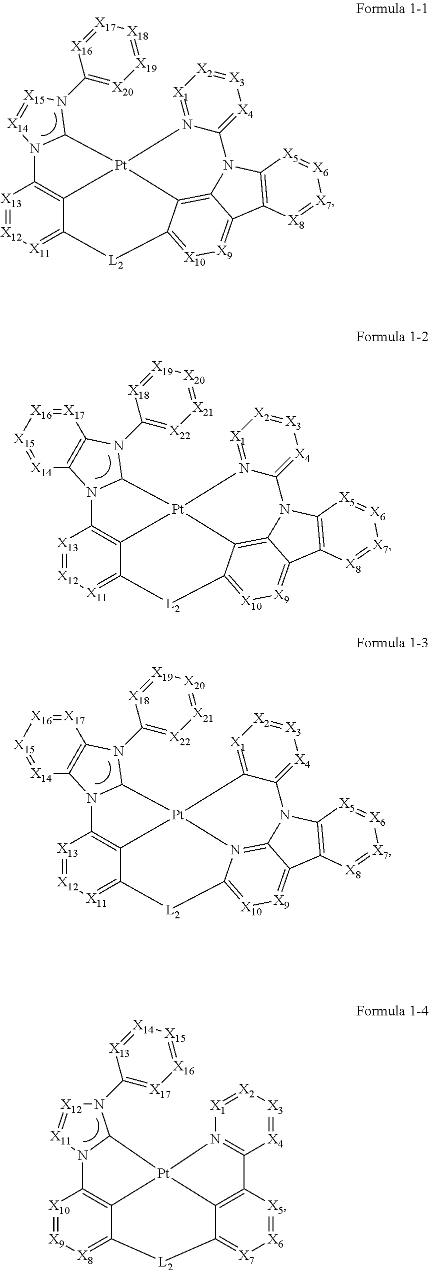 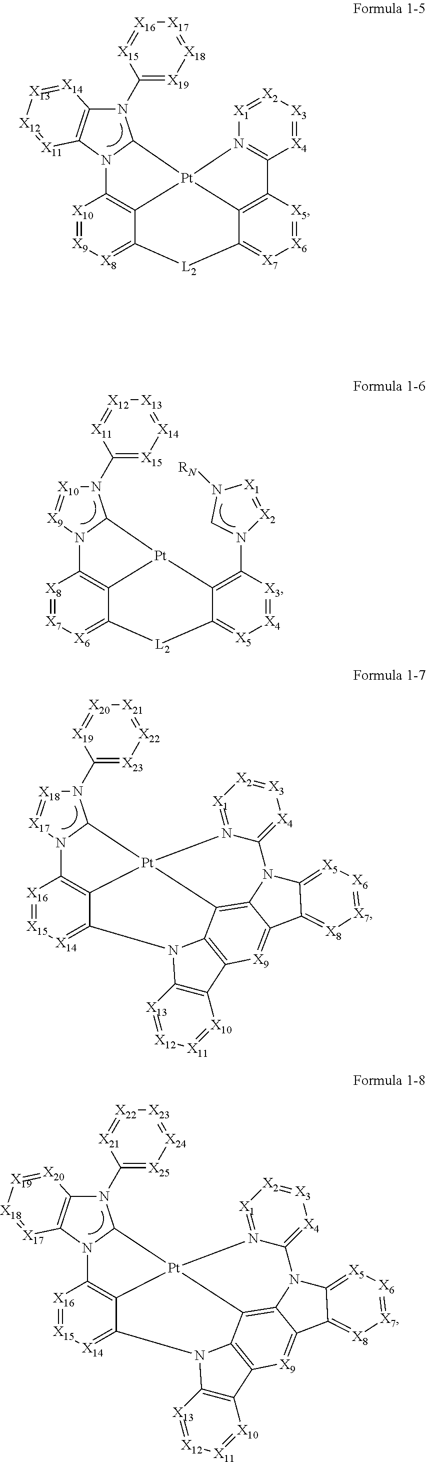 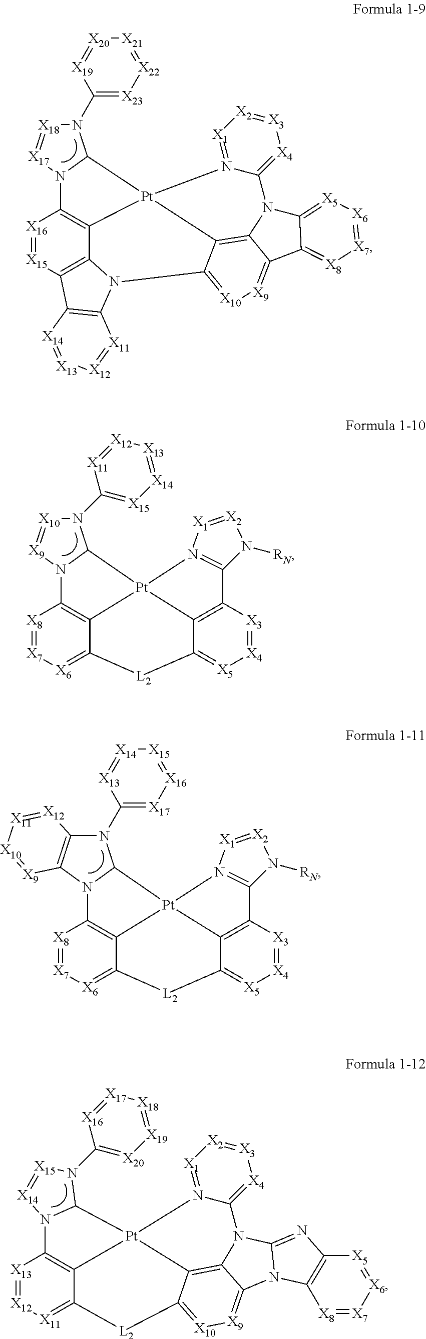 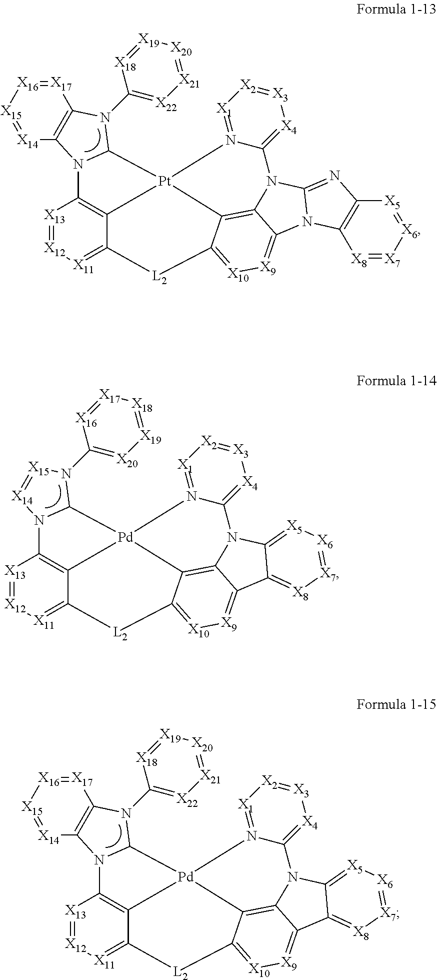
wherein in Formula 1-1 to Formula 1-15,
L₂ is, at each occurrence identically or differently, selected from a single bond, O, S, Se, (SiR′R′)_{y}, PR′, NR′, (CR′R′)_{y}, substituted or unsubstituted arylene having 6 to 30 carbon atoms, substituted or unsubstituted heteroarylene having 3 to 30 carbon atoms or a combination thereof,
y is, at each occurrence identically or differently, selected from 1, 2, 3, 4 or 5;
X₁ to X₂₅ are, at each occurrence identically or differently, selected from CR, CRₓ or N, and at least one of X₁ to Xᵢ is selected from CR, wherein the R has a structure represented by Formula 2-1, and Xᵢ corresponds to one of X₁ to X₂₅ that has the largest serial number in any one of Formula 1-1 to Formula 1-15: 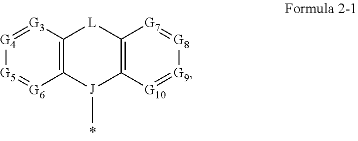
G₃ to G₁₀ are, at each occurrence identically or differently, selected from CR_{g} or N;
J is, at each occurrence identically or differently, selected from CR″ or SiR″;
L is selected from a single bond, O, S, SO₂, Se, NR″′, CR″R″′, SiR″R″′, GeR″R″′, BR″′, PR″′, P(O)R″′, substituted or unsubstituted alkylene having 2 to 20 carbon atoms, substituted or unsubstituted heteroalkylene having 1 to 20 carbon atoms, substituted or unsubstituted cycloalkylene having 3 to 20 ring carbon atoms, substituted or unsubstituted heterocyclylene having 3 to 20 ring atoms, substituted or unsubstituted arylene having 6 to 30 carbon atoms, substituted or unsubstituted heteroarylene having 3 to 30 carbon atoms or a combination thereof;
R′, R″, R″′, Rₓ, R_{g} and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents R′, R″, R″′, Rₓ, R_{g}, R_{N} can be optionally joined to form a ring;
preferably, the compound has a structure represented by Formula 1-1 or Formula 1-2.

10. The compound of claim 9, wherein L₂ is selected from a single bond, O, S, (SiR′R′)_{y}, NR′, (CR′R′)_{y} or a combination thereof, wherein y is 1 or 2, and the R′ is, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof,
preferably, L₂ is selected from a single bond, O or S;
more preferably, L₂ is selected from O.

11. The compound of claim 1, wherein L is selected from a single bond, O, S, Se, NR″′, CR″R″′, SiR″R″′, GeR″′R′″, PR″′ or P(O)R″′, and the R″′ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof,
preferably, L is selected from a single bond.

12. The compound of claim 9, wherein G₃ to G₁₀ are, at each occurrence identically or differently, selected from CR_{g}, and the R_{g} is, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof,
preferably, the R_{g} is, at each occurrence identically or differently, selected from the group consisting of: hydrogen, deuterium, fluorine, cyano, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

13. The compound of claim 9, wherein the R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof,
preferably, the R″ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, substituted or unsubstituted phenyl, substituted or unsubstituted pyridyl and combinations thereof.

14. The compound of claim 1, wherein the substituent R is, at each occurrence identically or differently, selected from the group consisting of structures Jn-1 to Jn-70: 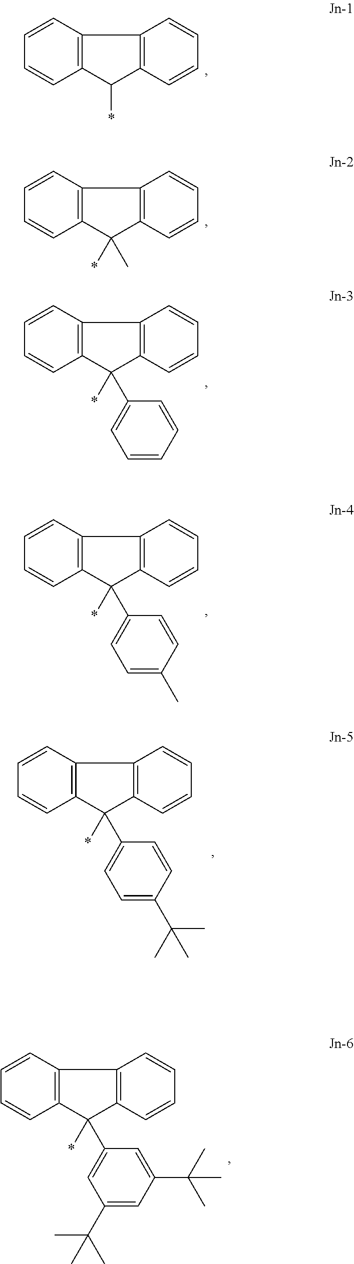 [SMILES: *C1c2ccccc2-c2ccccc21 ; *C1(C)c2ccccc2-c2ccccc21 ; *C1(c2ccccc2)c2ccccc2-c2ccccc21 ; *C1(c2ccc(C)cc2)c2ccccc2-c2ccccc21 ; *C1(c2ccc(C(C)(C)C)cc2)c2ccccc2-c2ccccc21 ; *C1(c2cc(C(C)(C)C)cc(C(C)(C)C)c2)c2ccccc2-c2ccccc21] 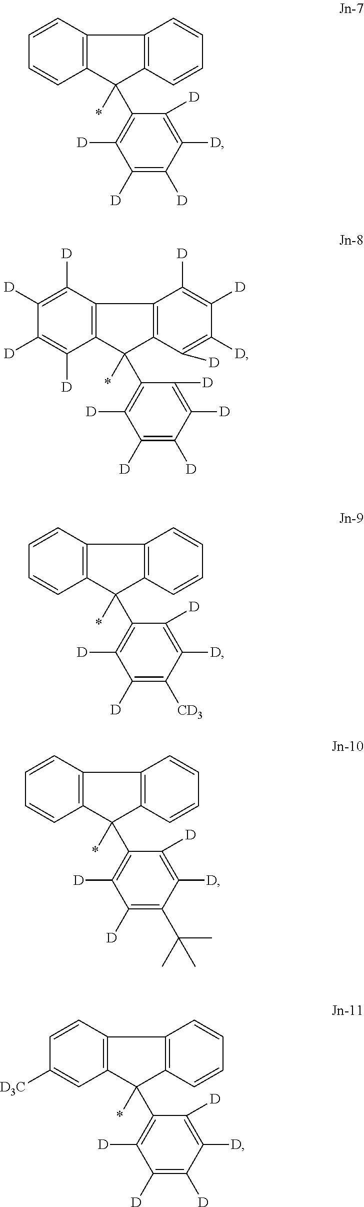 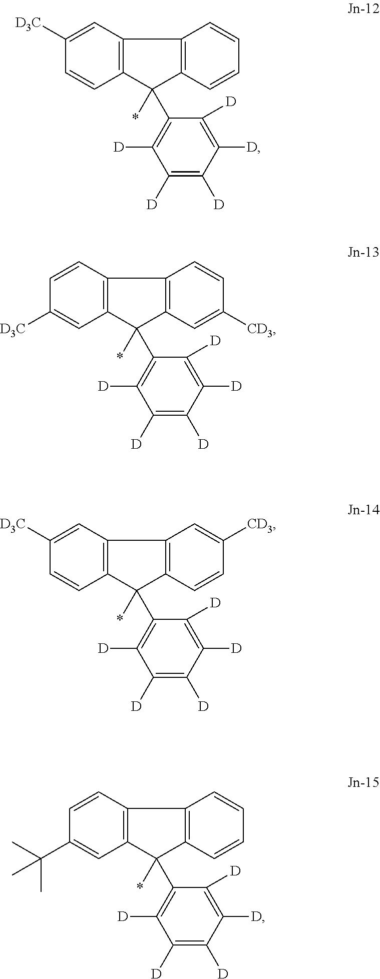 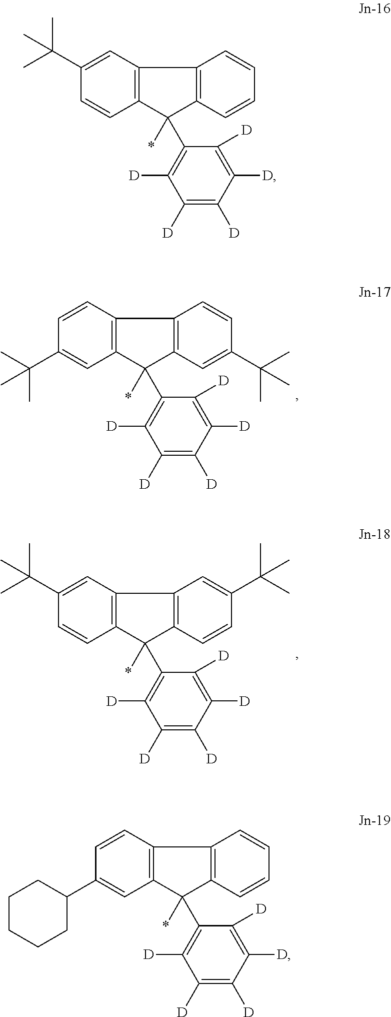 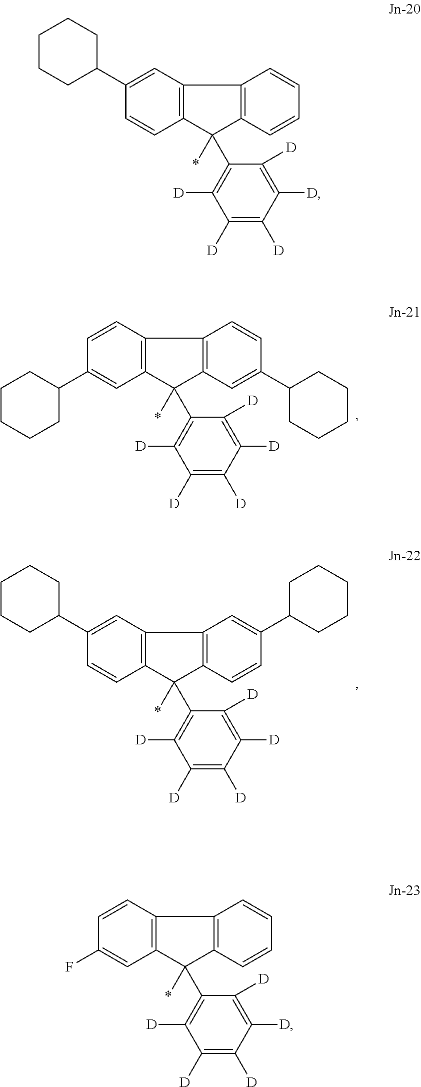 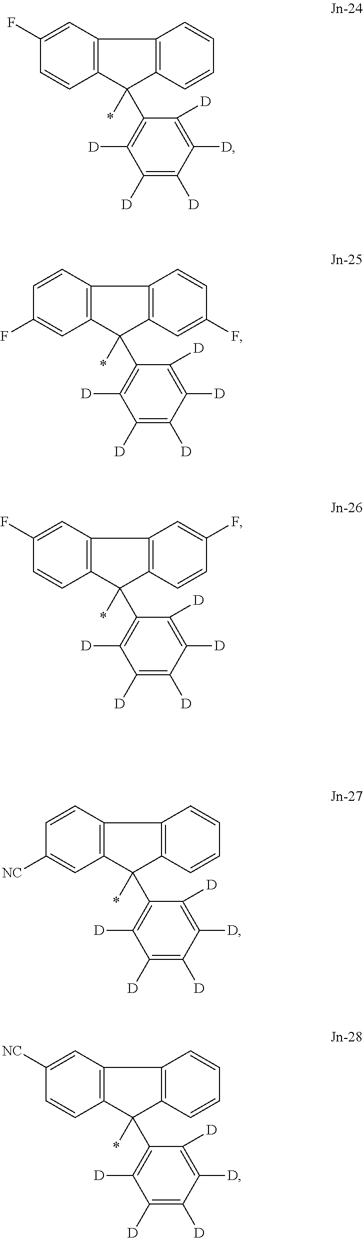 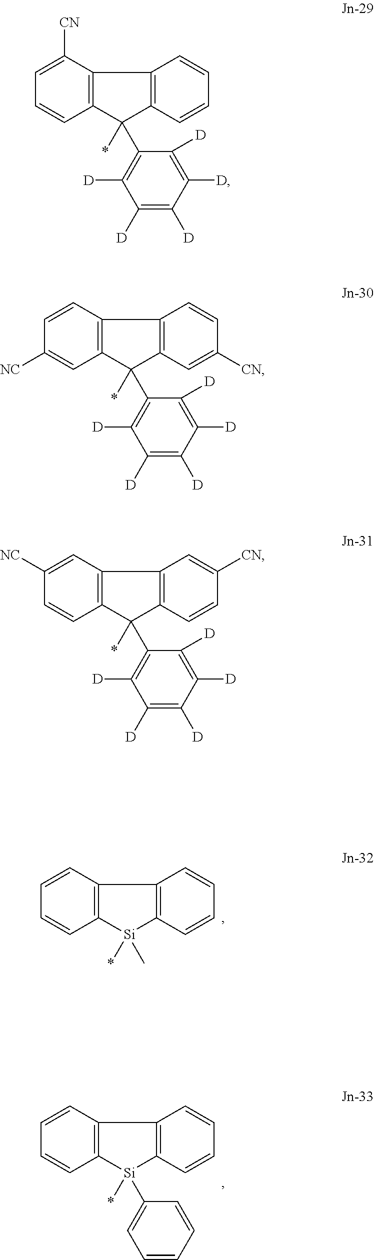 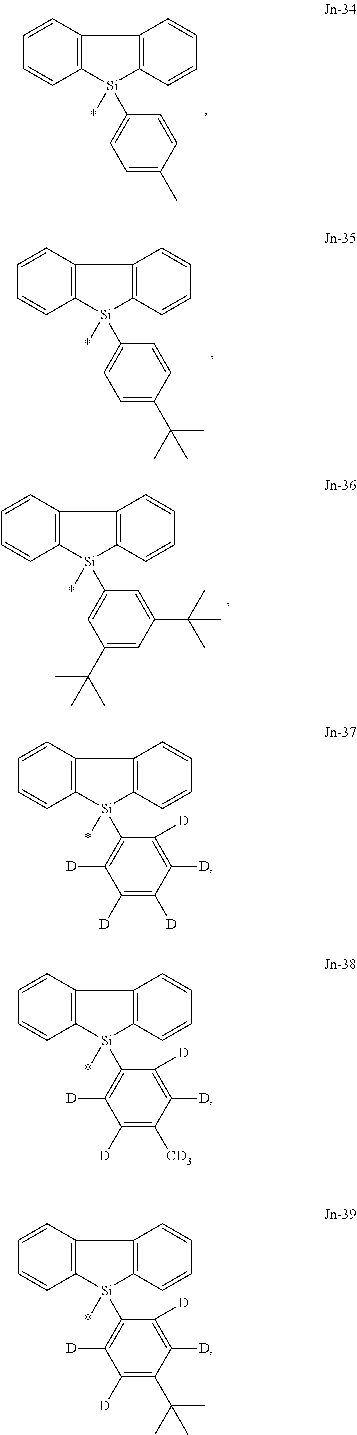 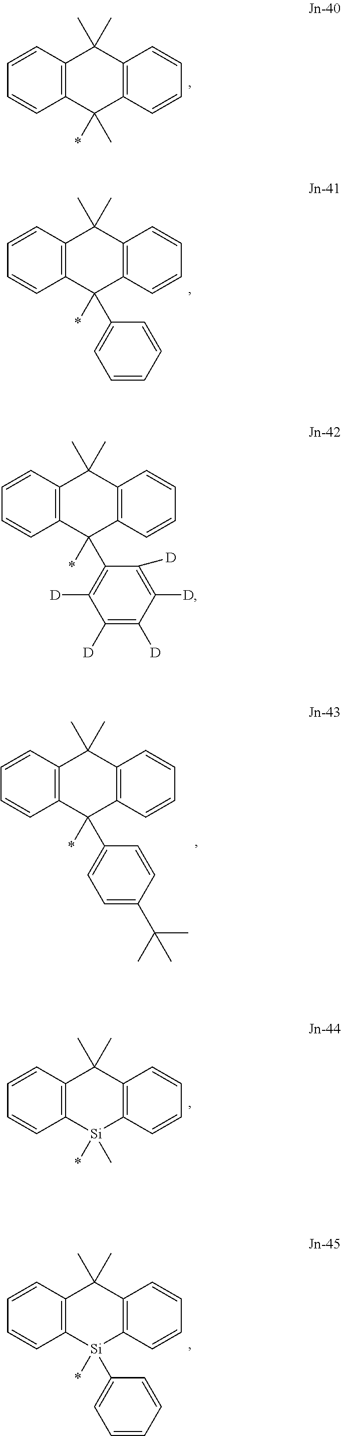 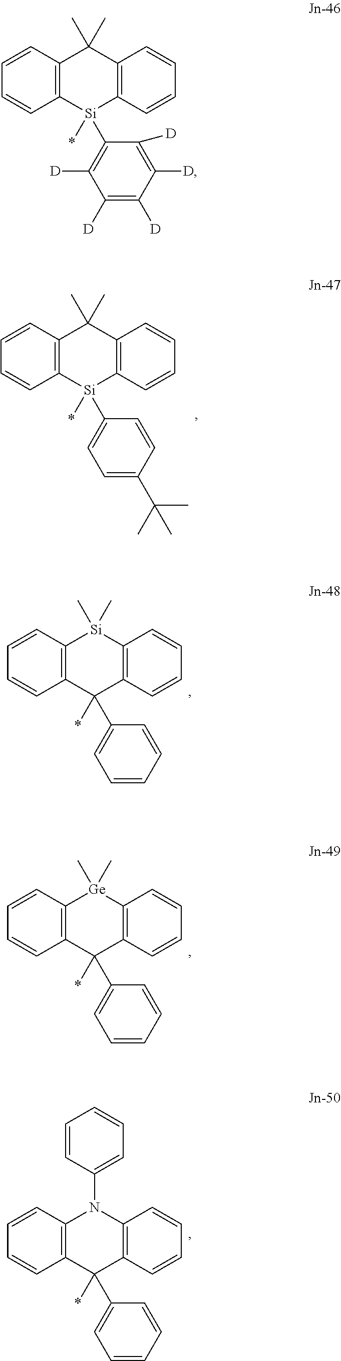 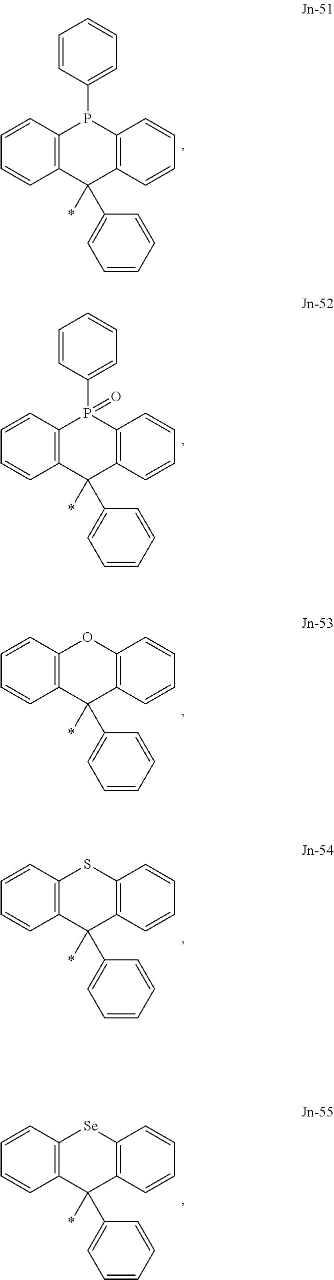 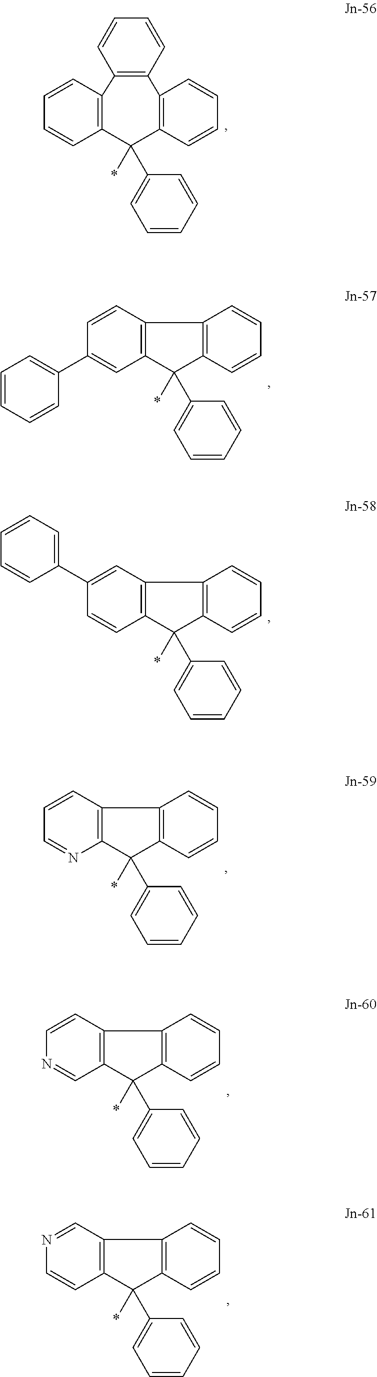 [SMILES: *C1(c2ccccc2)c2ccccc2-c2ccccc2-c2ccccc21 ; *C1(c2ccccc2)c2ccccc2-c2ccc(-c3ccccc3)cc21 ; *C1(c2ccccc2)c2ccccc2-c2cc(-c3ccccc3)ccc21 ; *C1(c2ccccc2)c2ccccc2-c2cccnc21 ; *C1(c2ccccc2)c2ccccc2-c2ccncc21 ; *C1(c2ccccc2)c2ccccc2-c2cnccc21] 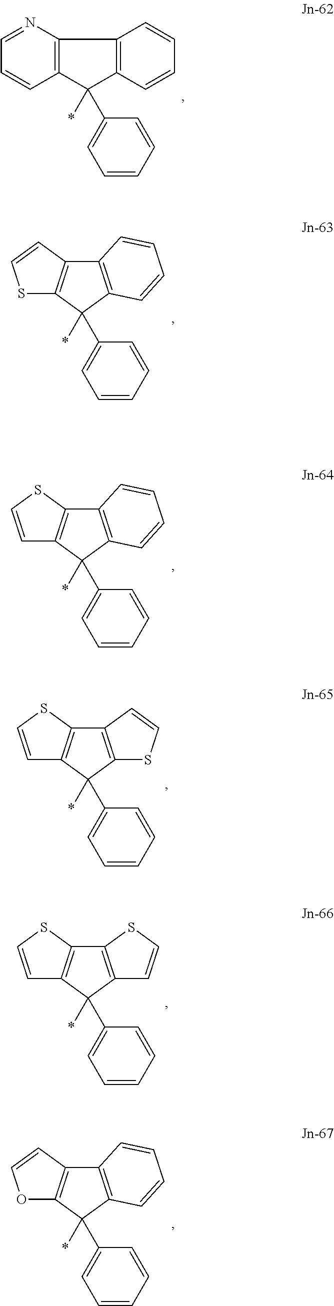 [SMILES: *C1(c2ccccc2)c2ccccc2-c2ncccc21 ; *C1(c2ccccc2)c2ccccc2-c2ccsc21 ; *C1(c2ccccc2)c2ccccc2-c2sccc21 ; *C1(c2ccccc2)c2ccsc2-c2ccsc21 ; *C1(c2ccccc2)c2ccsc2-c2sccc21 ; *C1(c2ccccc2)c2ccccc2-c2ccoc21] 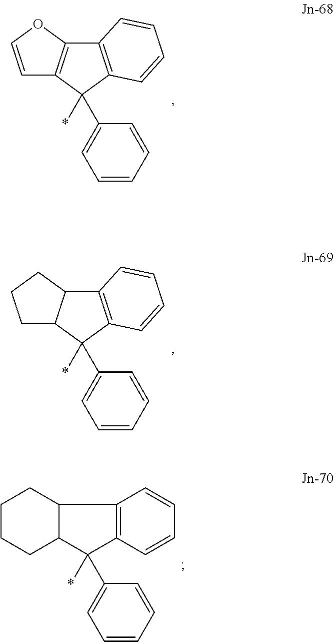 [SMILES: *C1(c2ccccc2)c2ccccc2-c2occc21 ; *C1(c2ccccc2)c2ccccc2C2CCCC21 ; *C1(c2ccccc2)c2ccccc2C2CCCCC21]
wherein optionally, hydrogens in the structures Jn-1 to Jn-70 can be partially or fully substituted with deuterium.

15. The compound of claim 1, wherein the compound is selected from the group consisting of: Compound Pt1-1 to Compound Pt1-164, Compound Pt2-1 to Compound Pt2-176, Compound Pt3-1 to Compound Pt3-80, and Compound Pt4-1 to Compound Pt4-32:

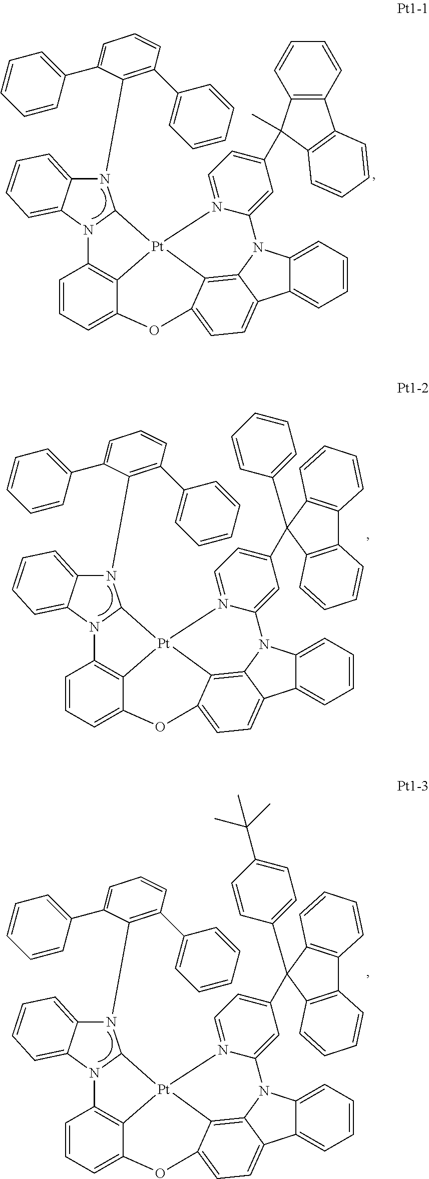

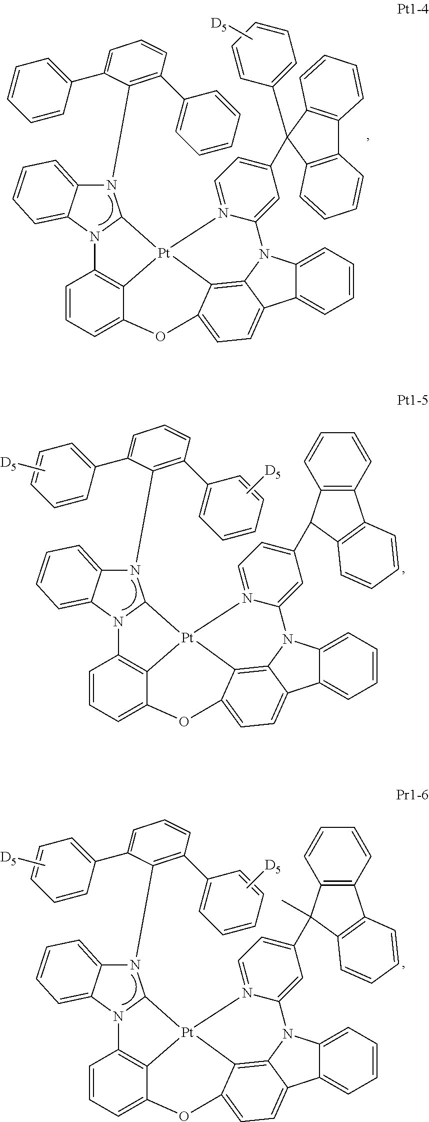

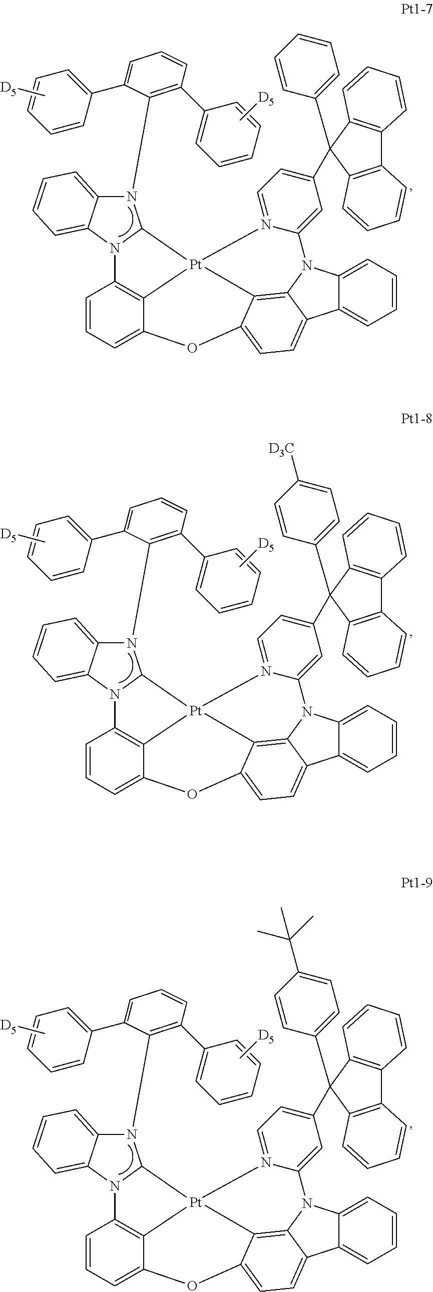

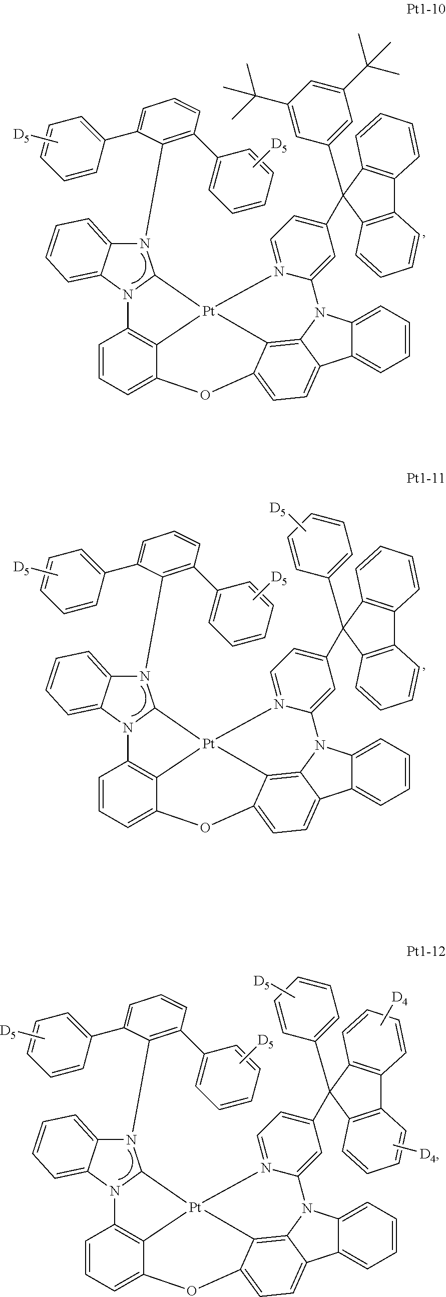

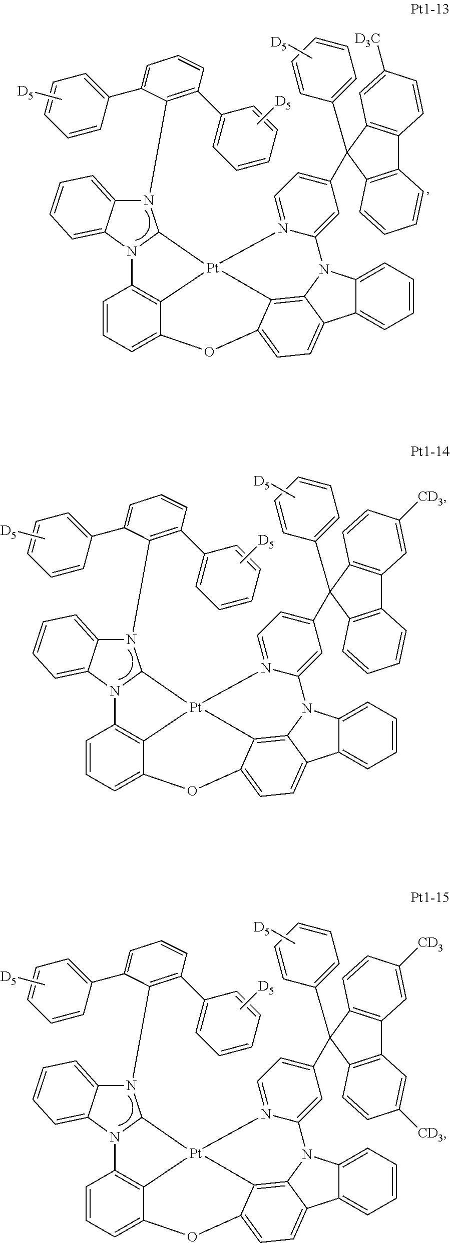

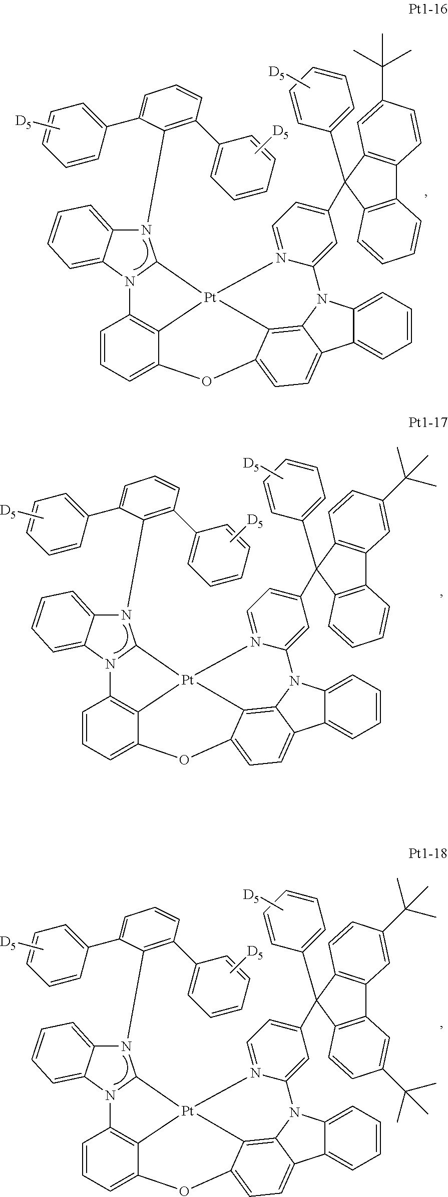

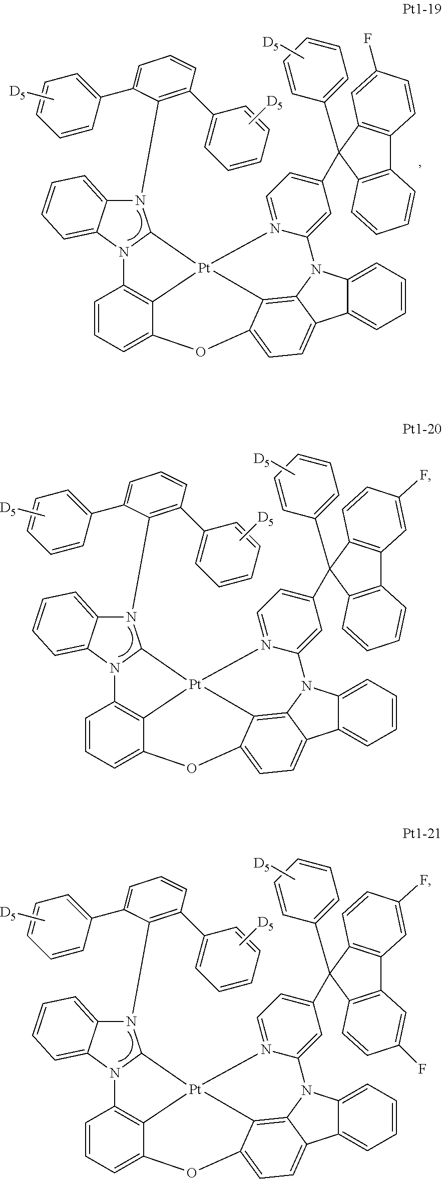

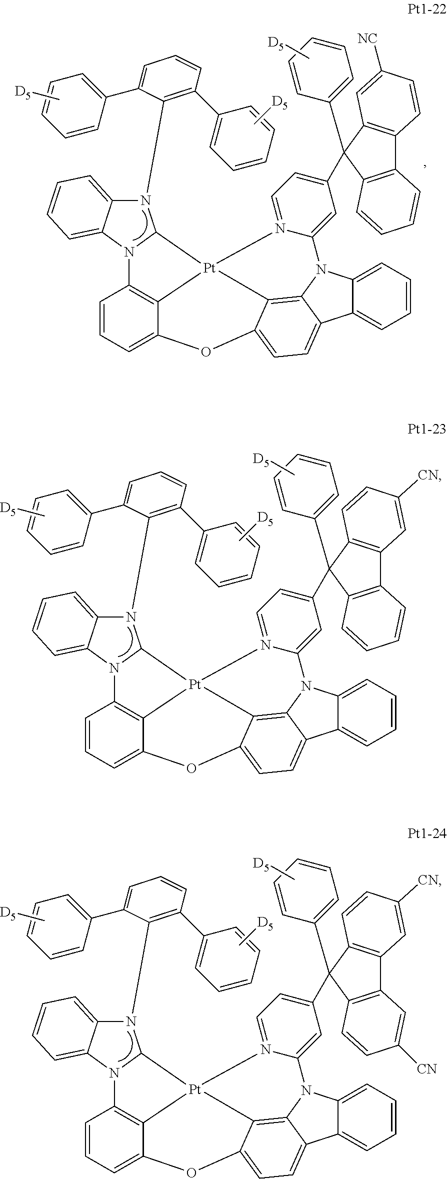

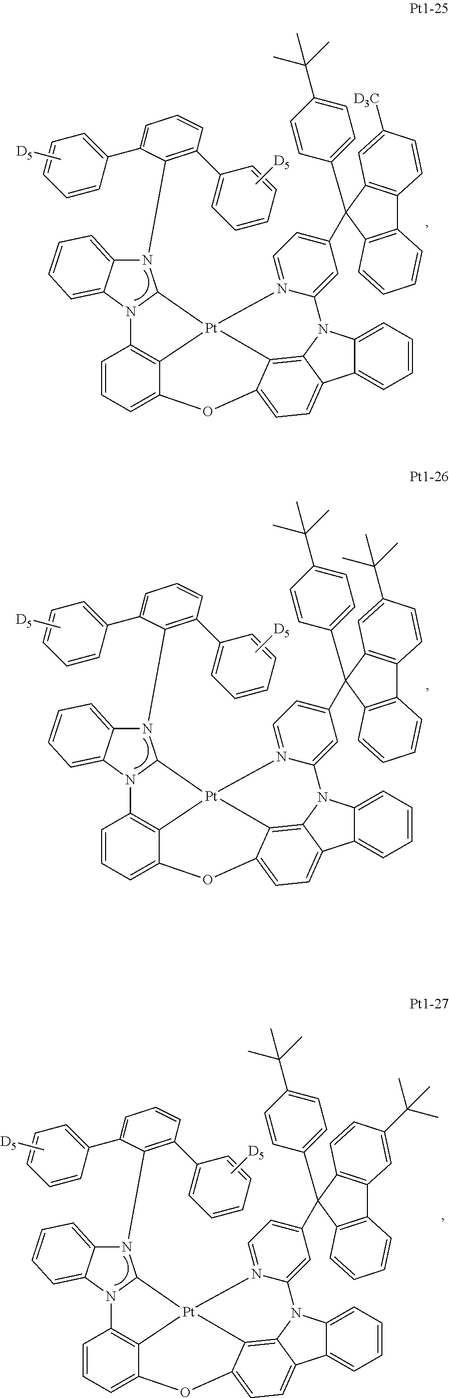

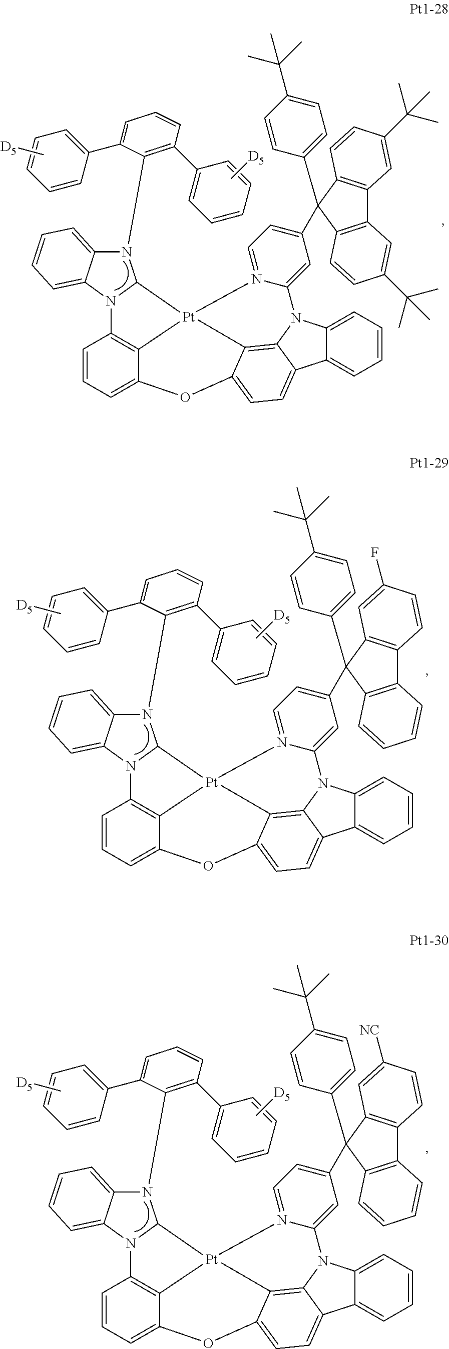

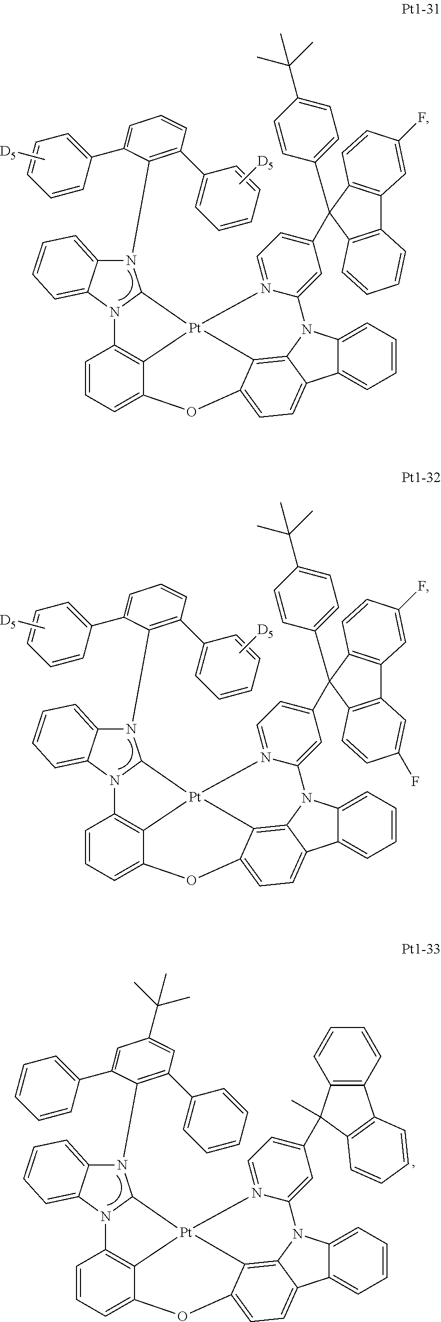

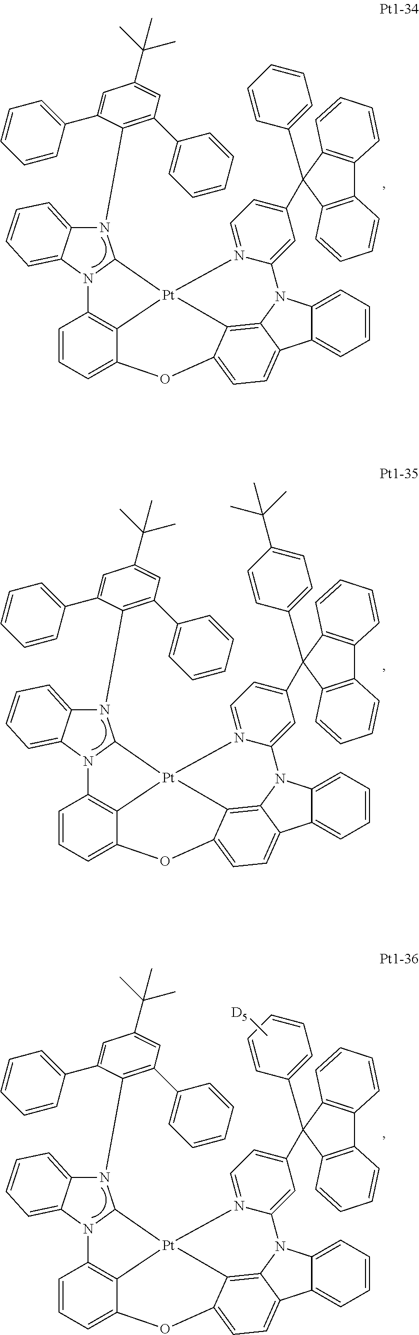

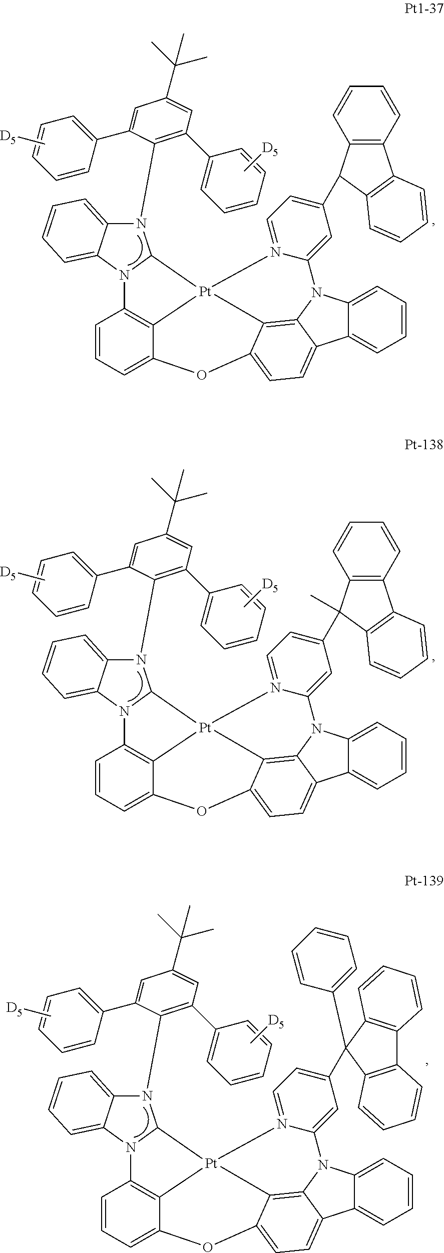

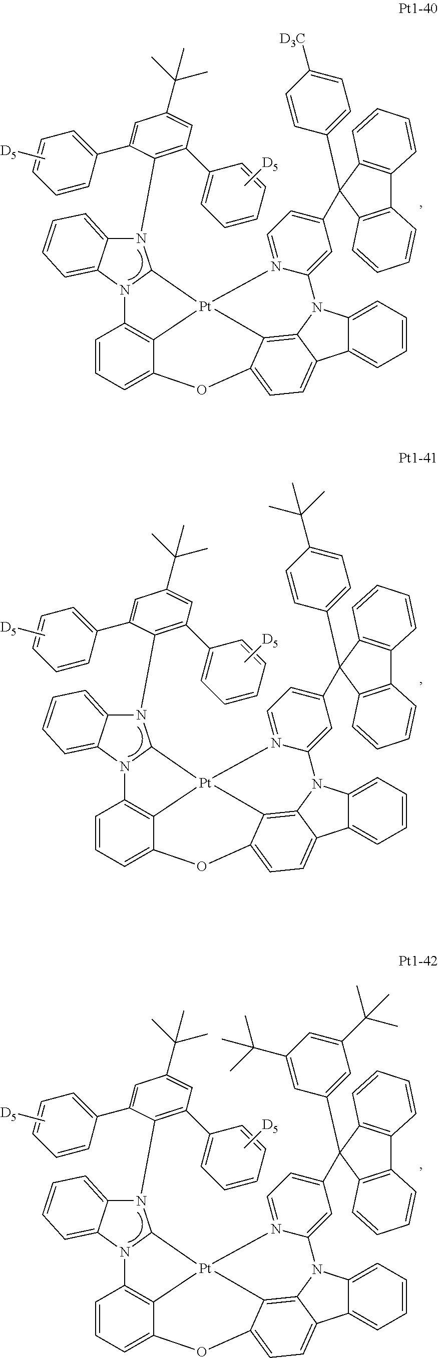

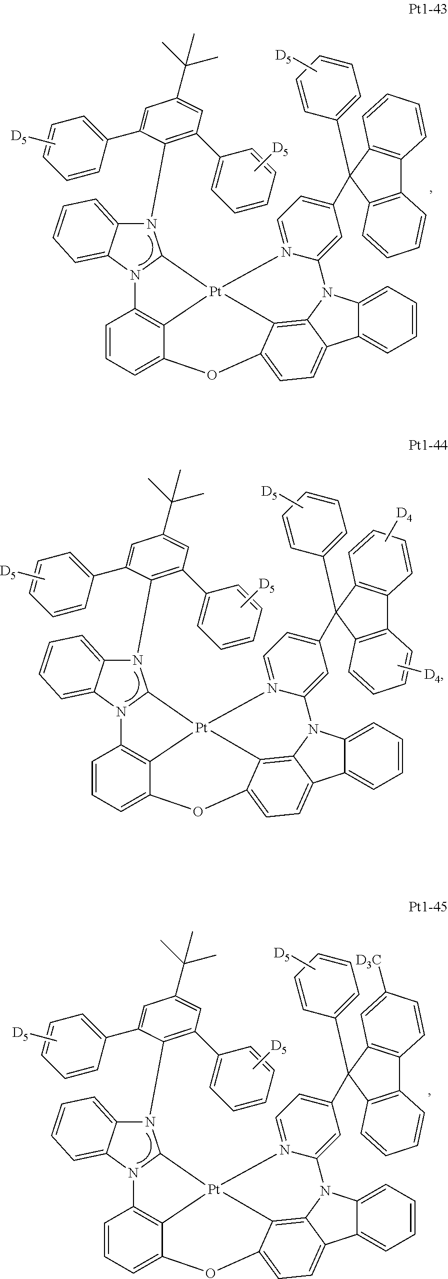

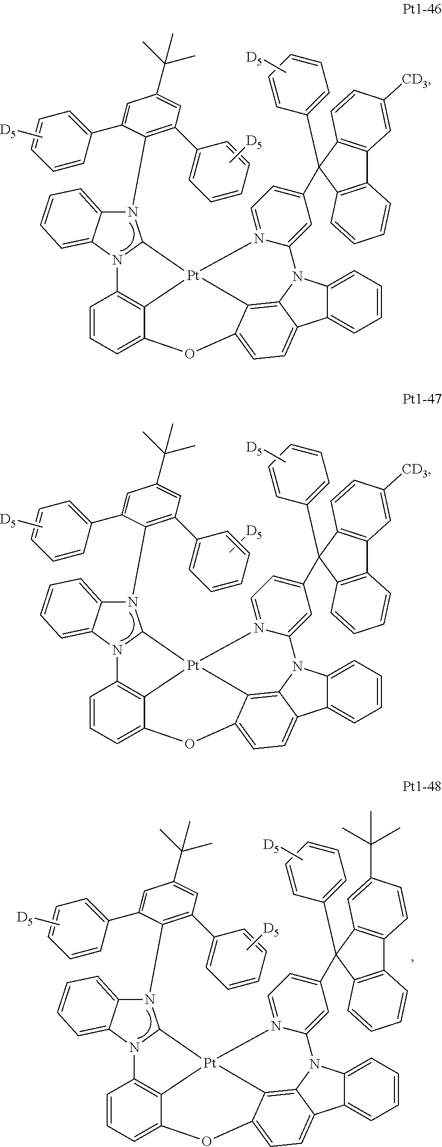

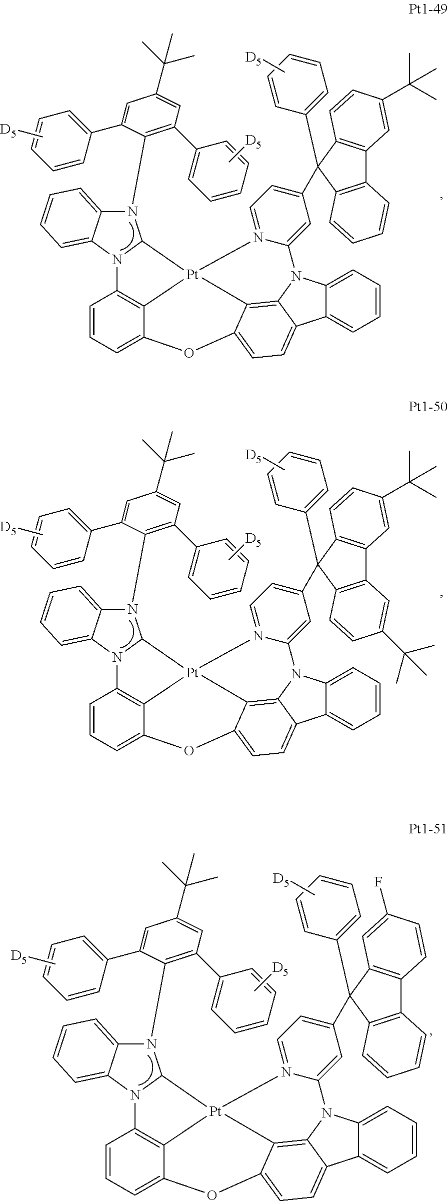

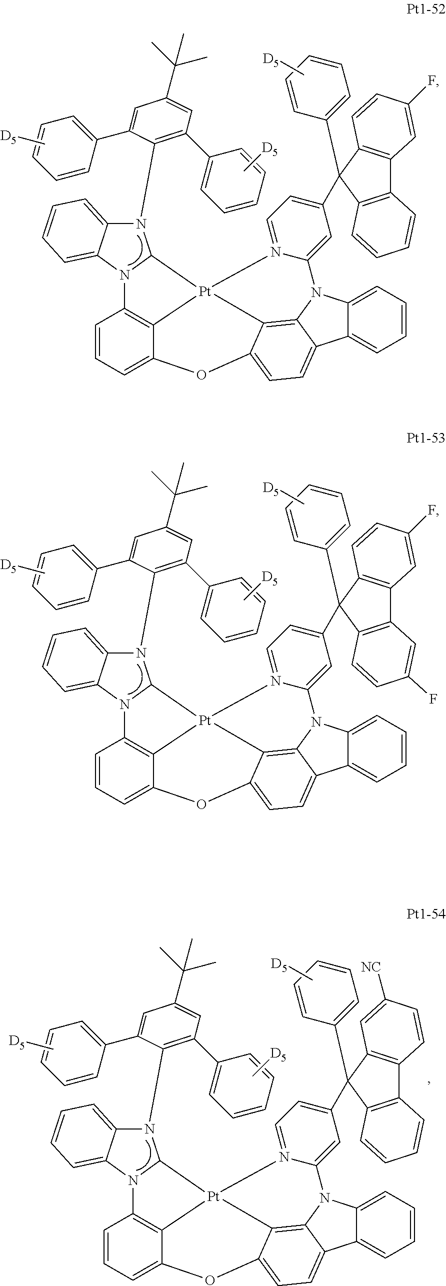

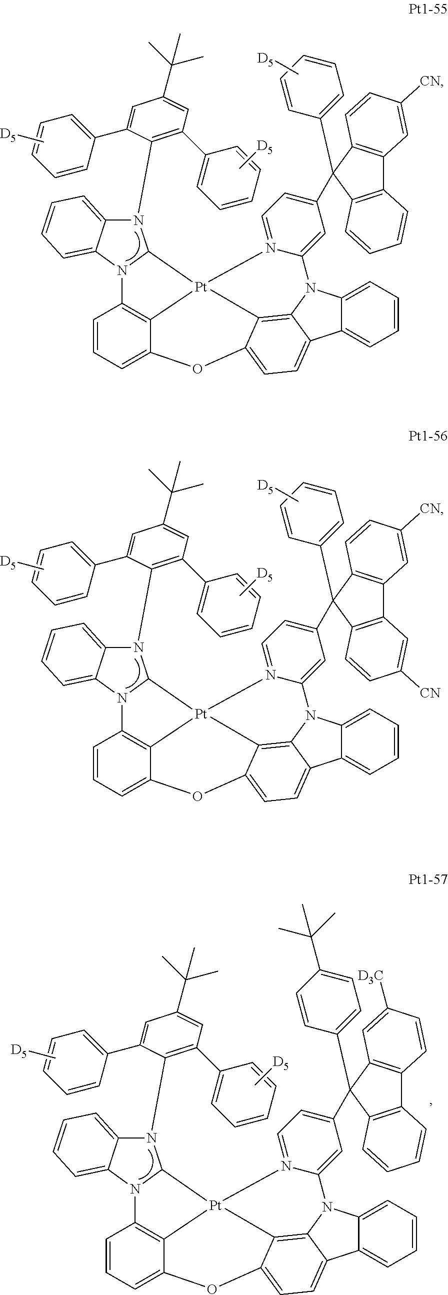

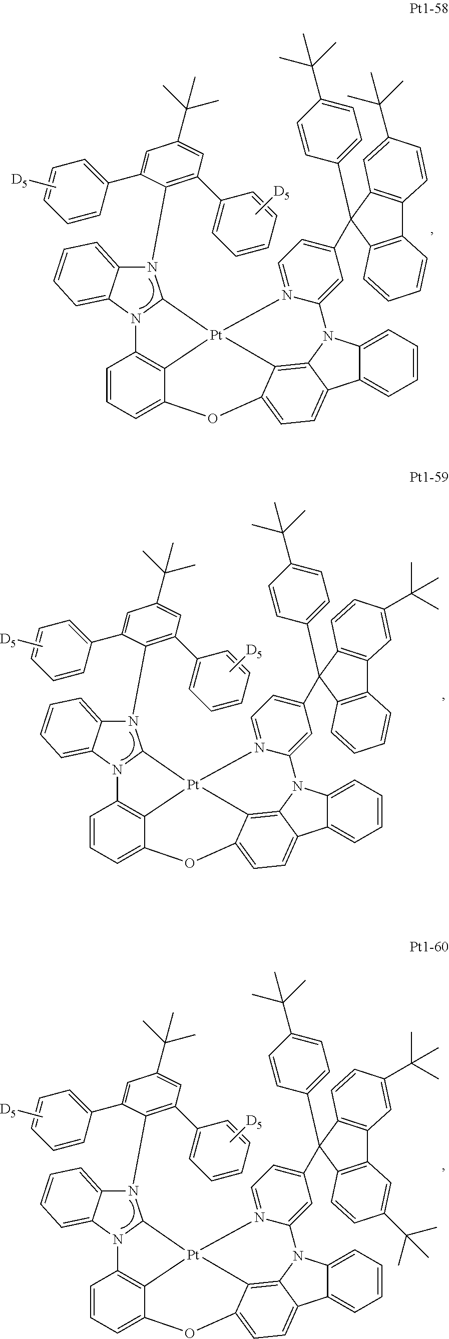

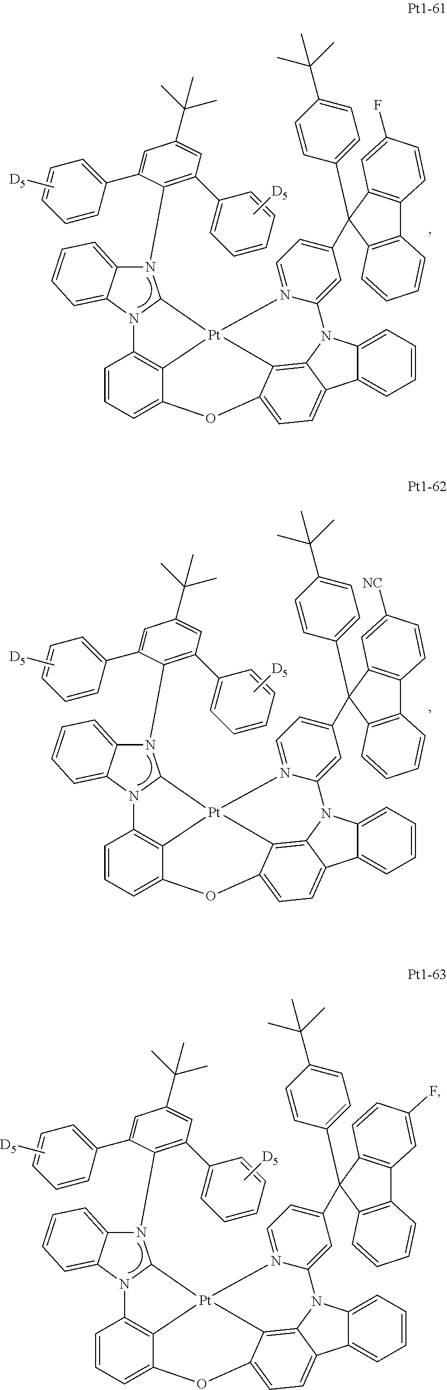

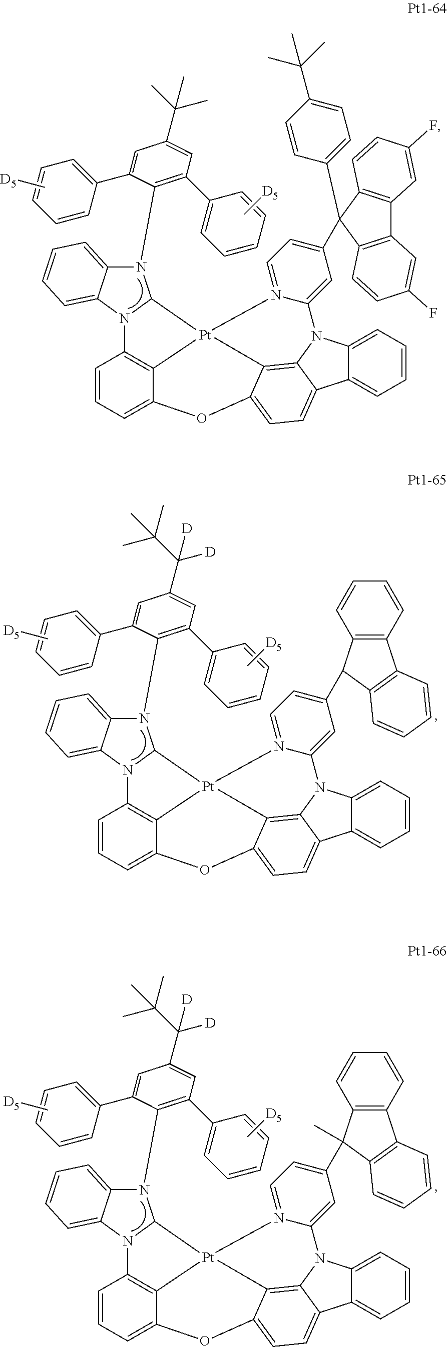

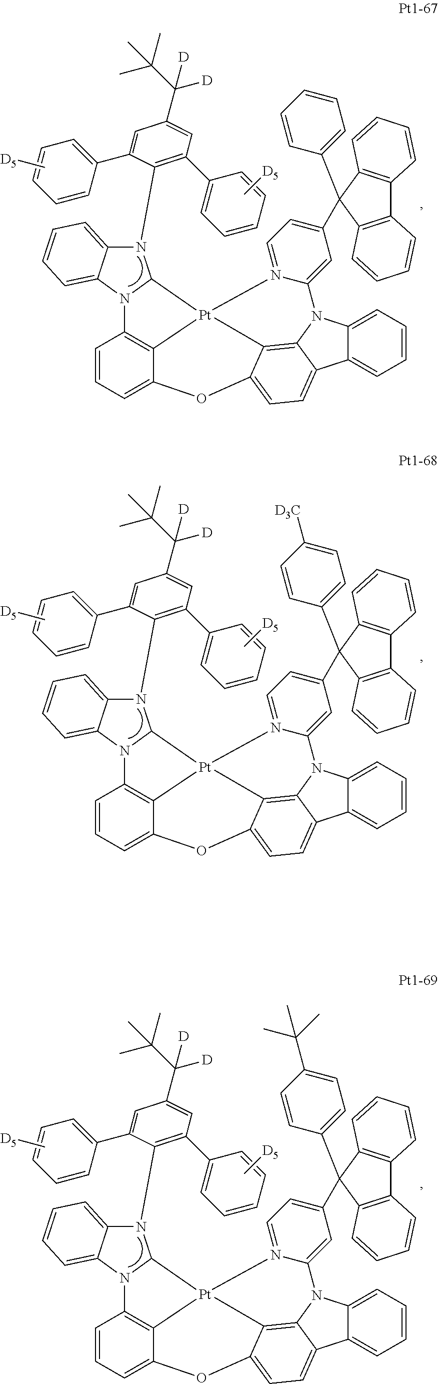

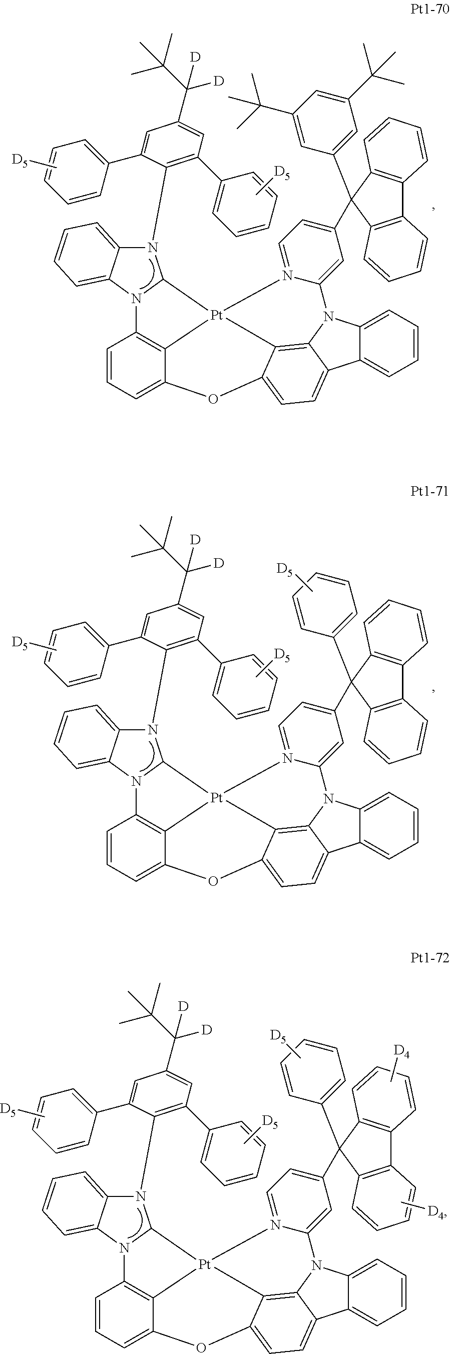

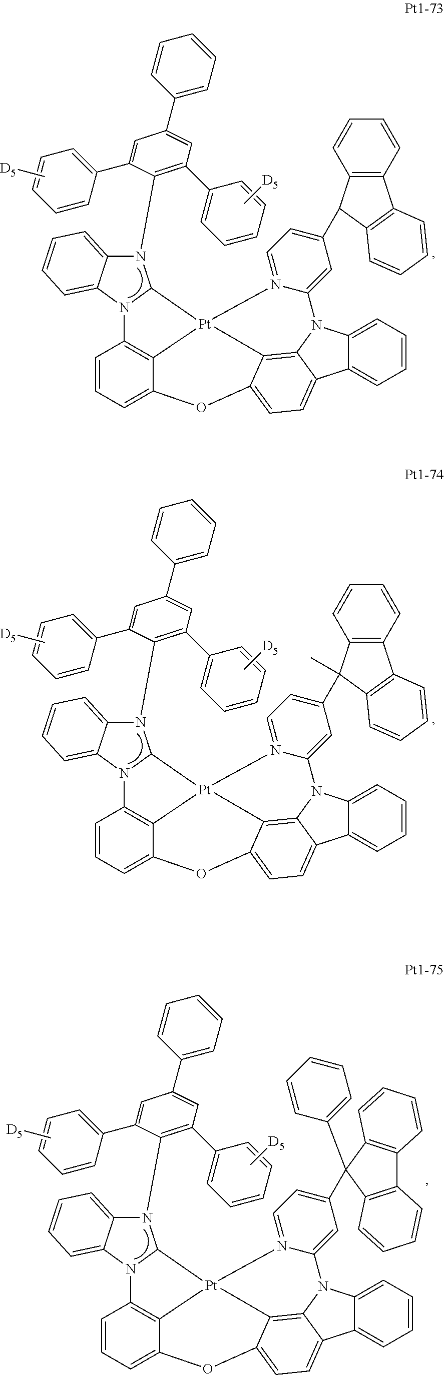

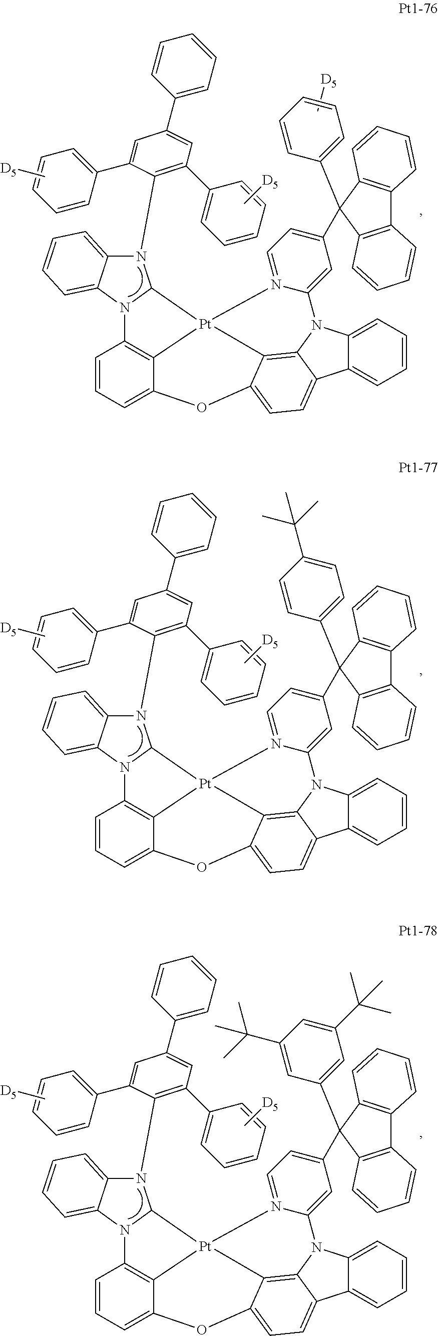

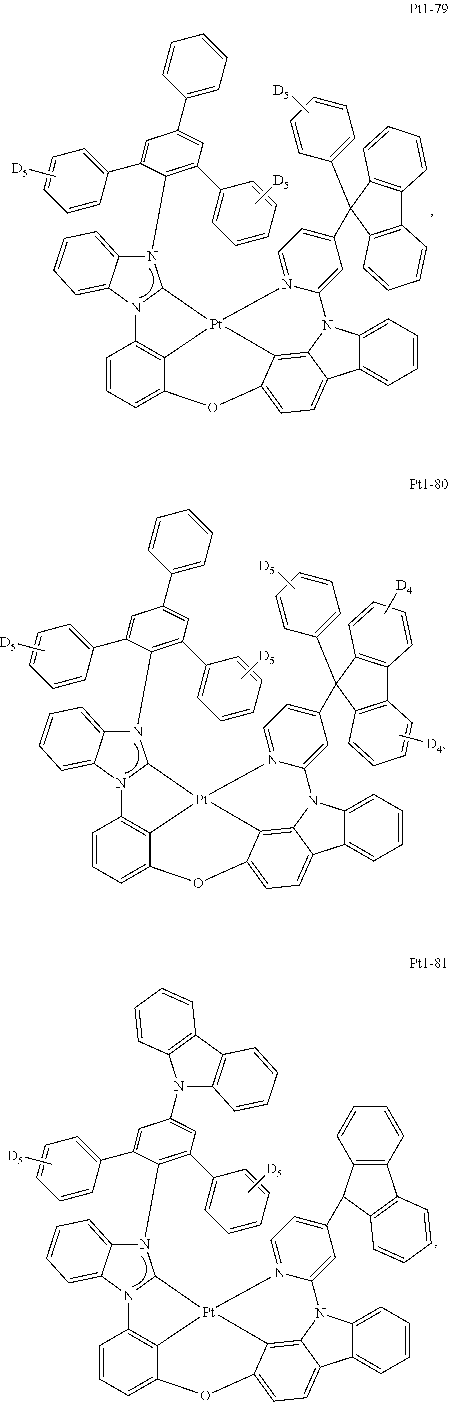

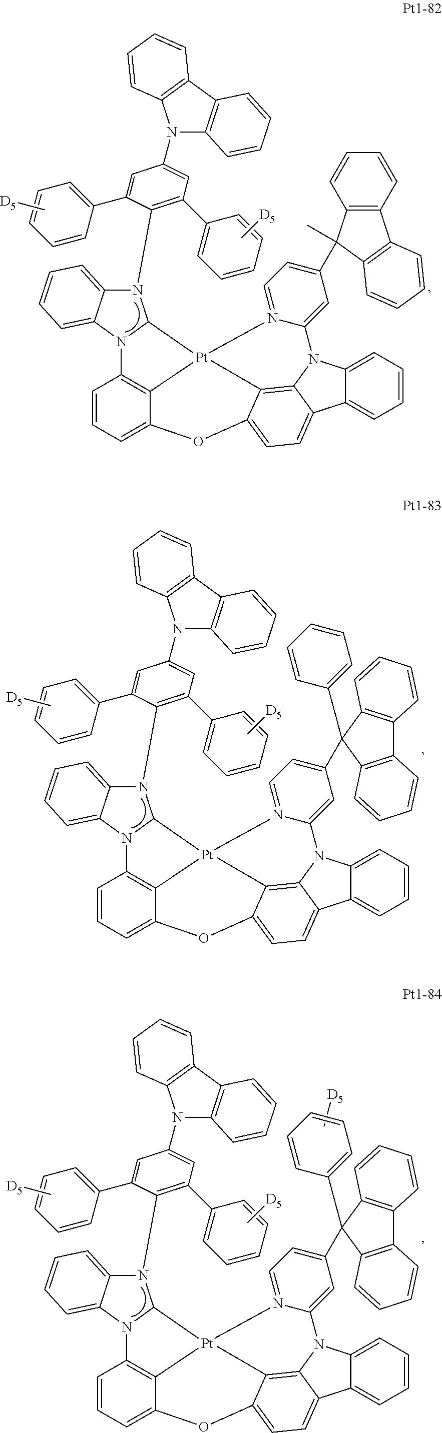

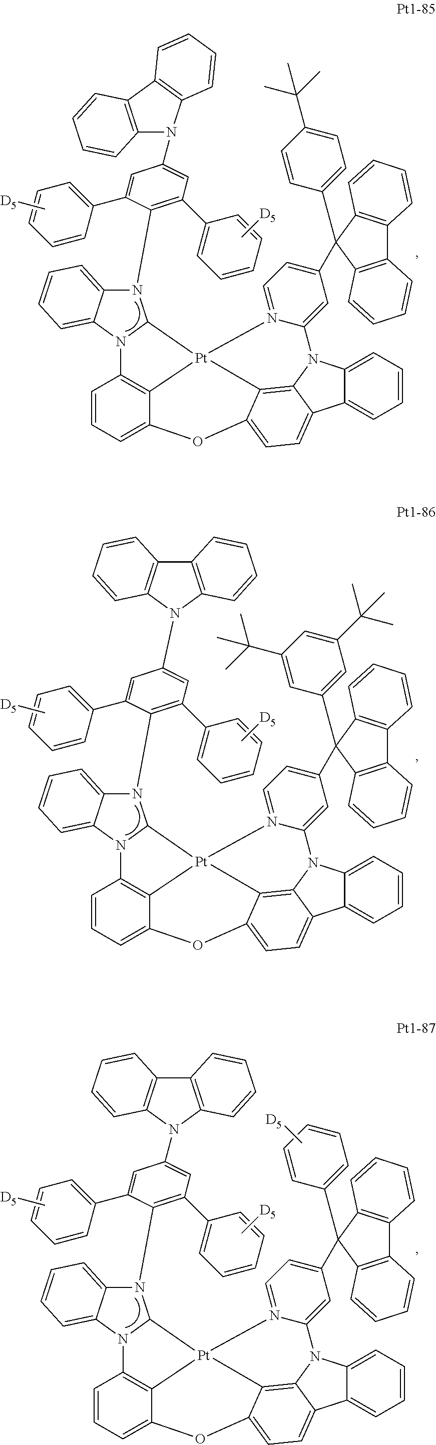

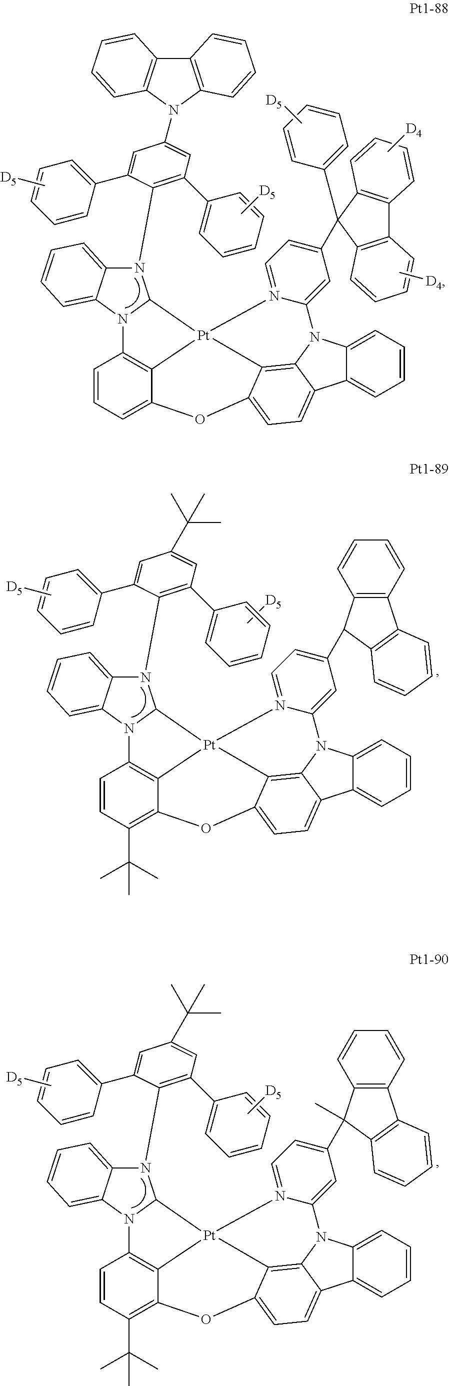

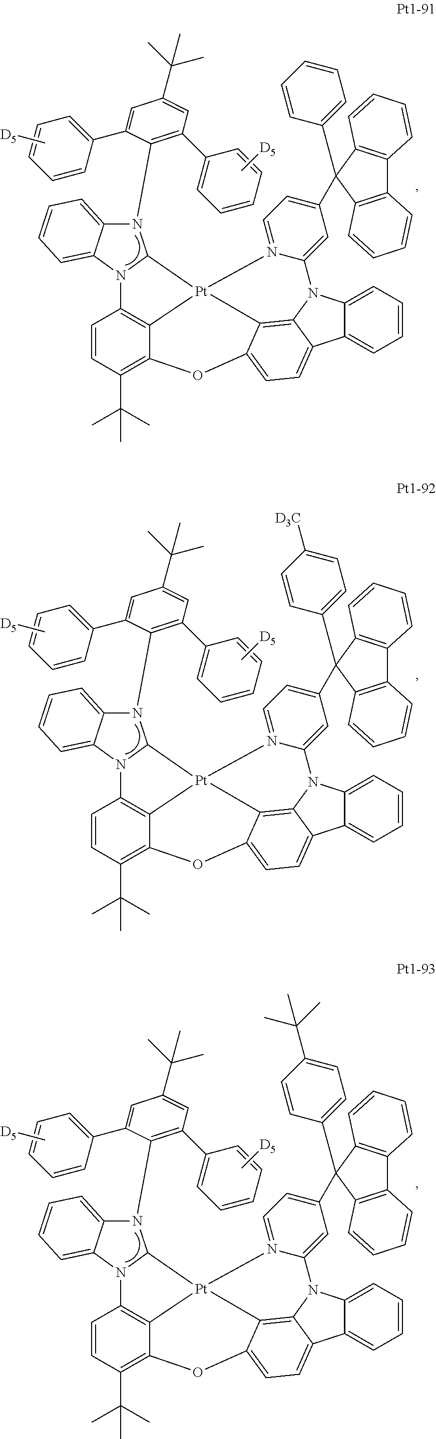

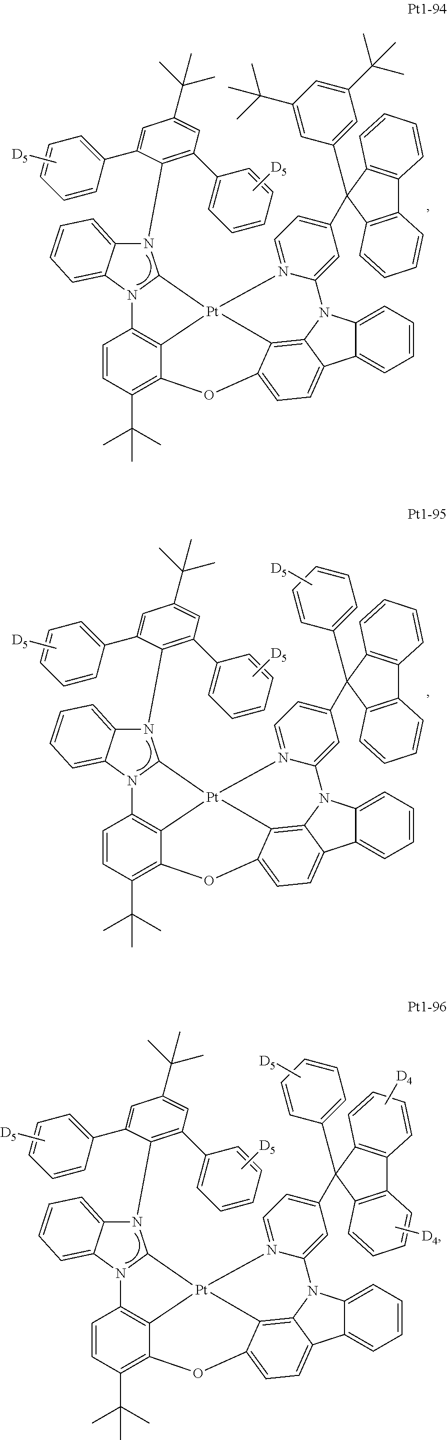

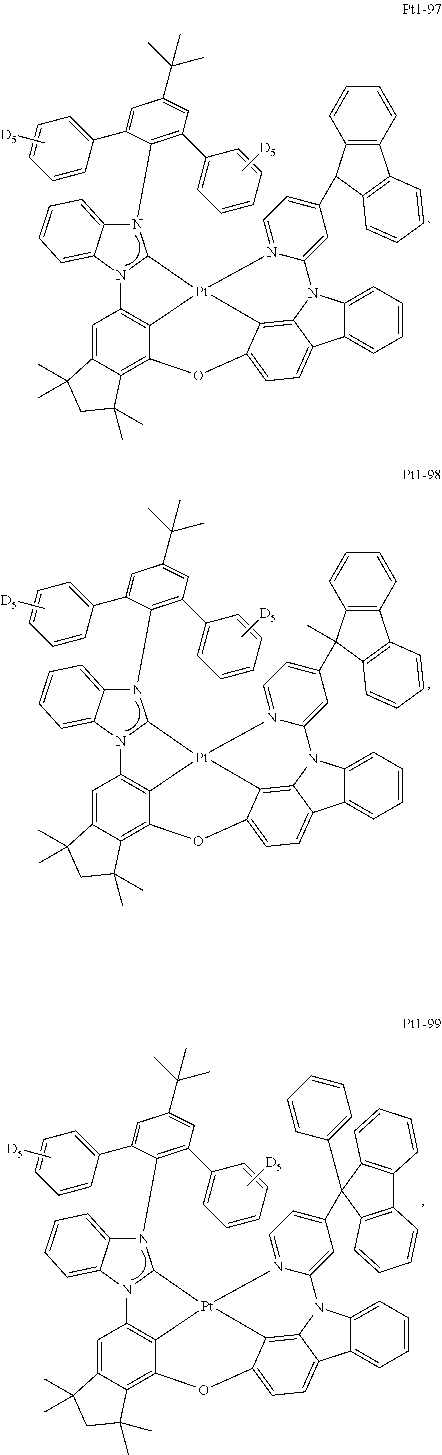

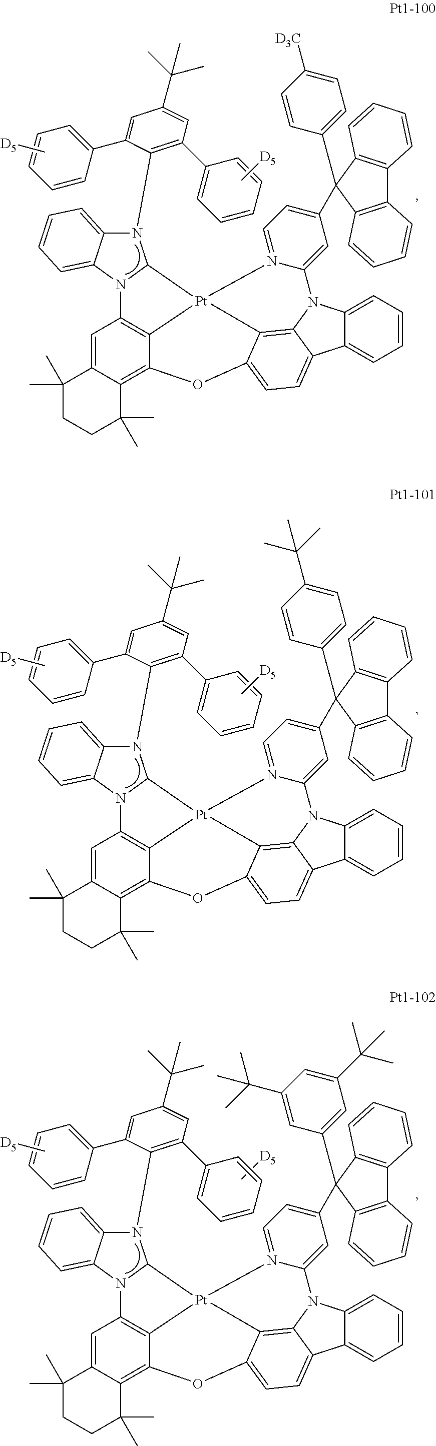

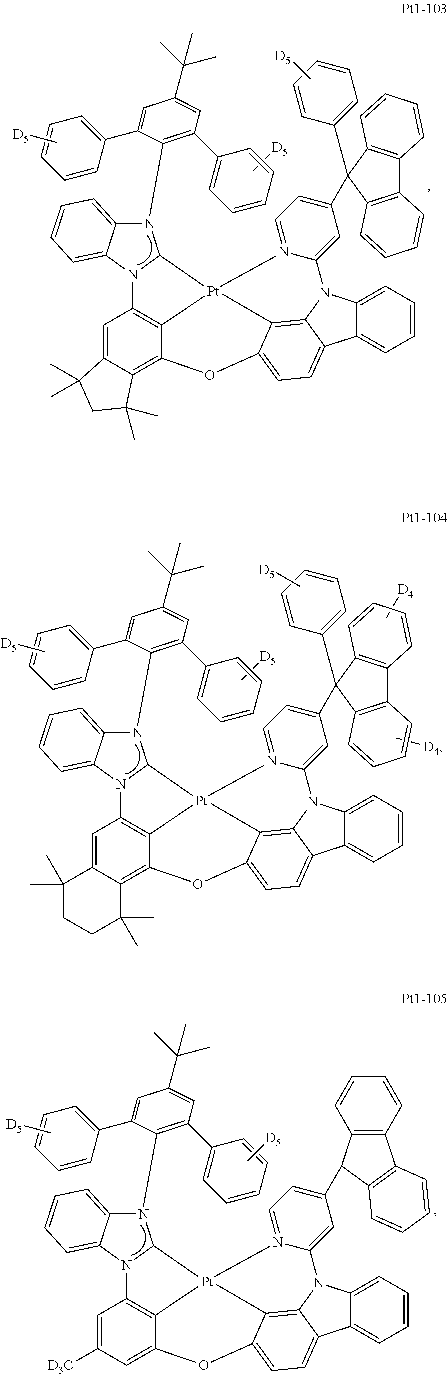

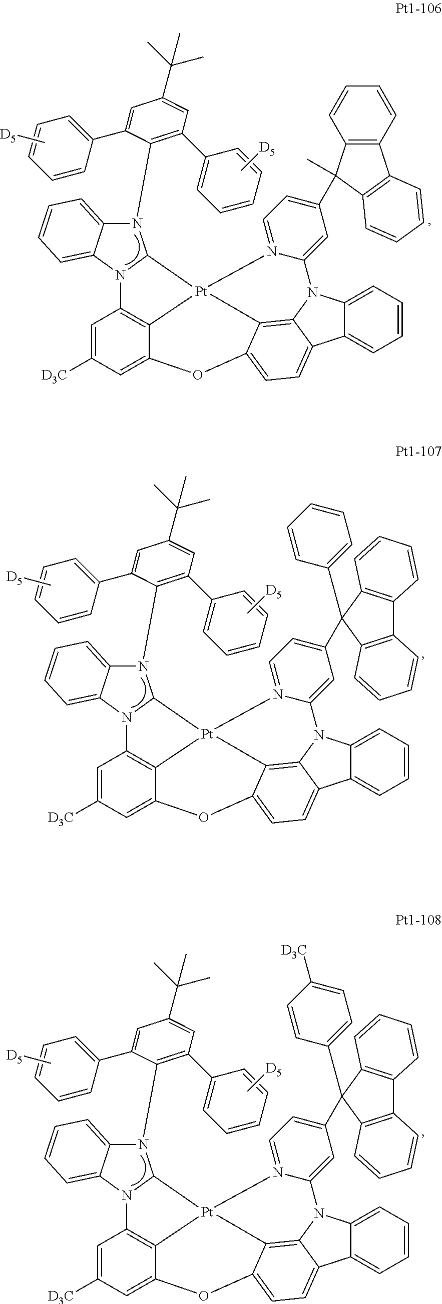

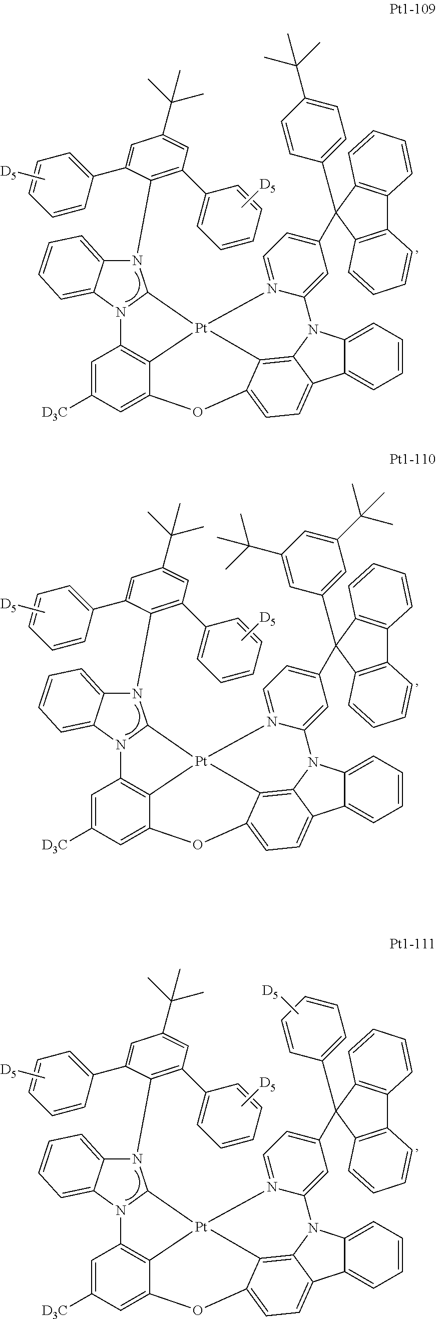

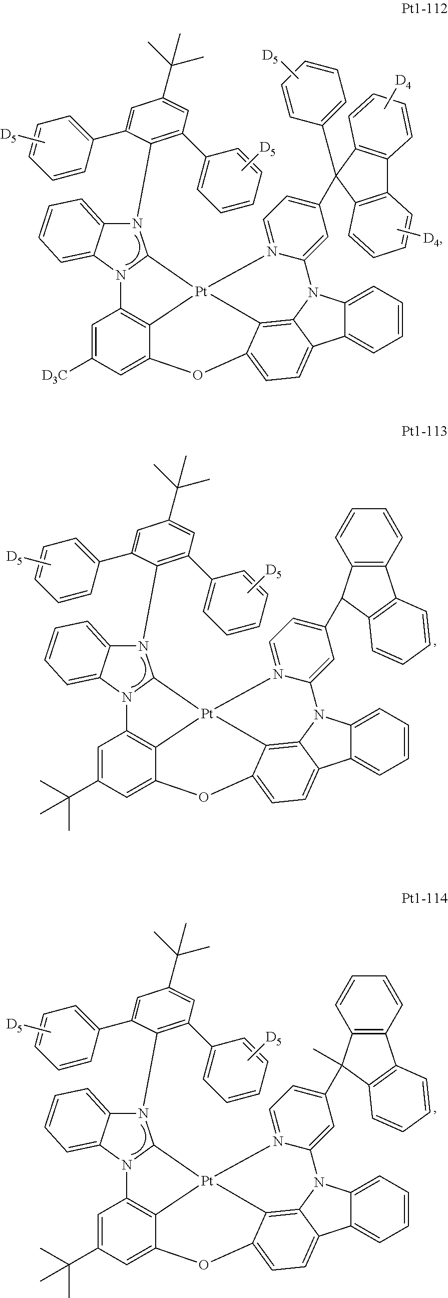

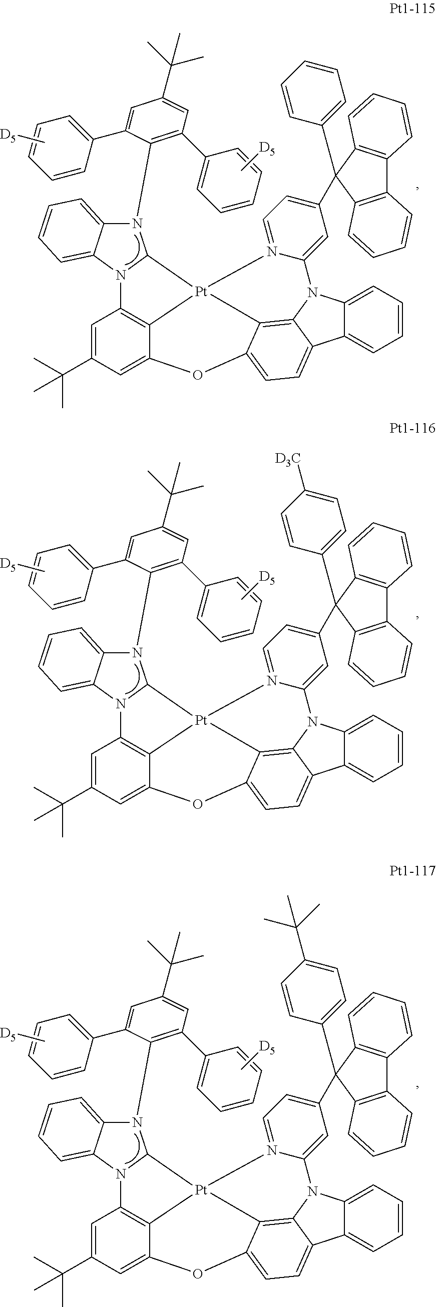

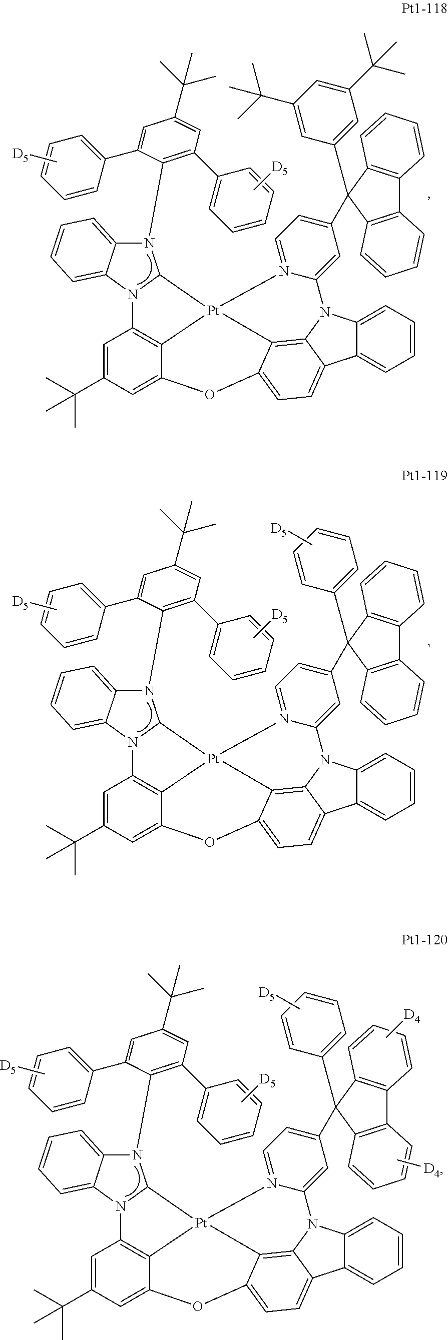

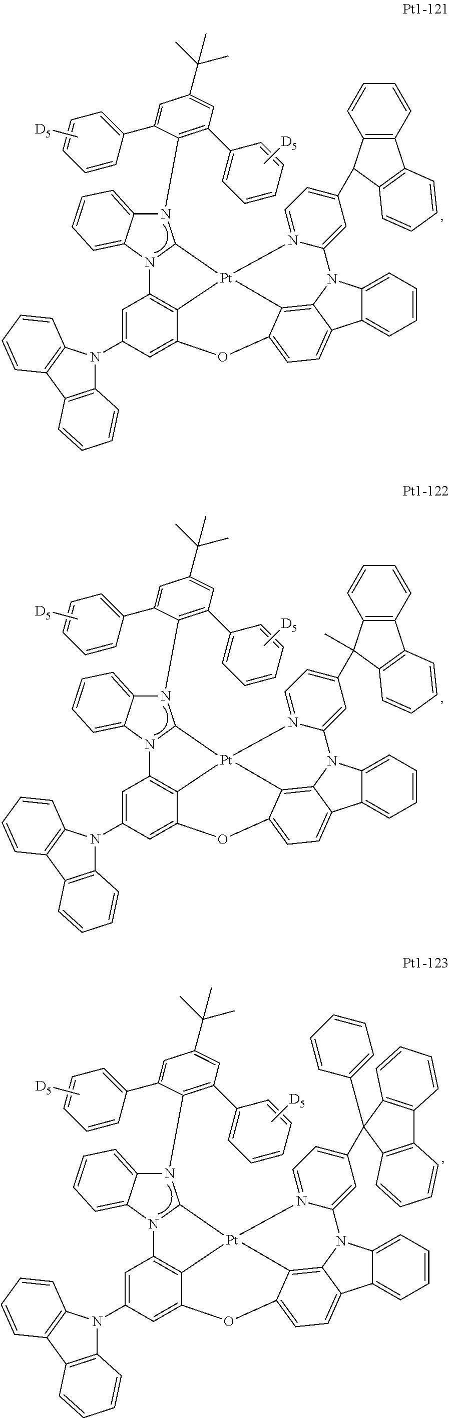

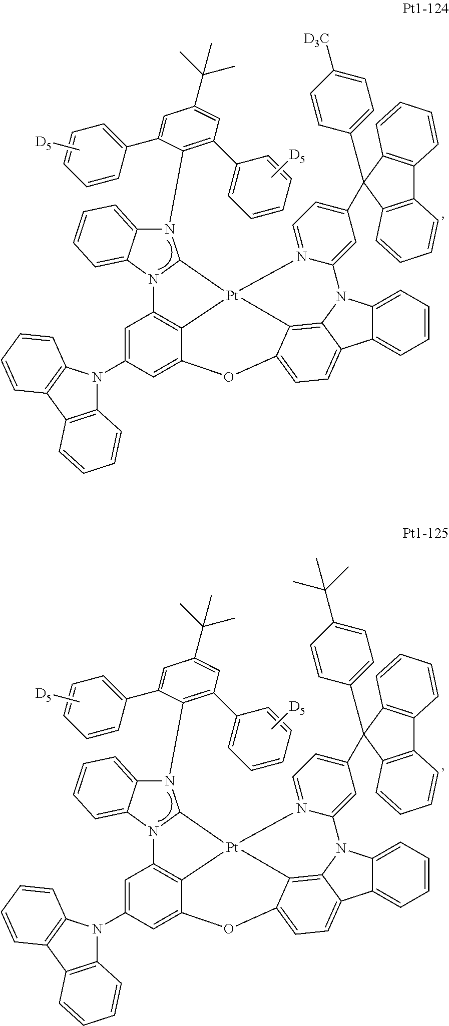

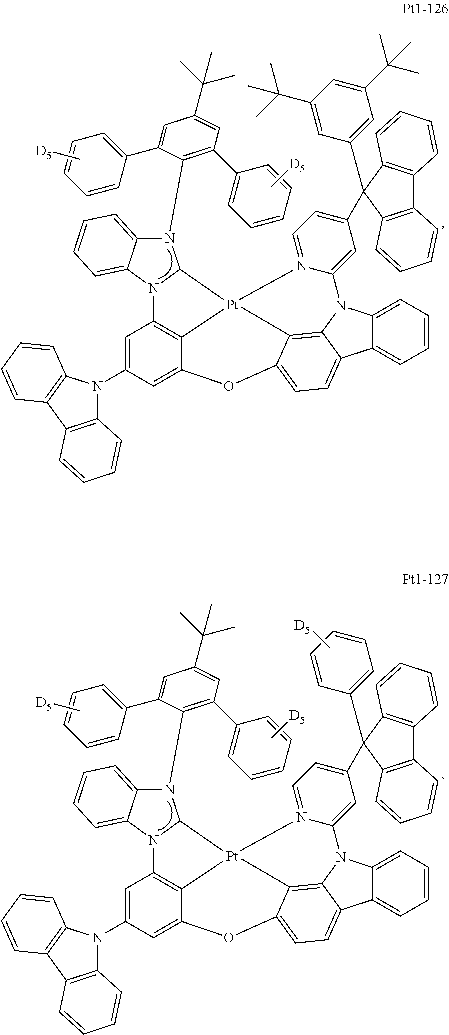

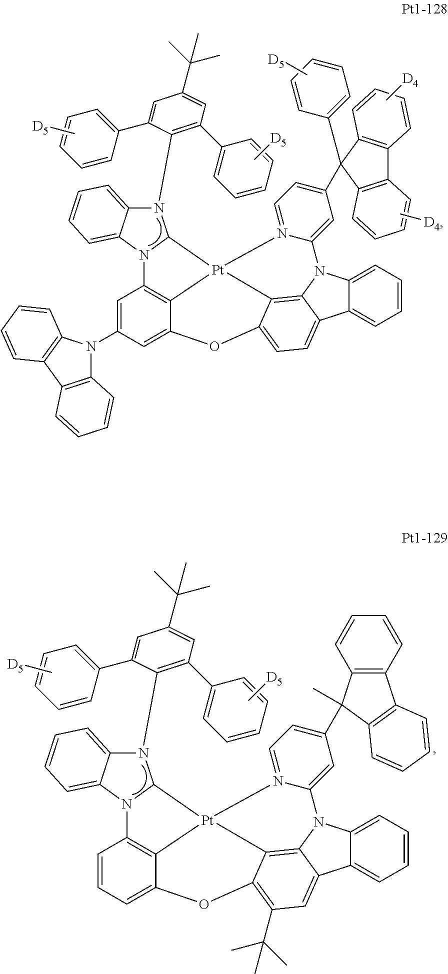

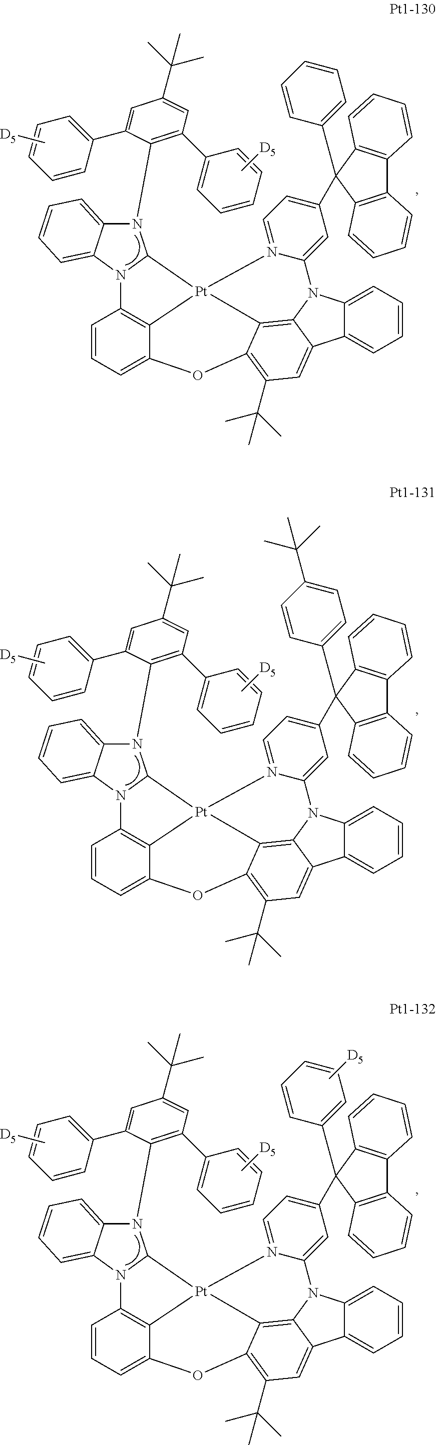

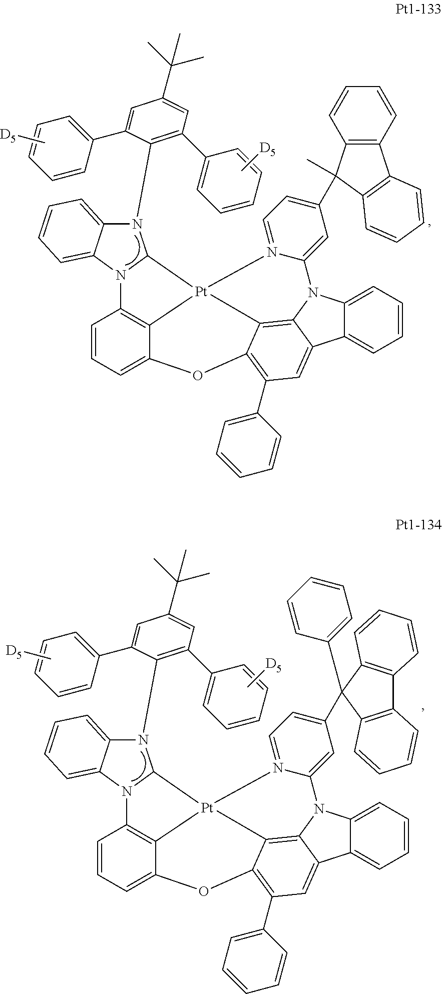

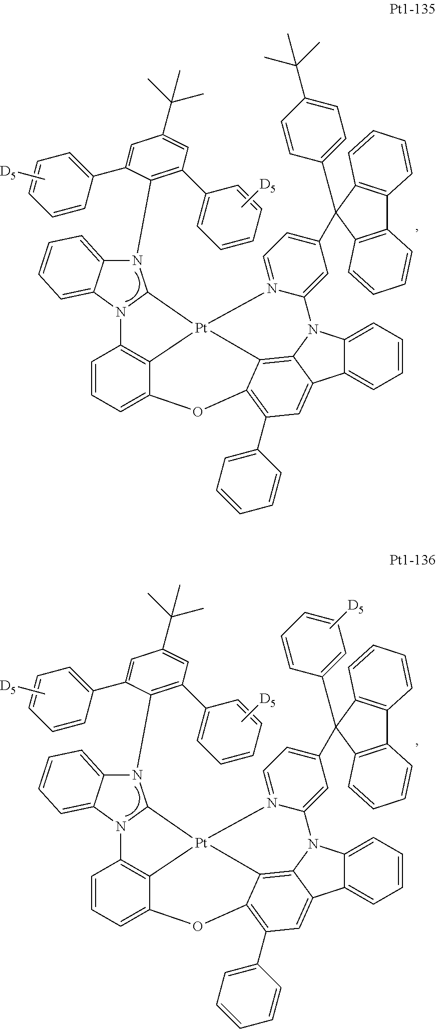

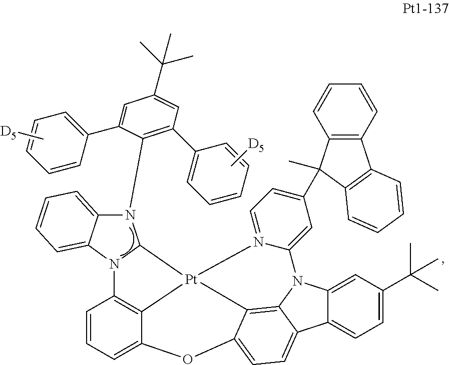

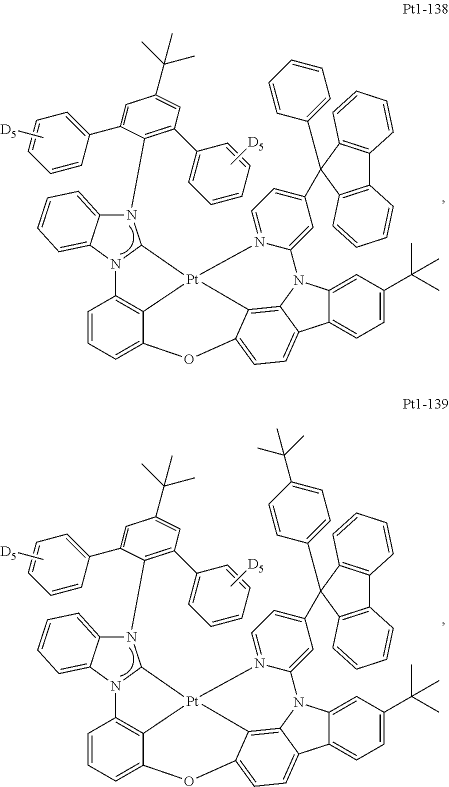

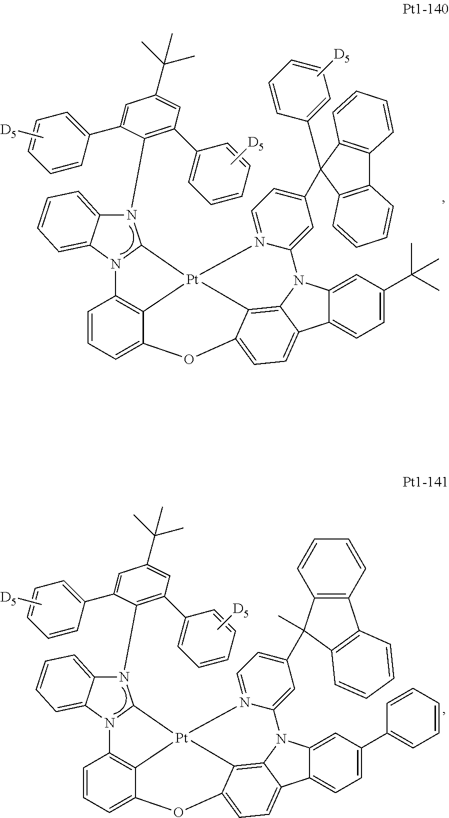

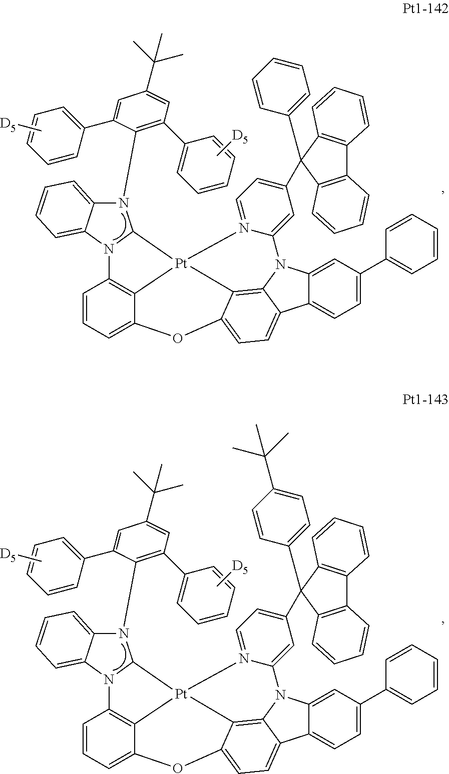

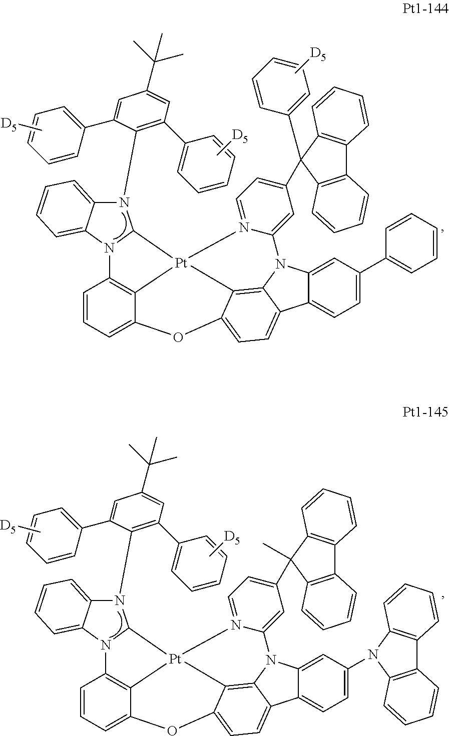

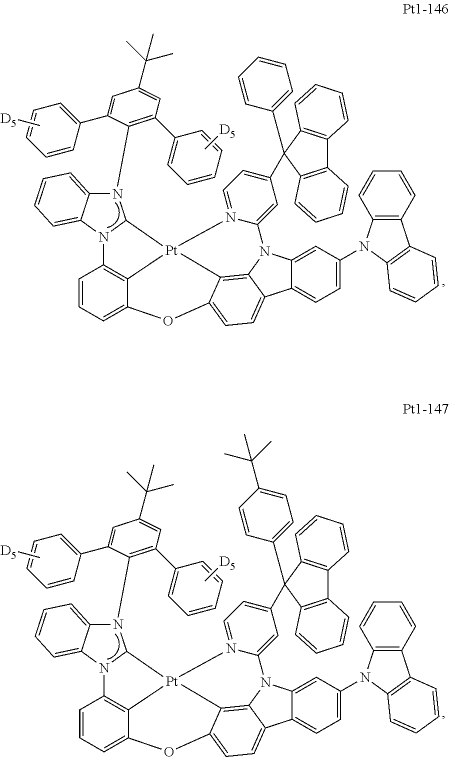

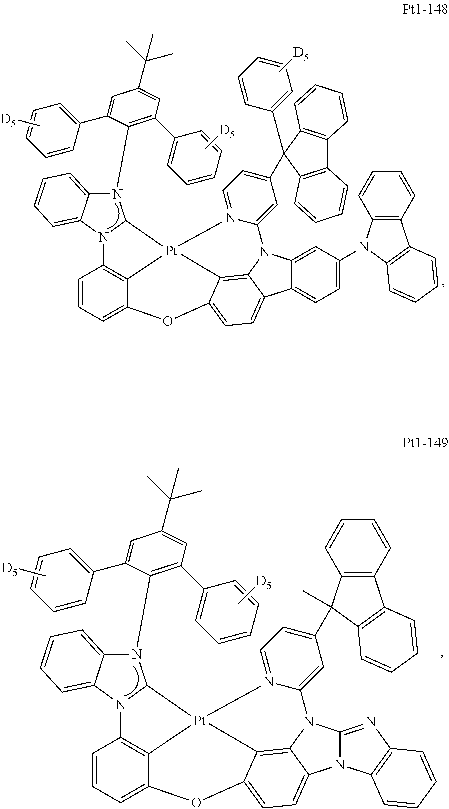

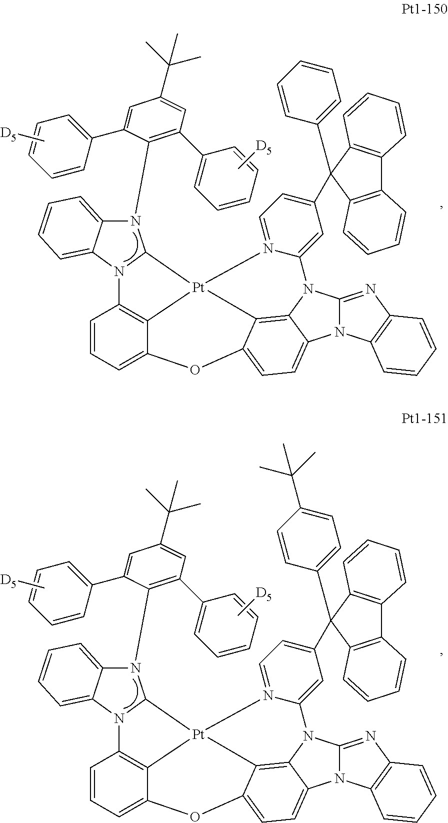

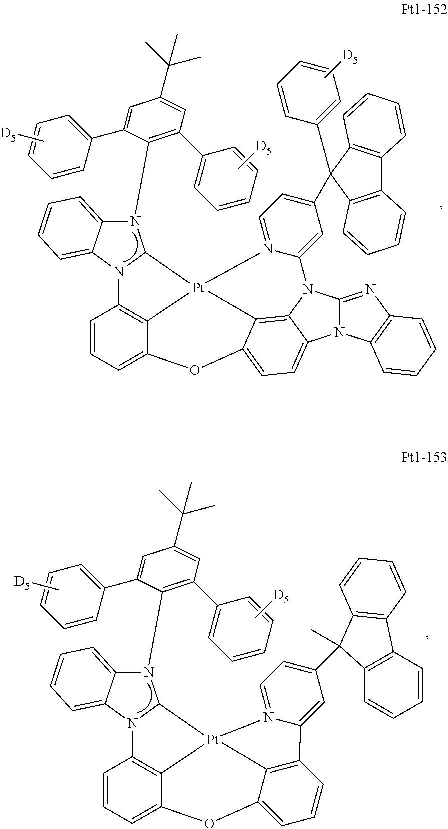

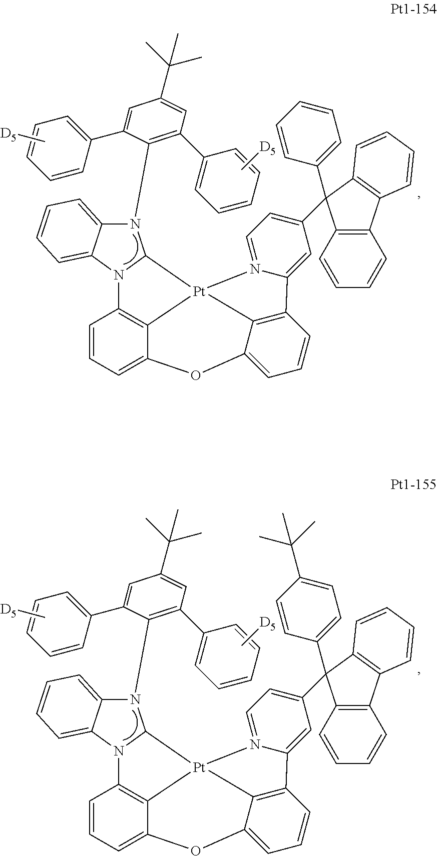

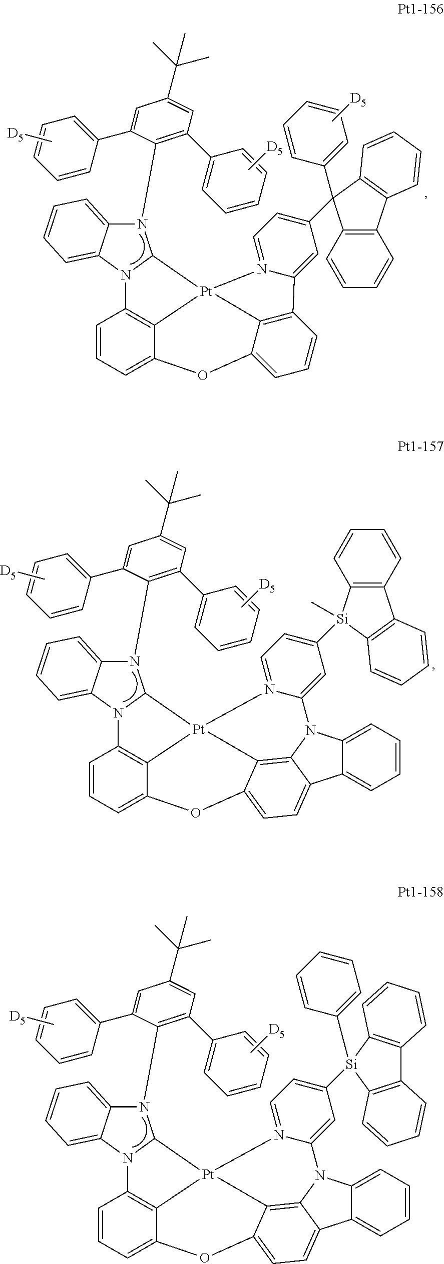

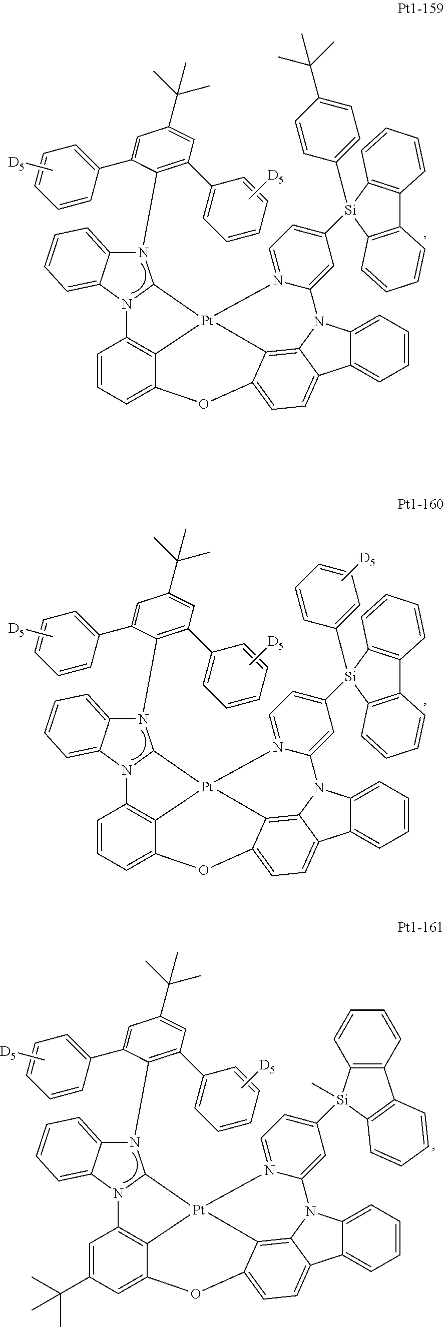

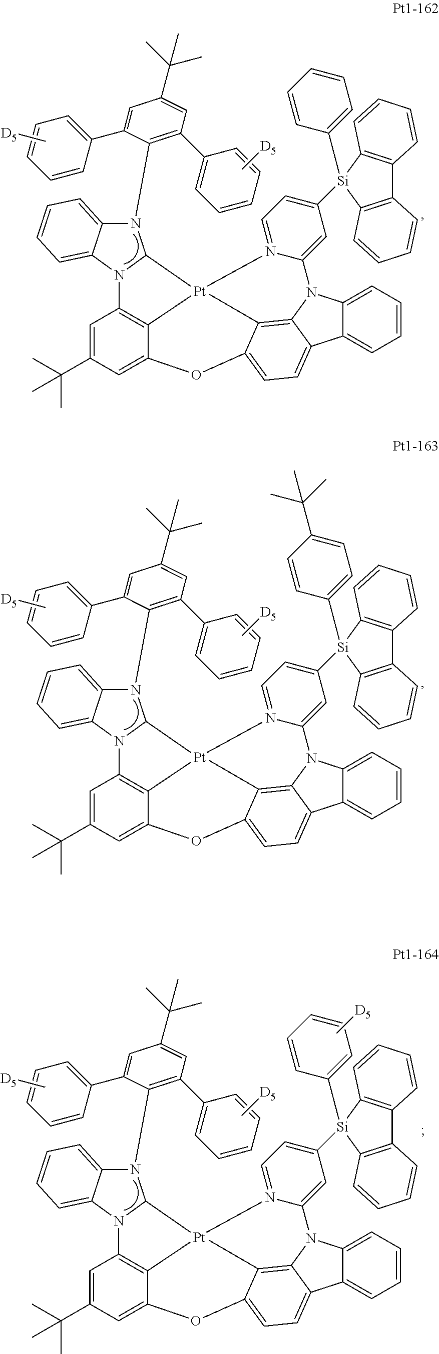

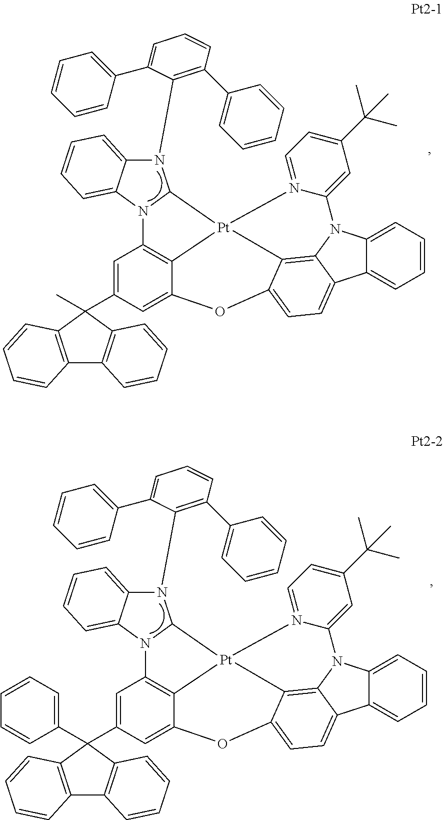

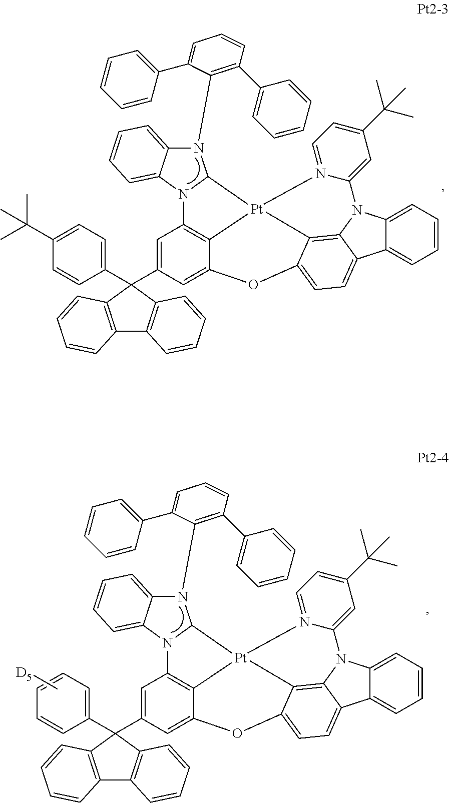

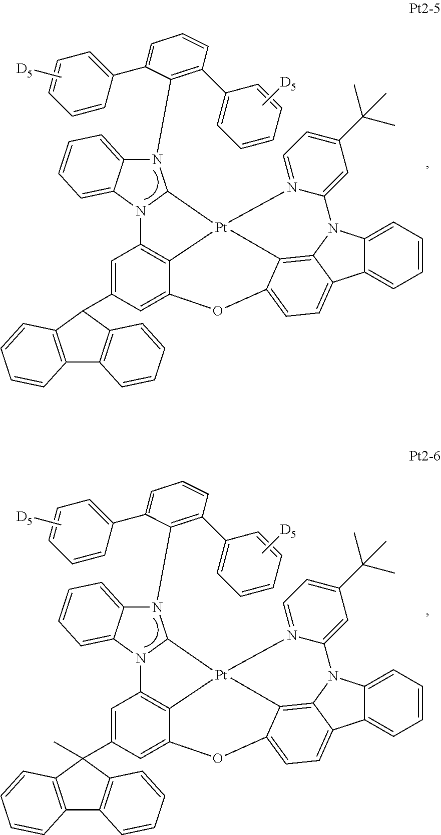

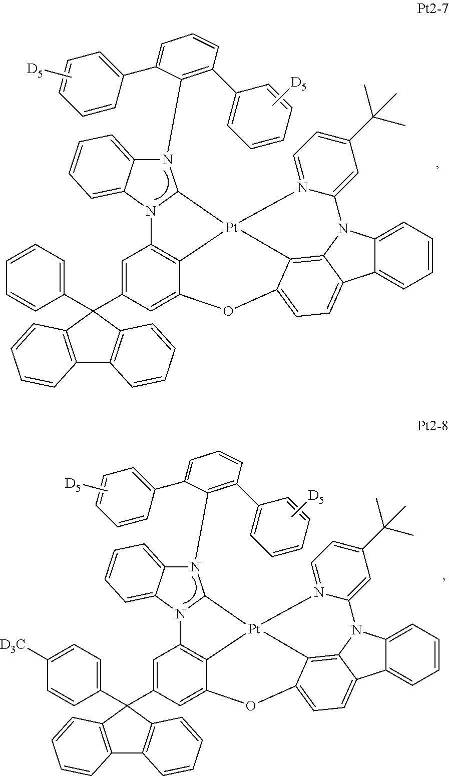

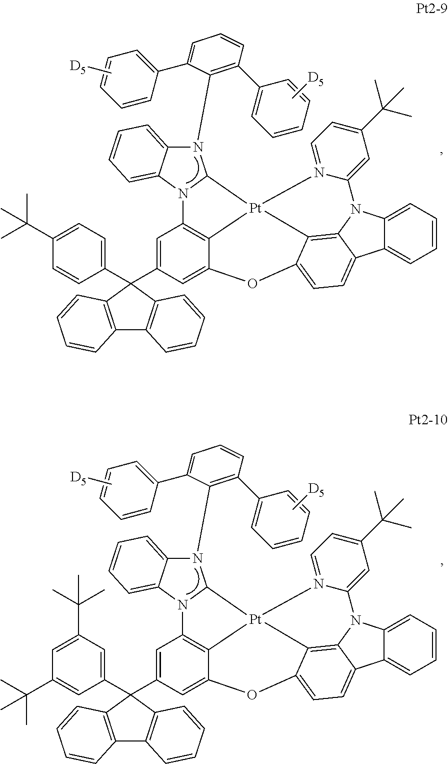

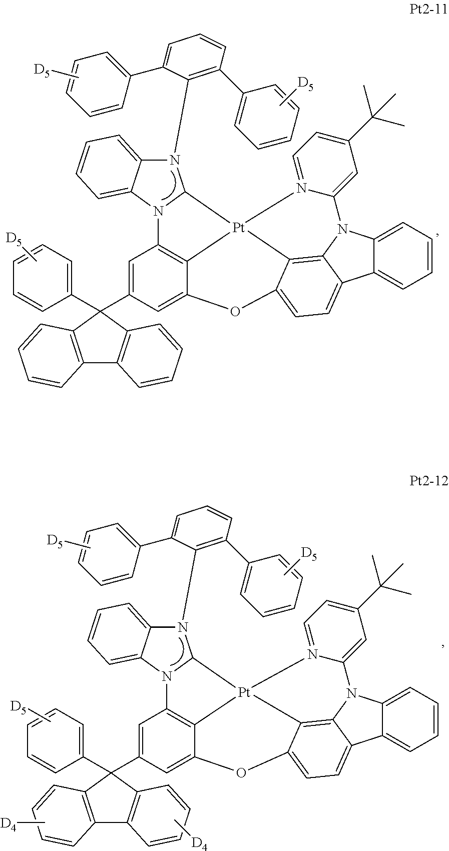

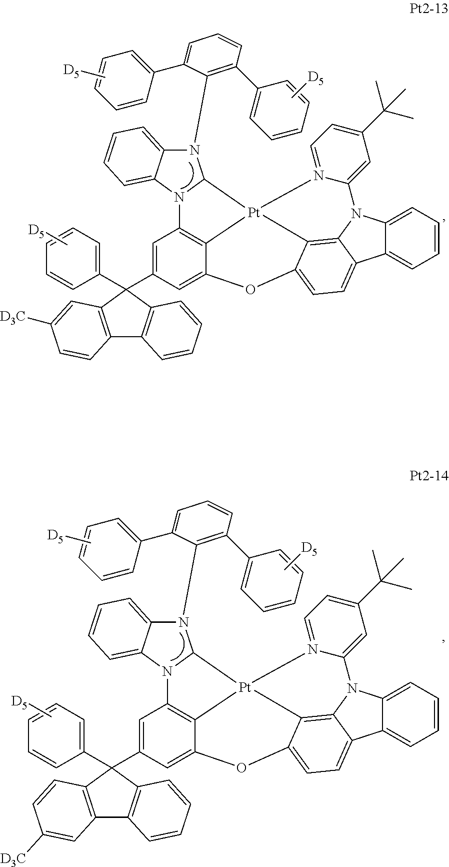

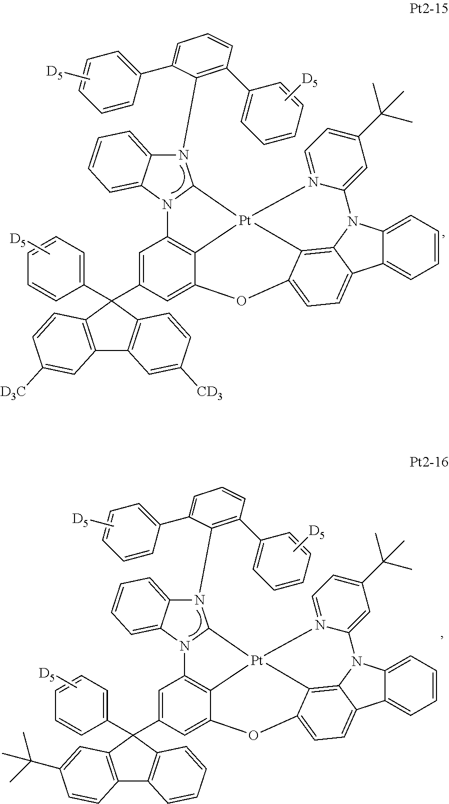

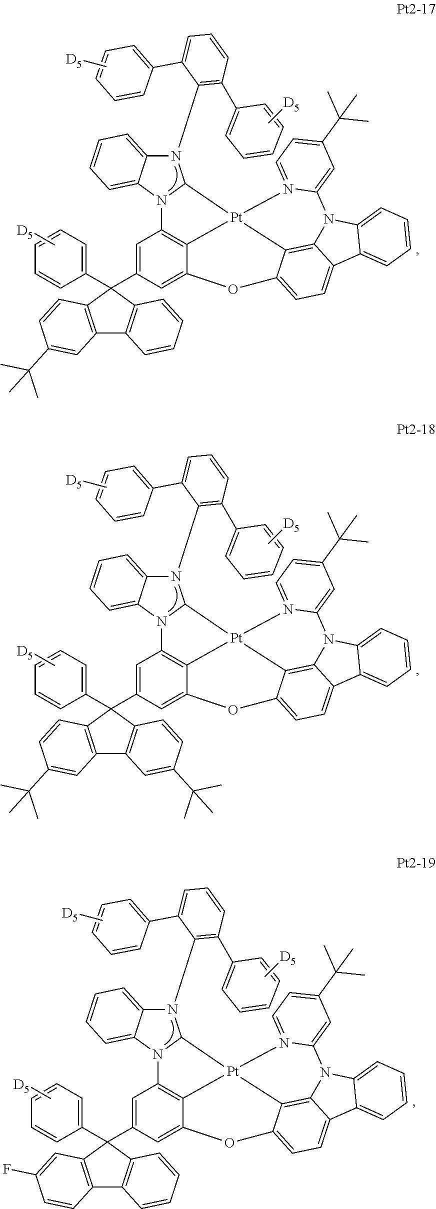

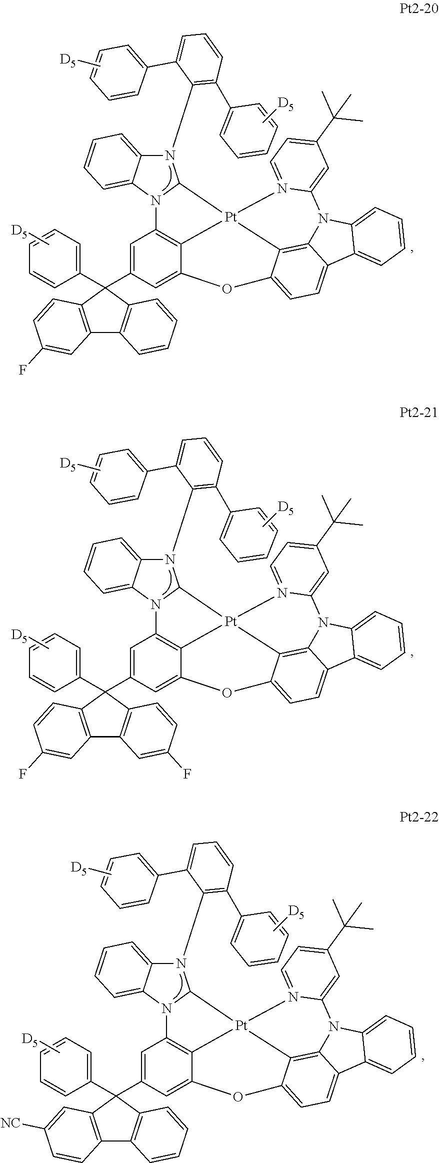

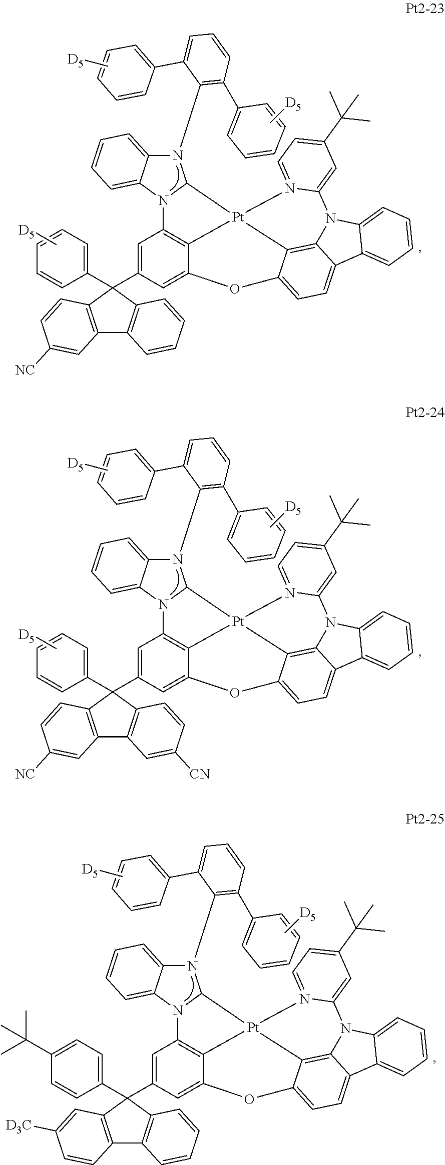

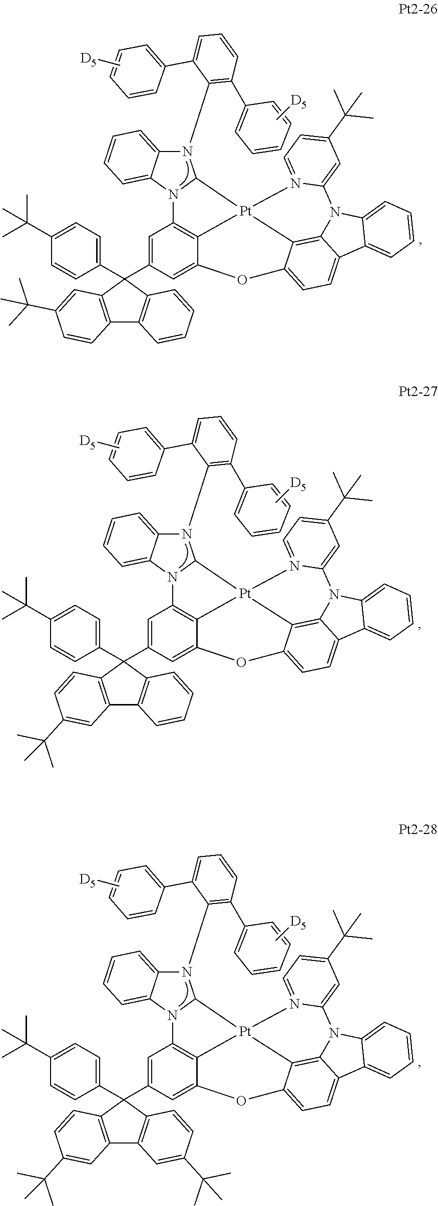

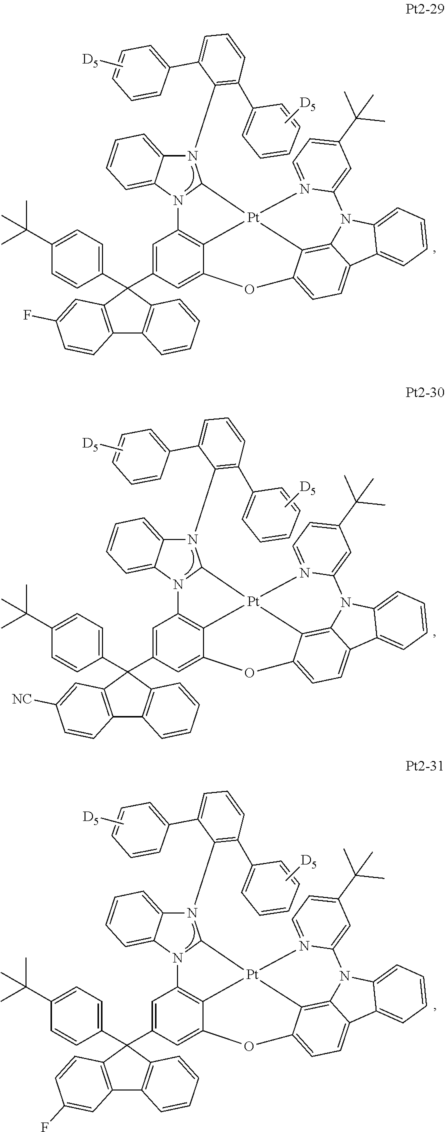

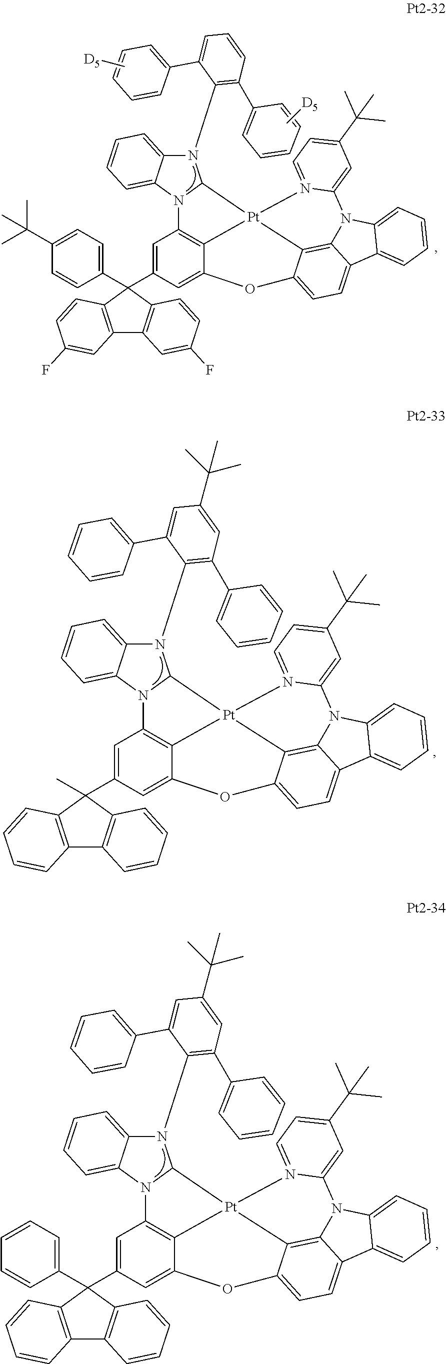

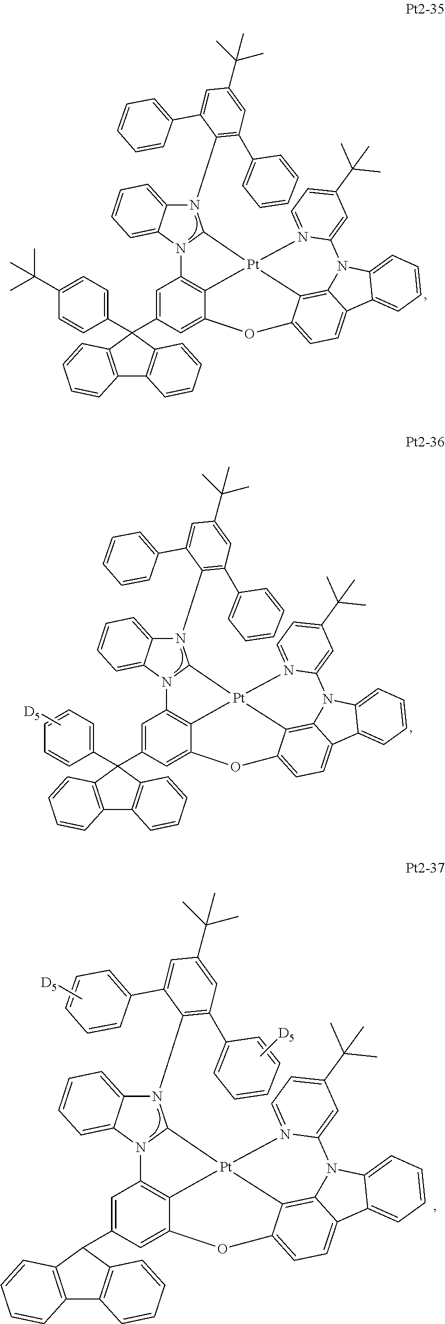

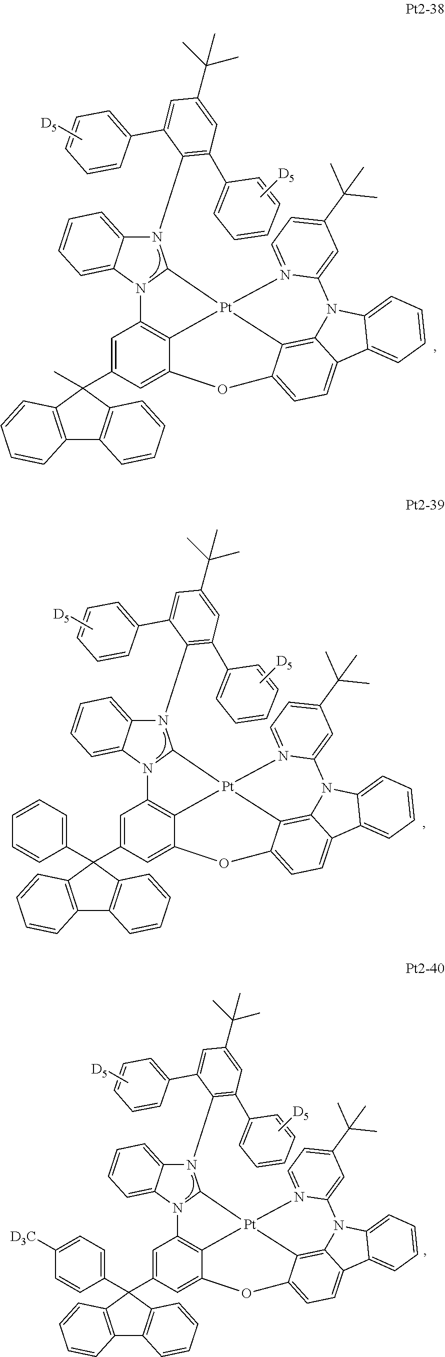

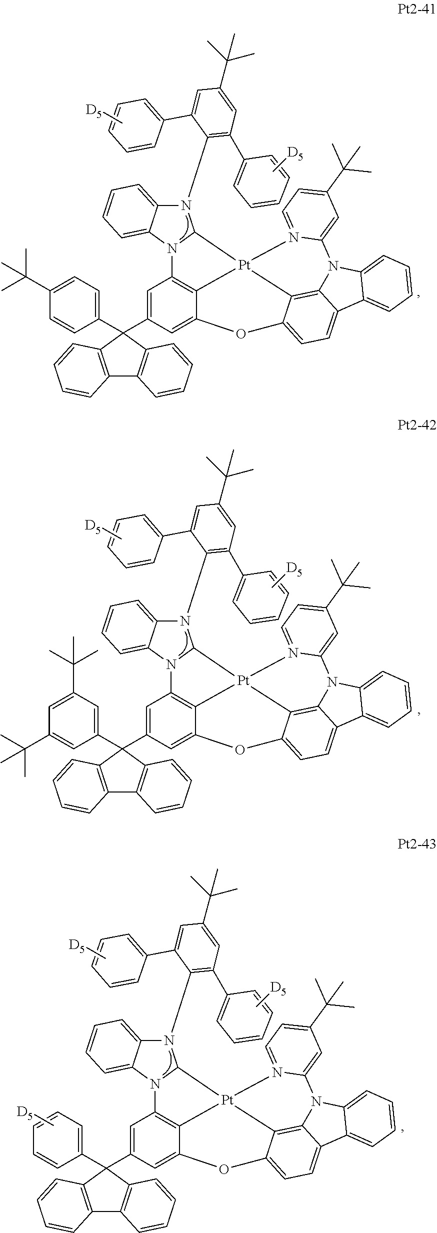

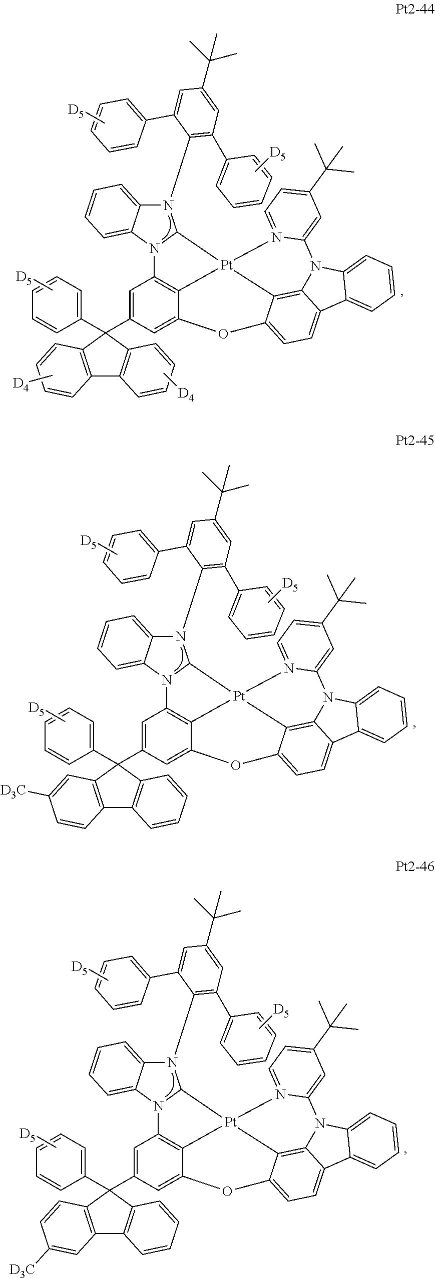

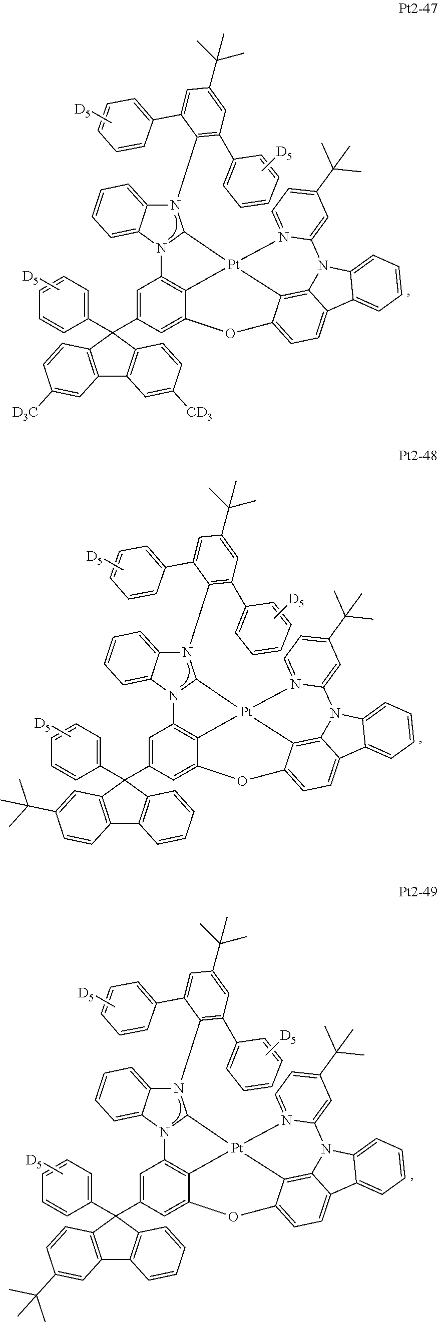

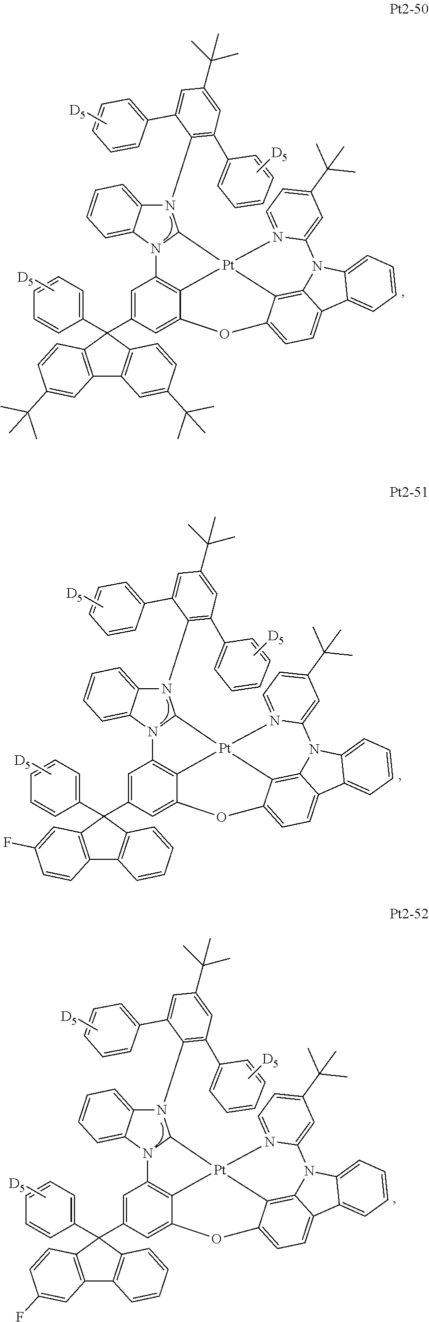

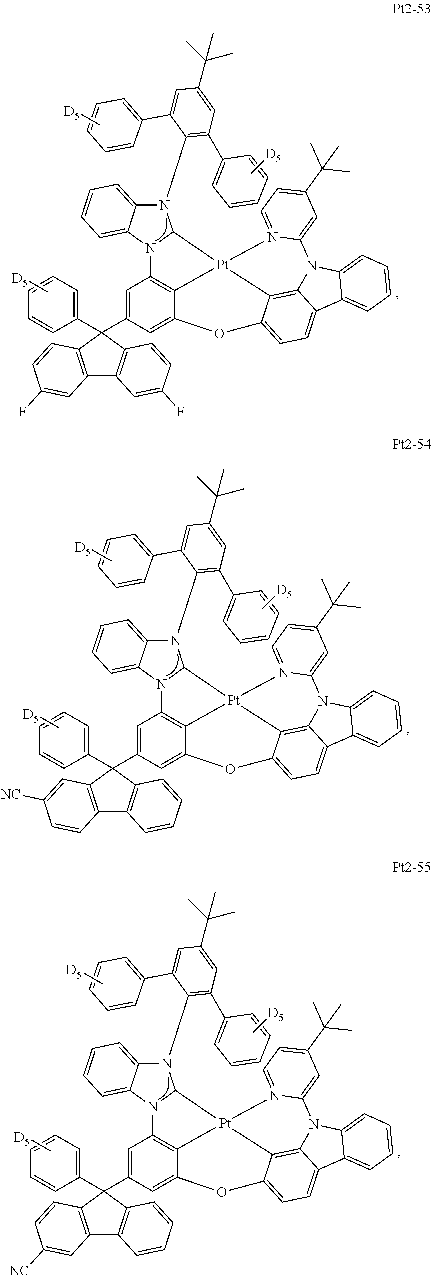

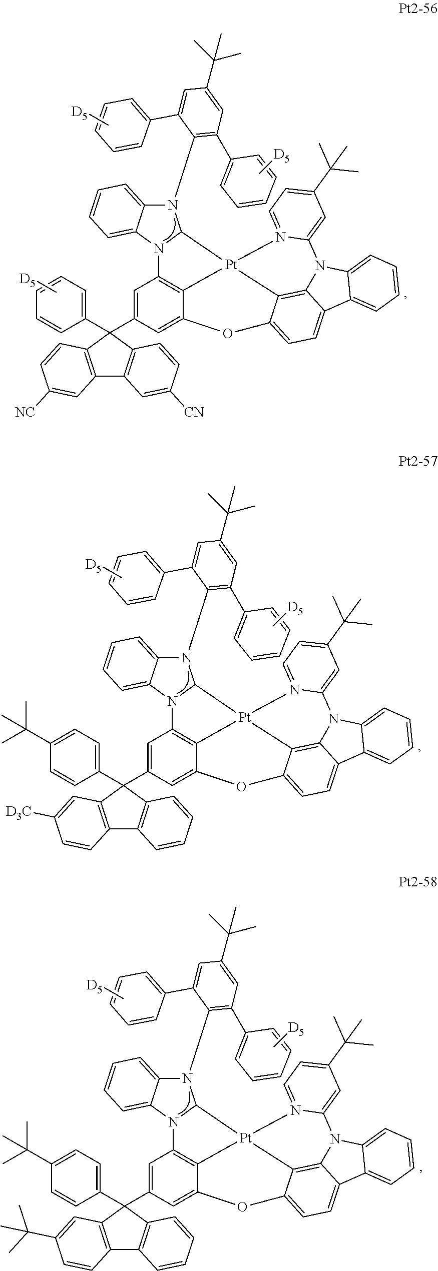

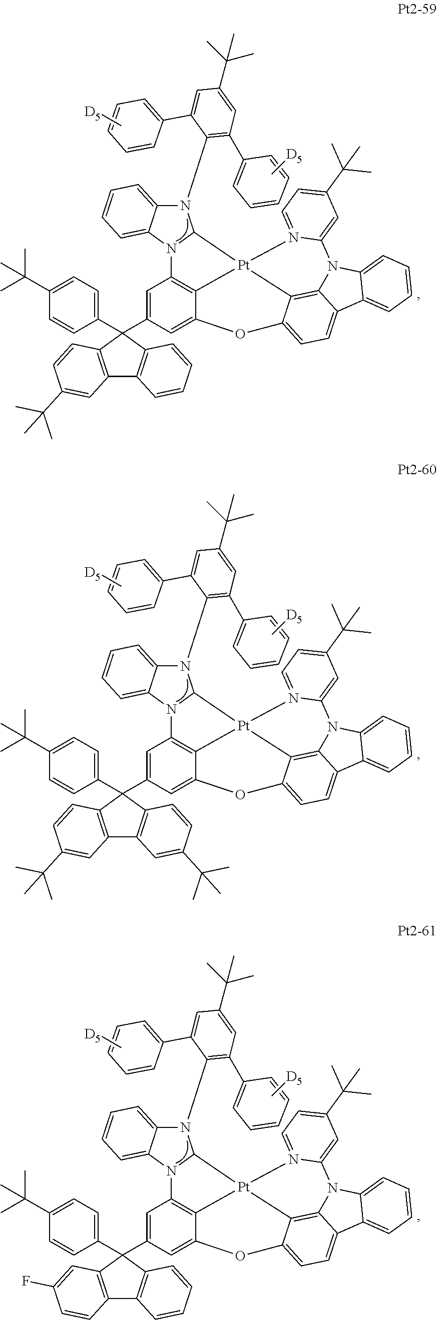

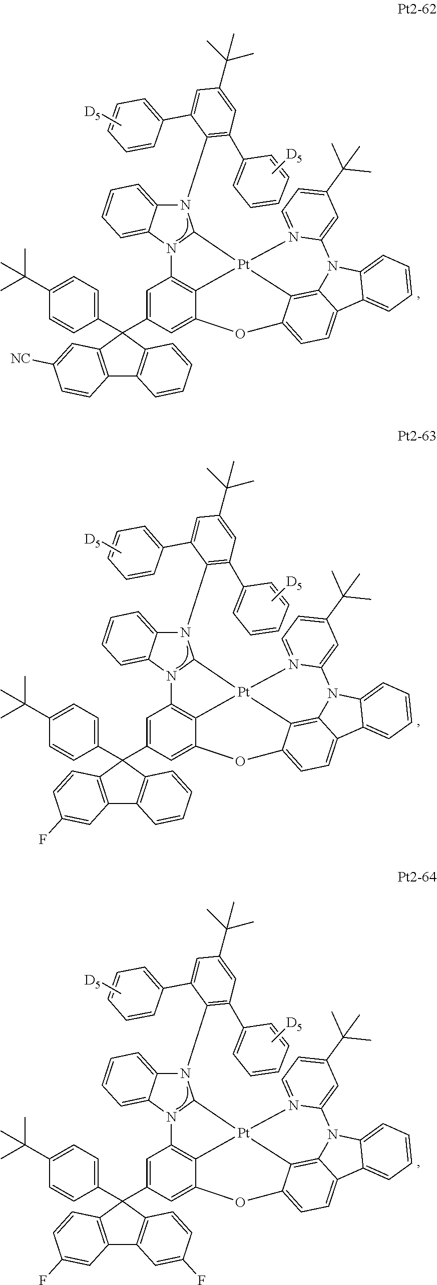

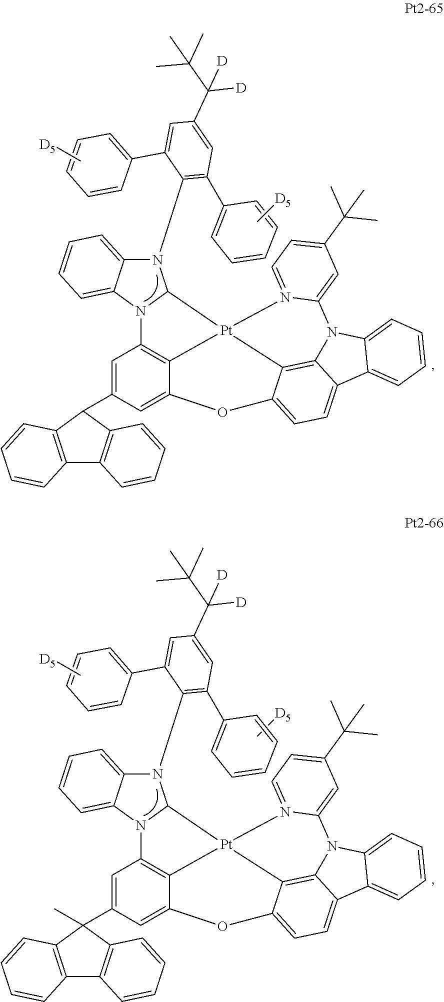

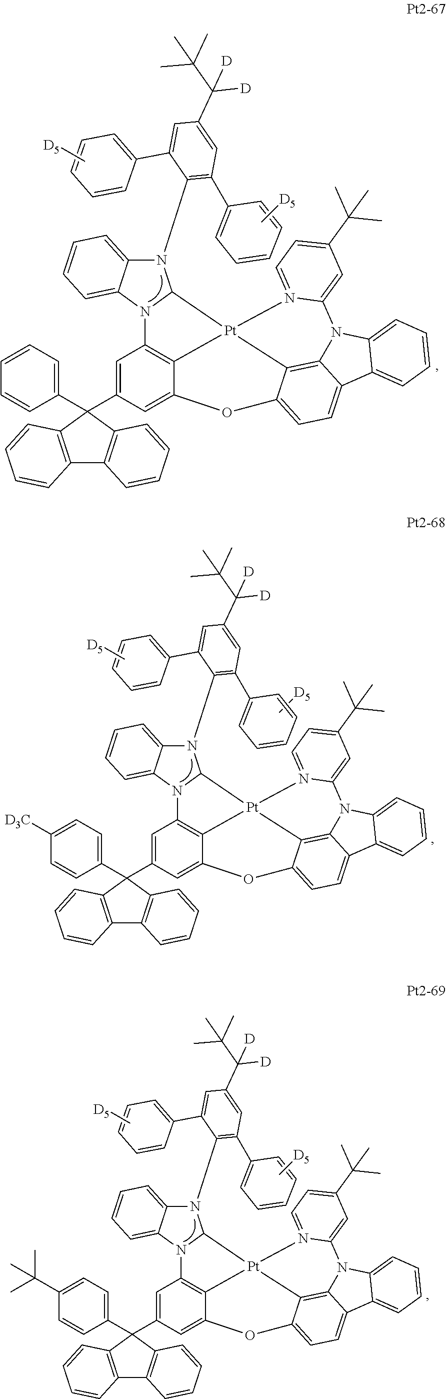

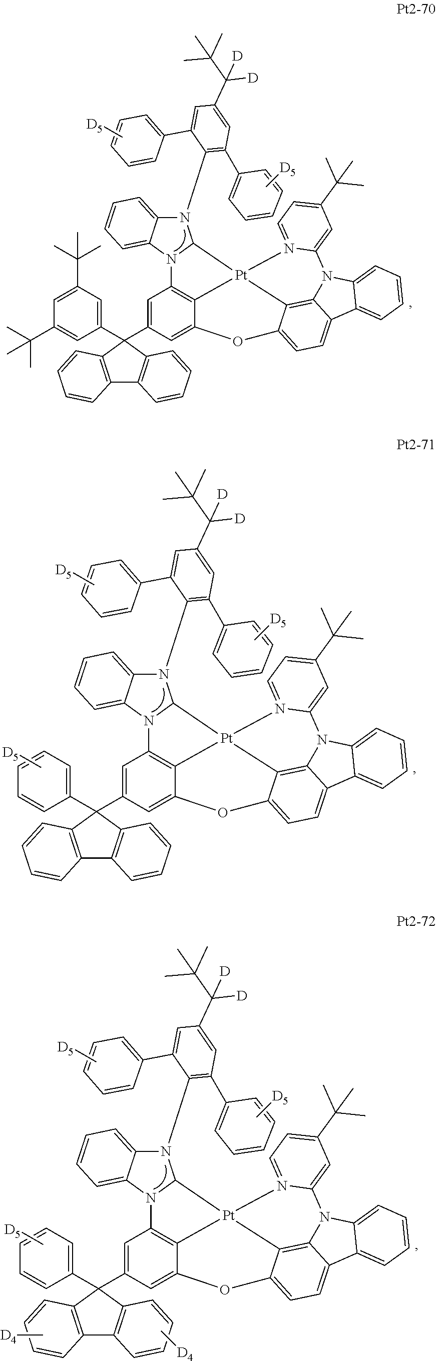

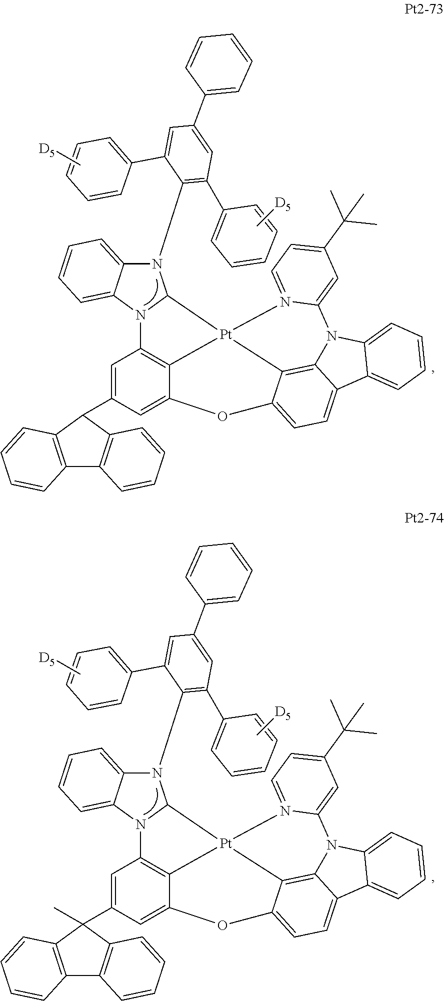

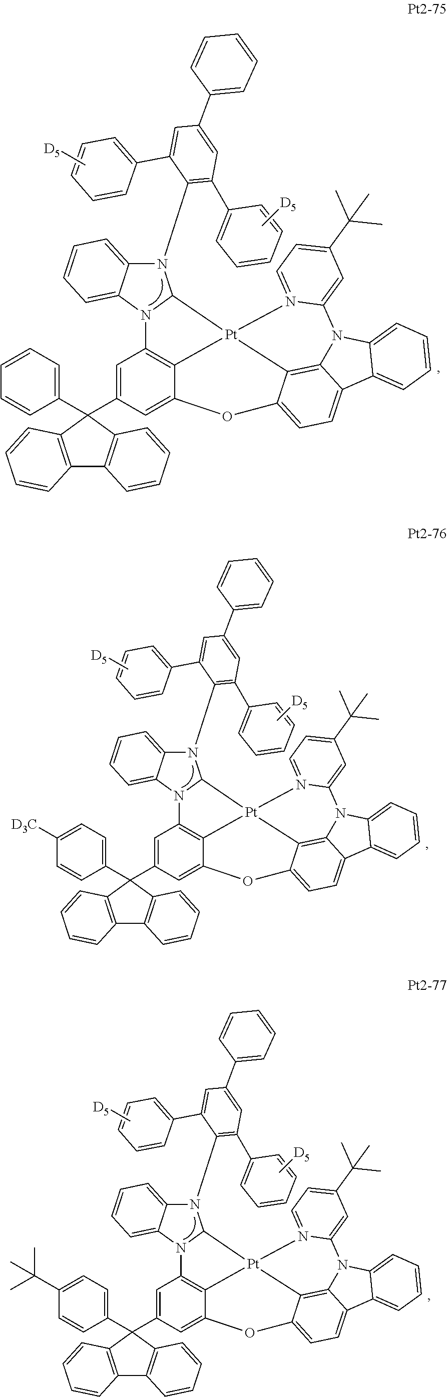

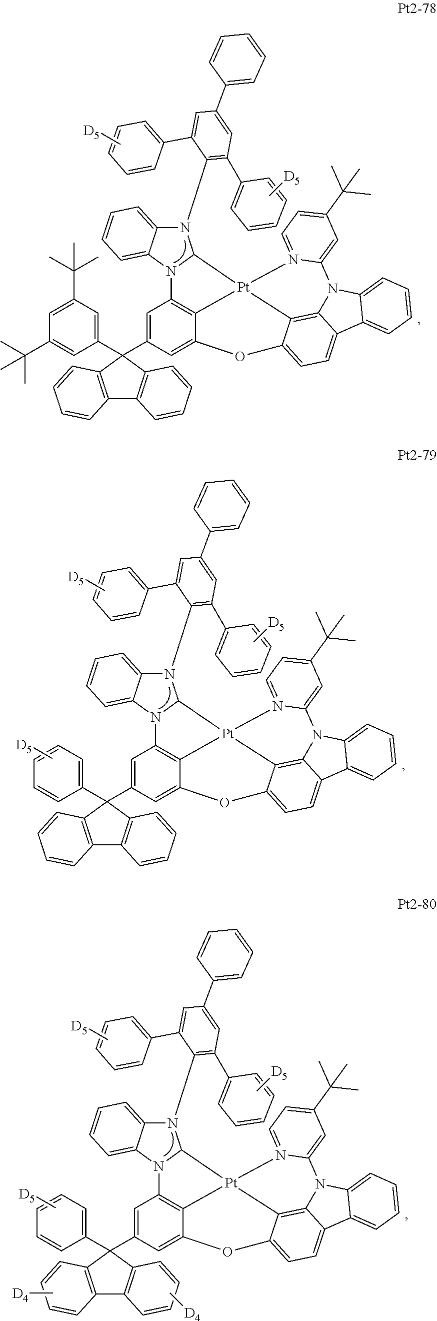

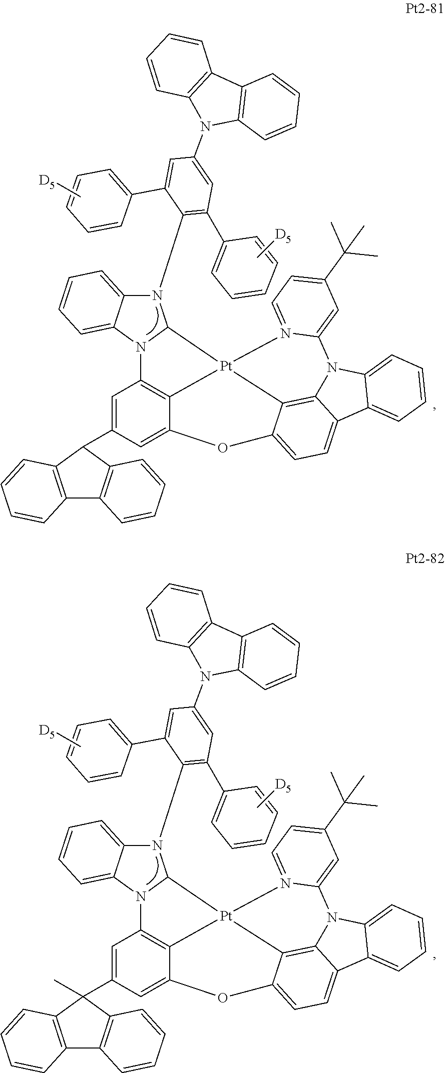

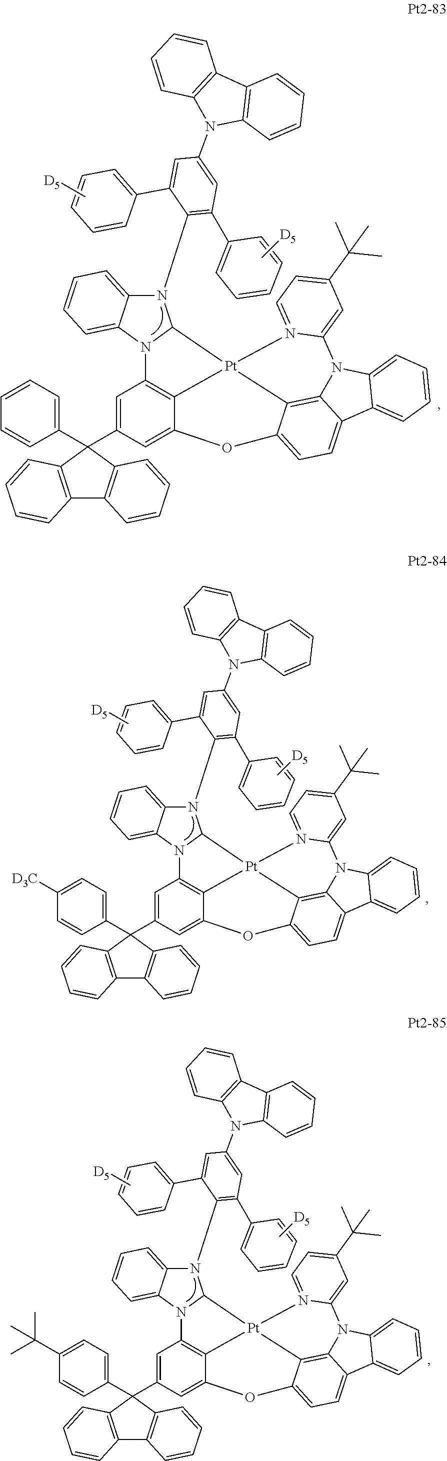

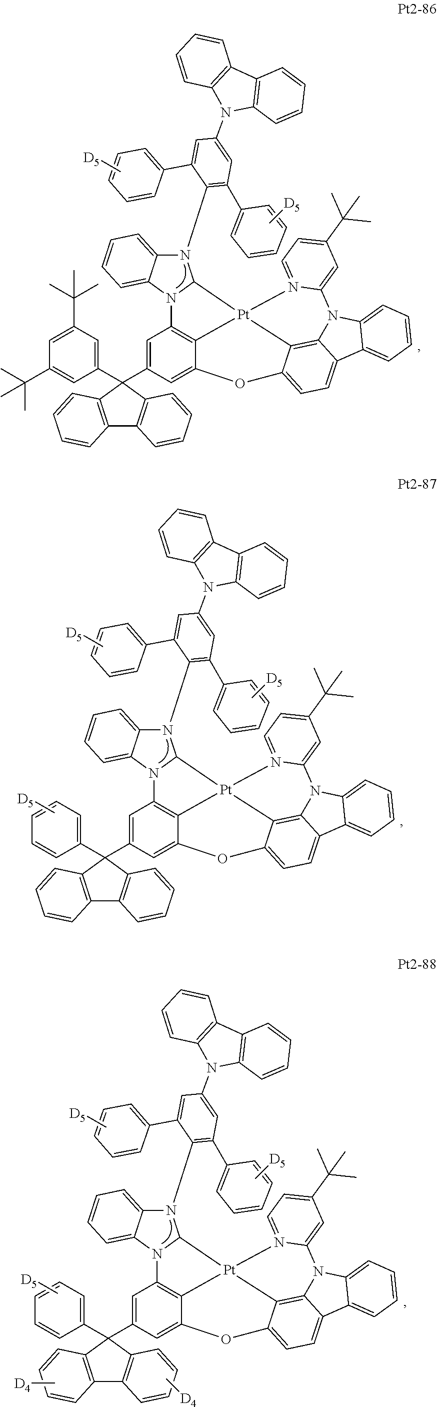

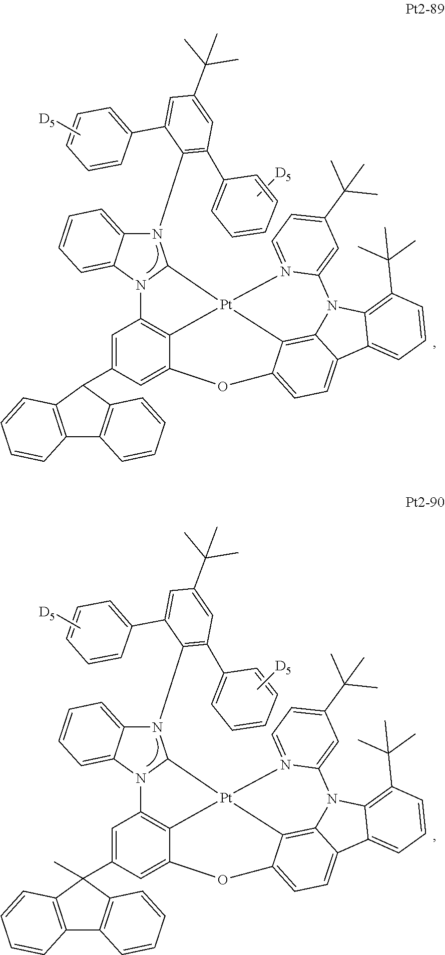

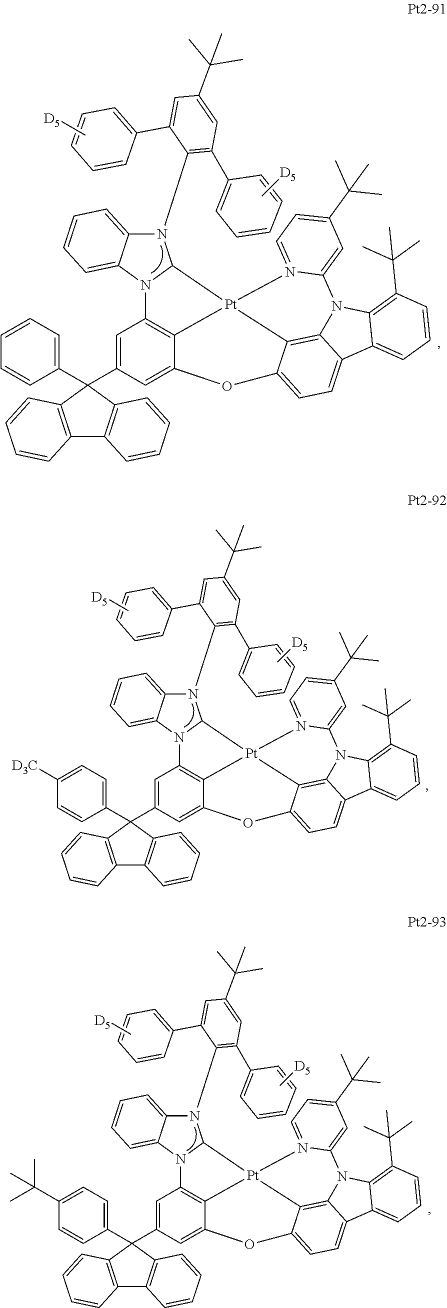

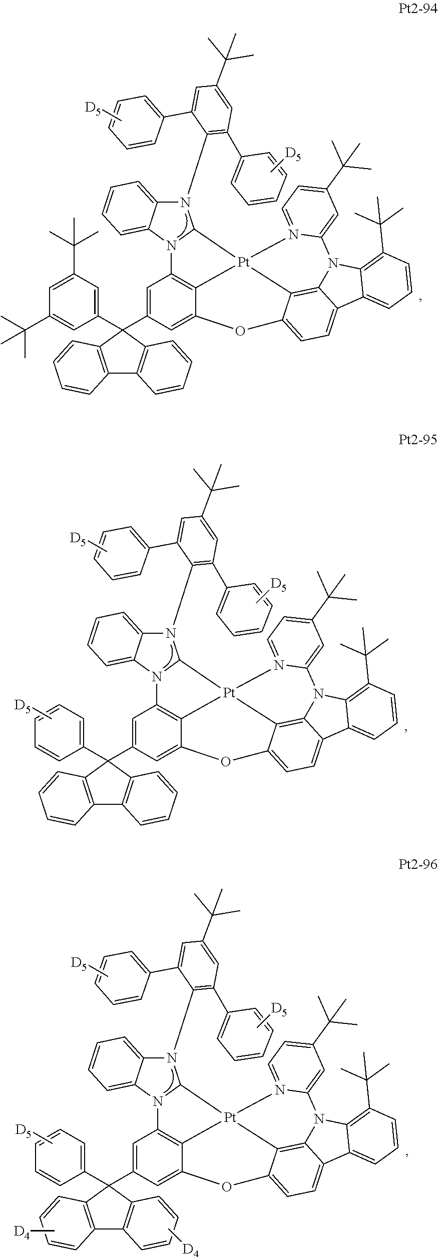

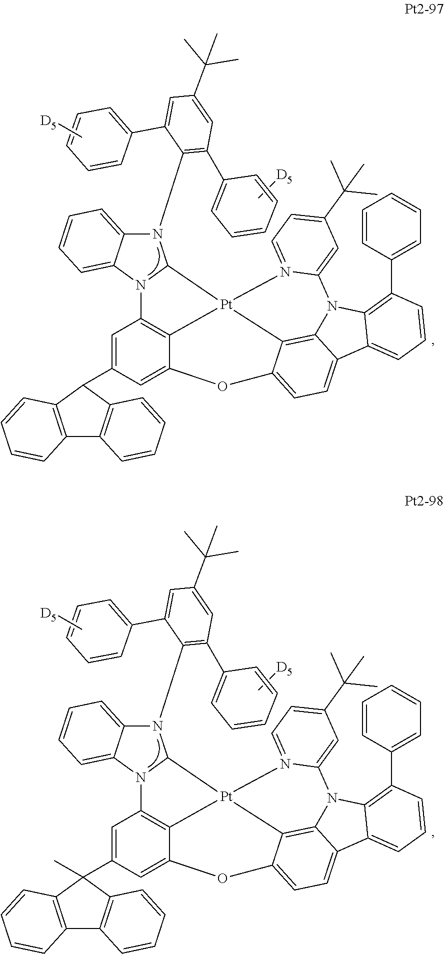

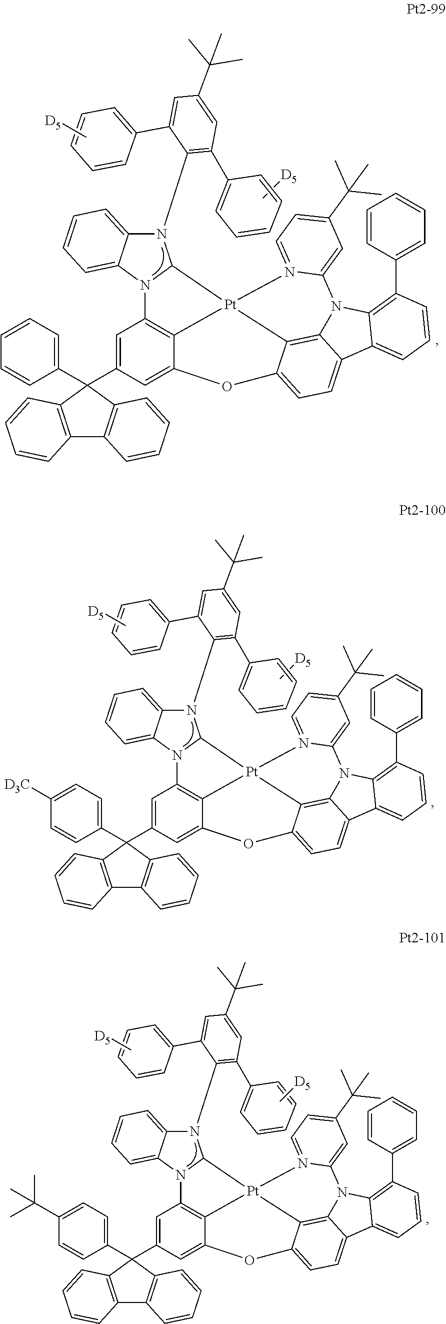

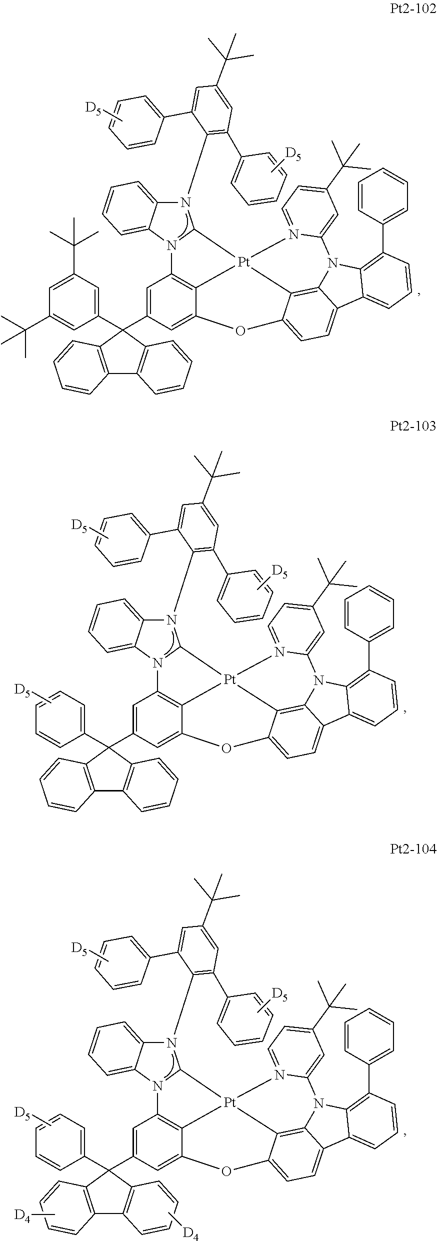

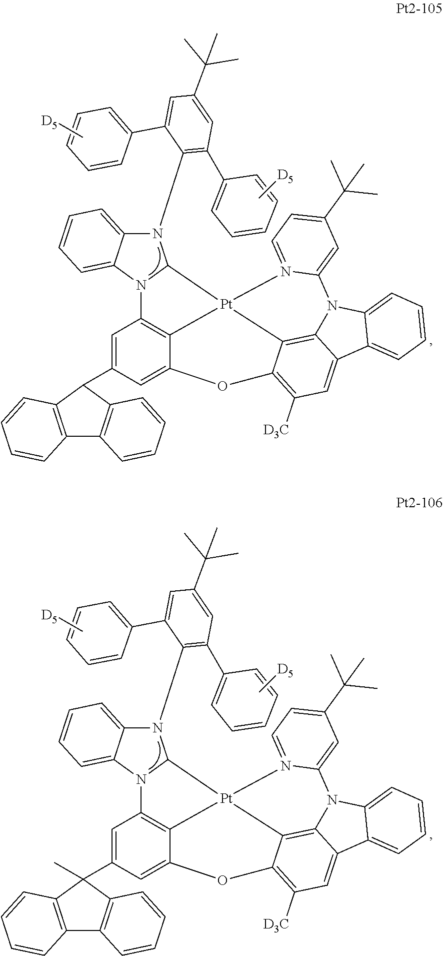

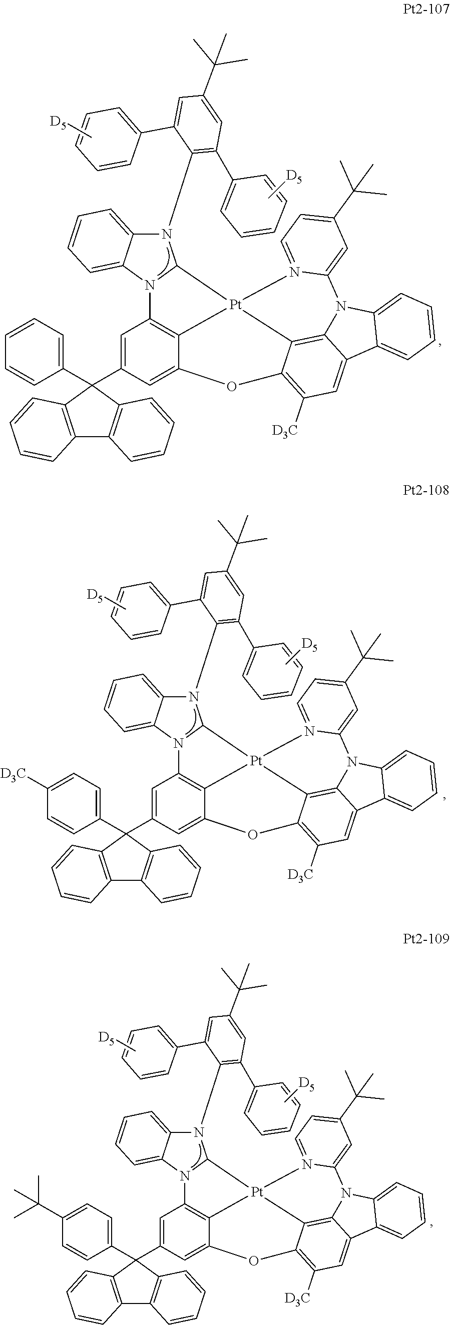

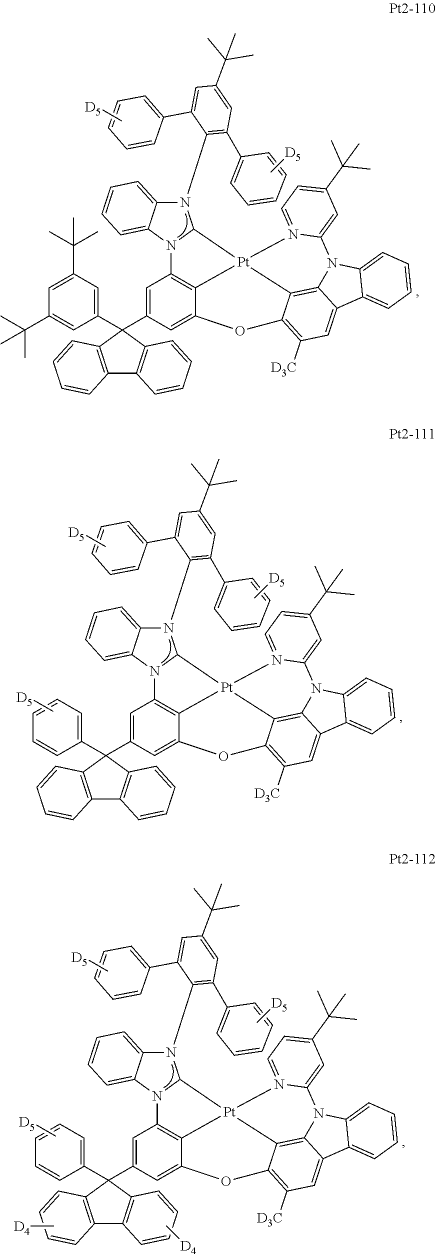

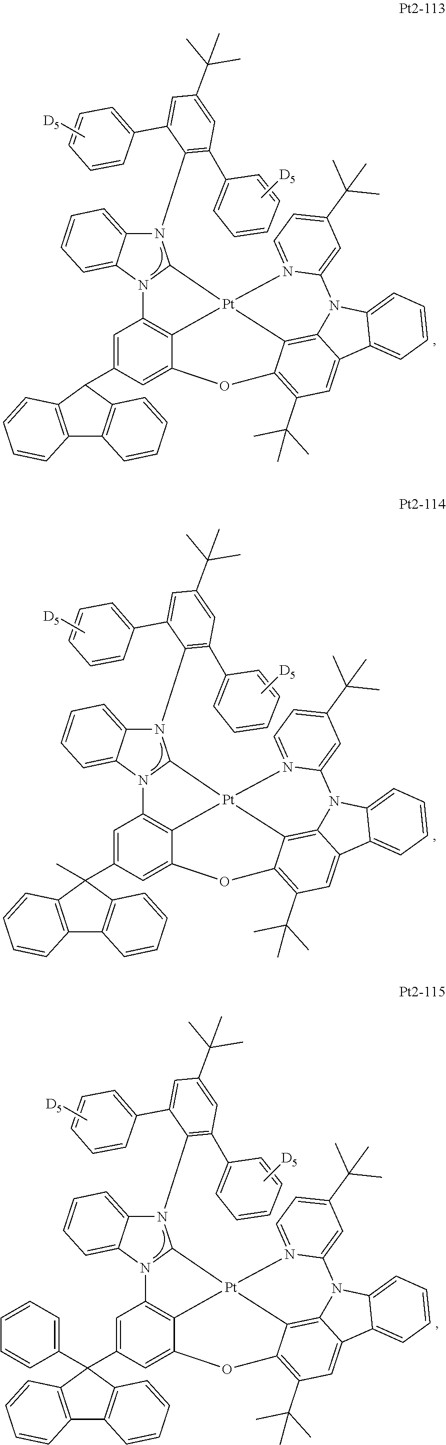

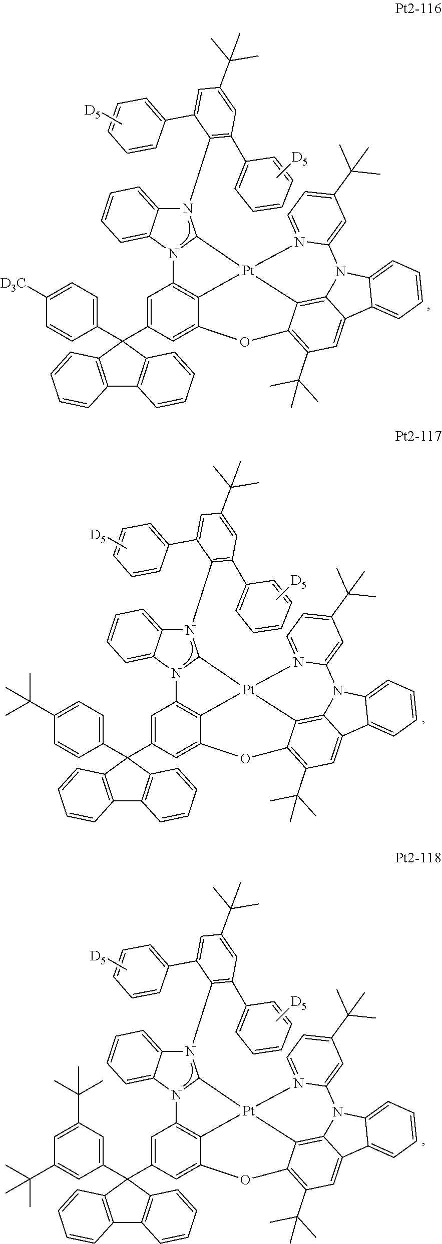

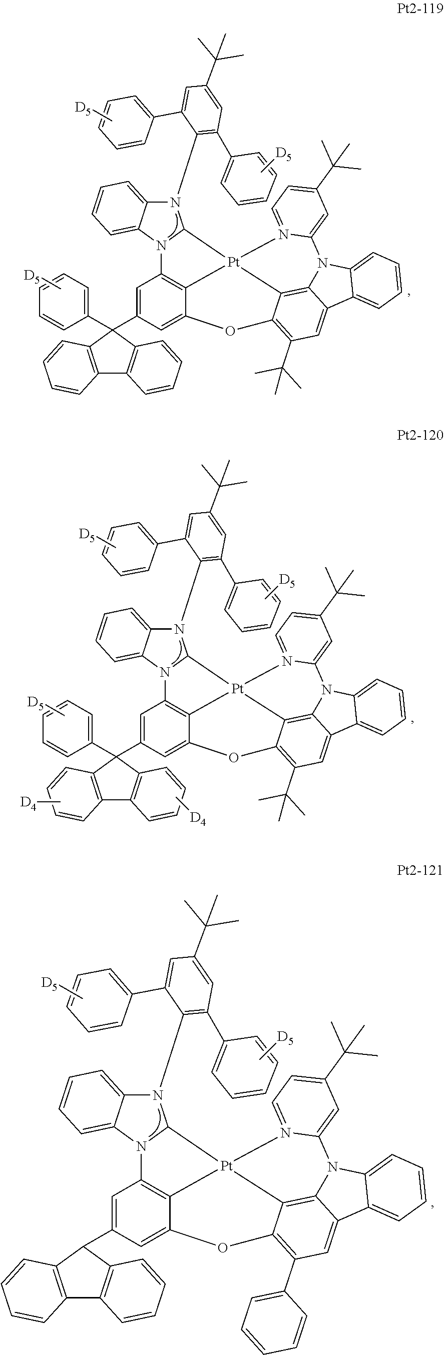

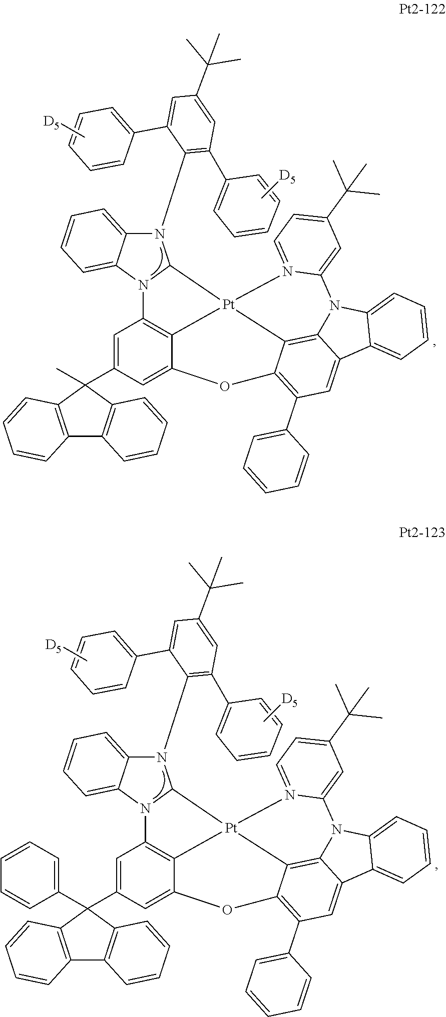

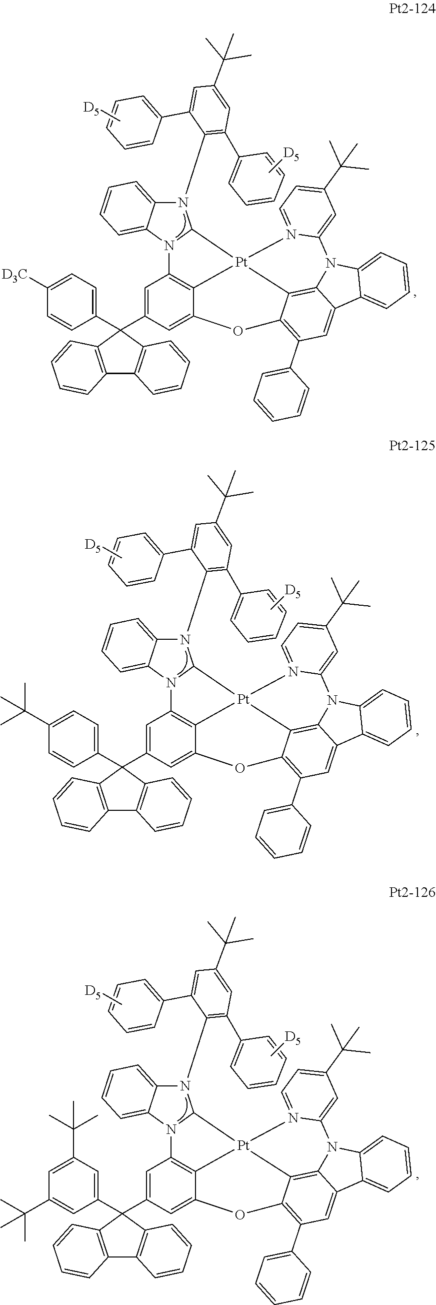

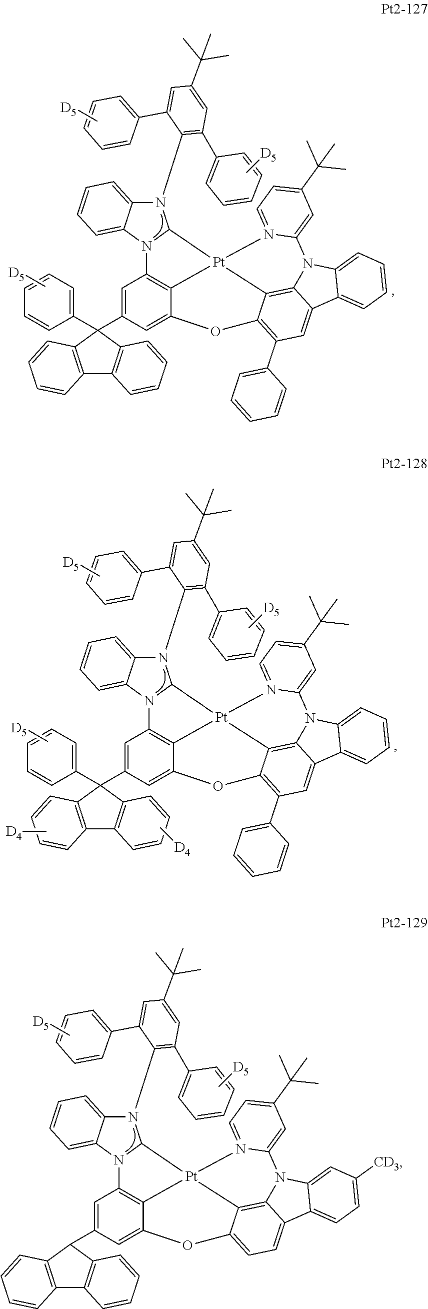

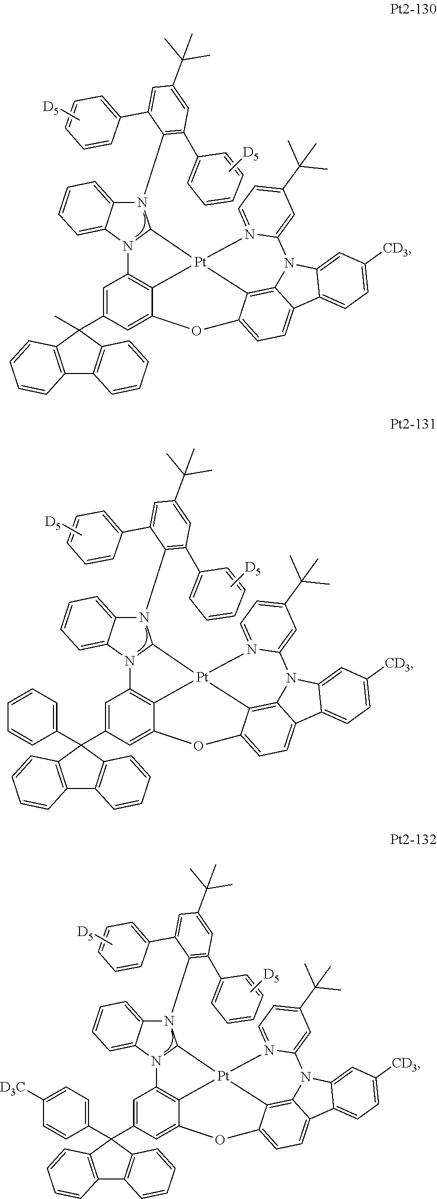

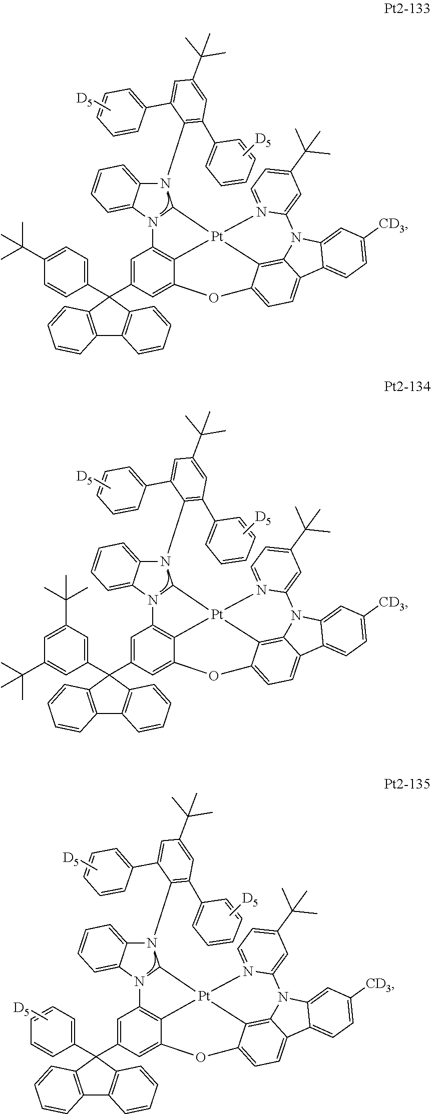

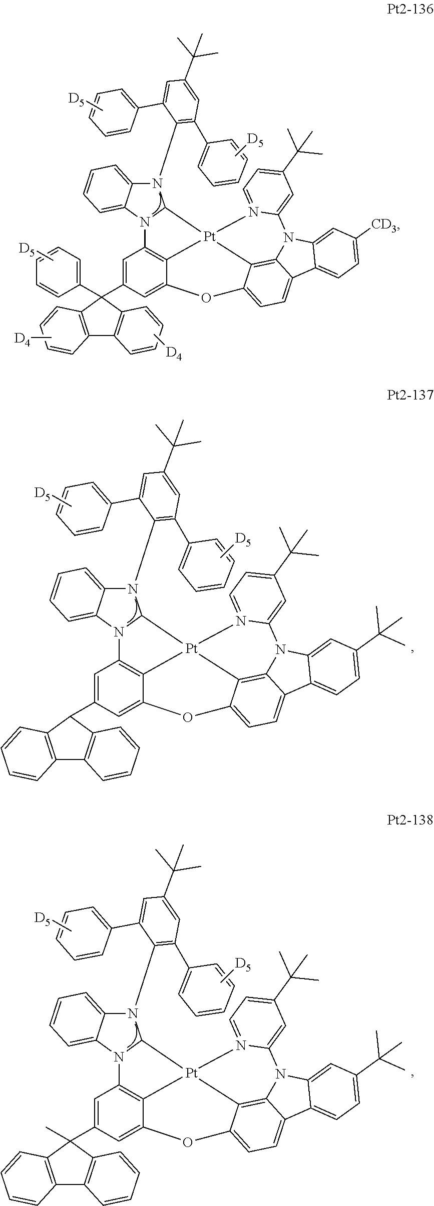

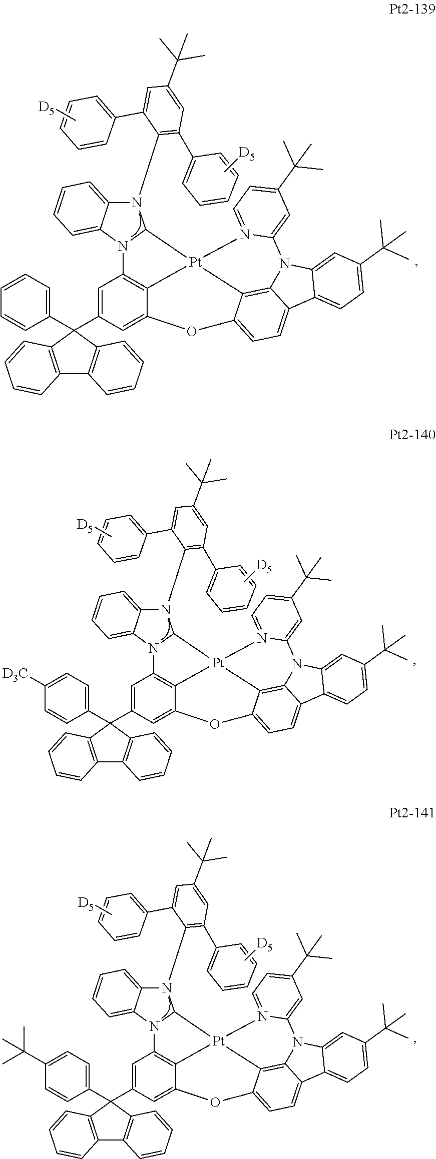

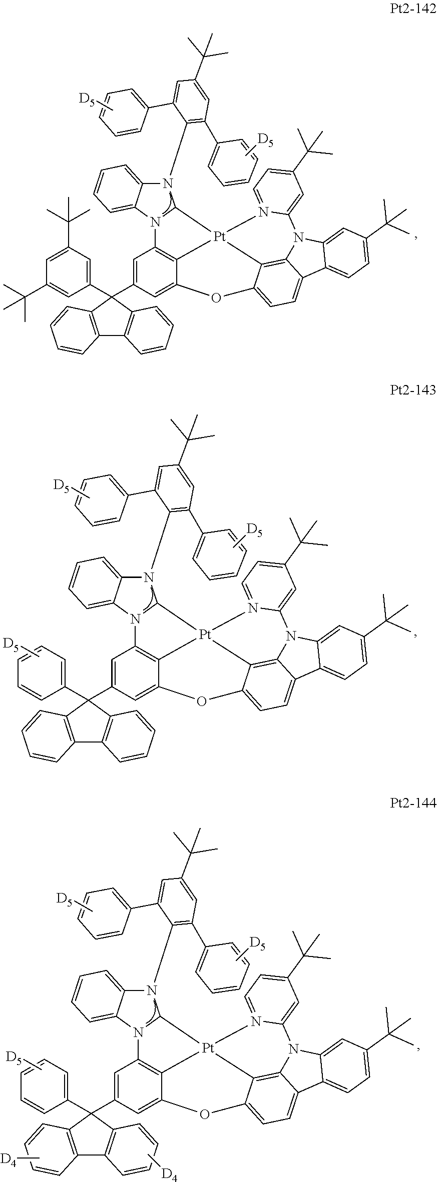

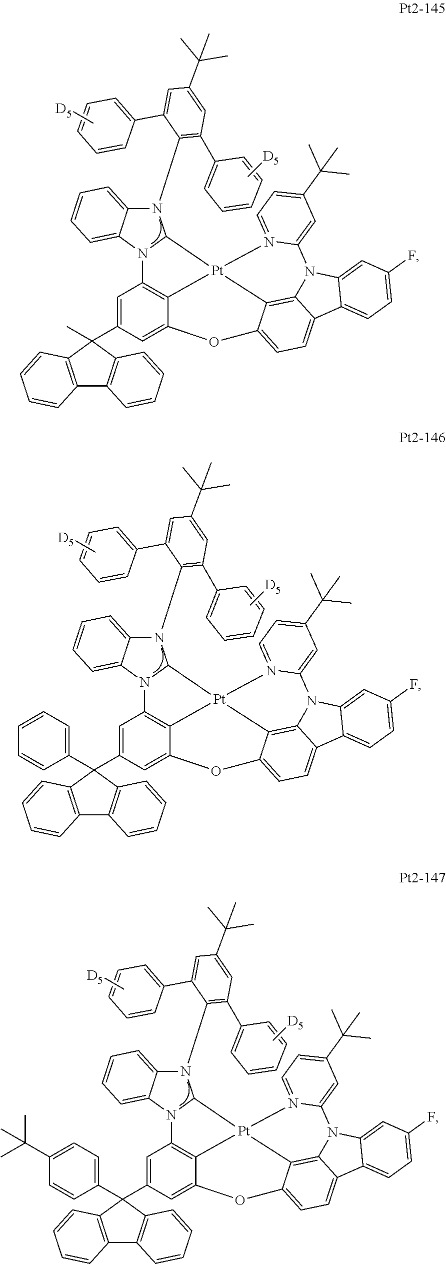

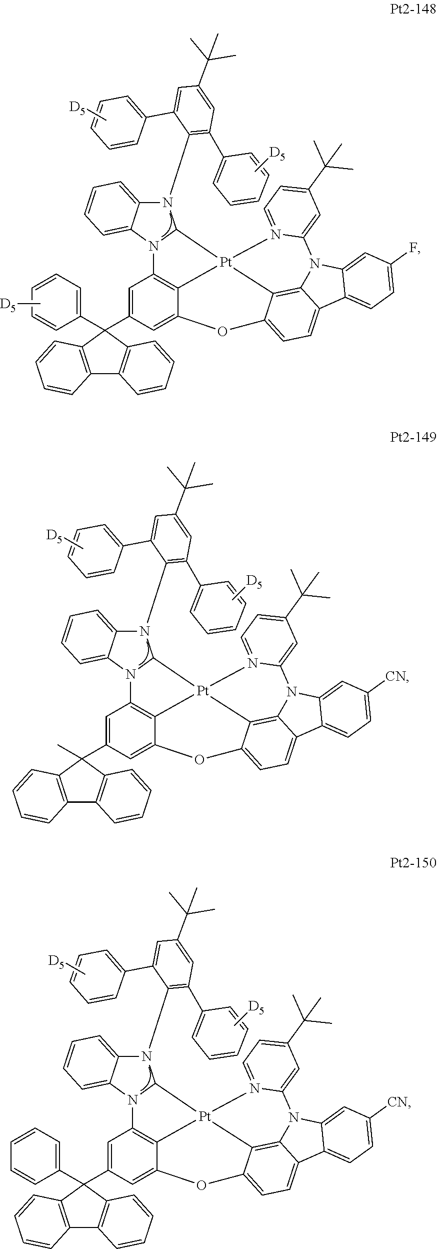

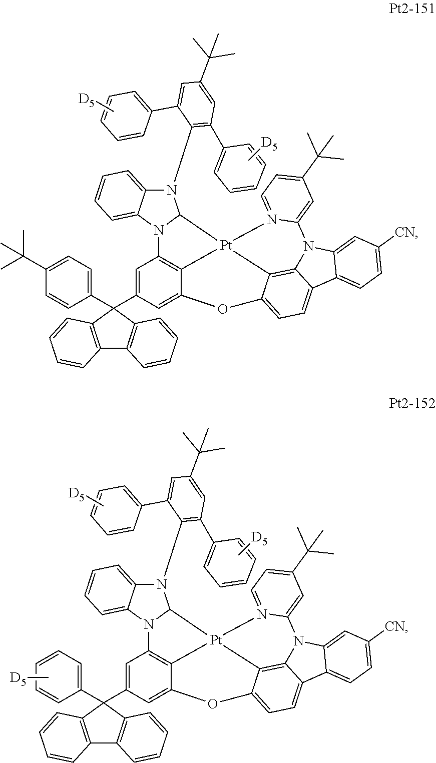

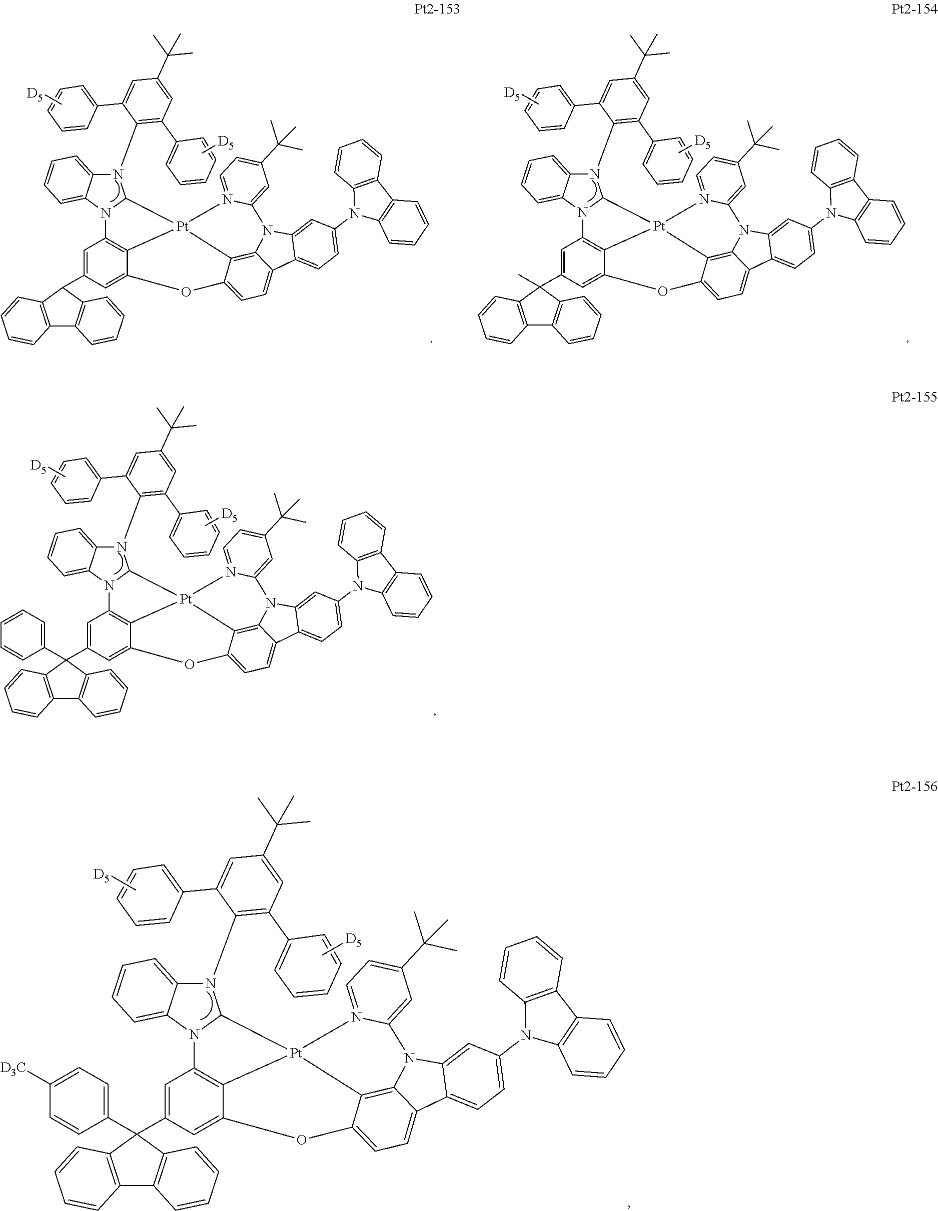

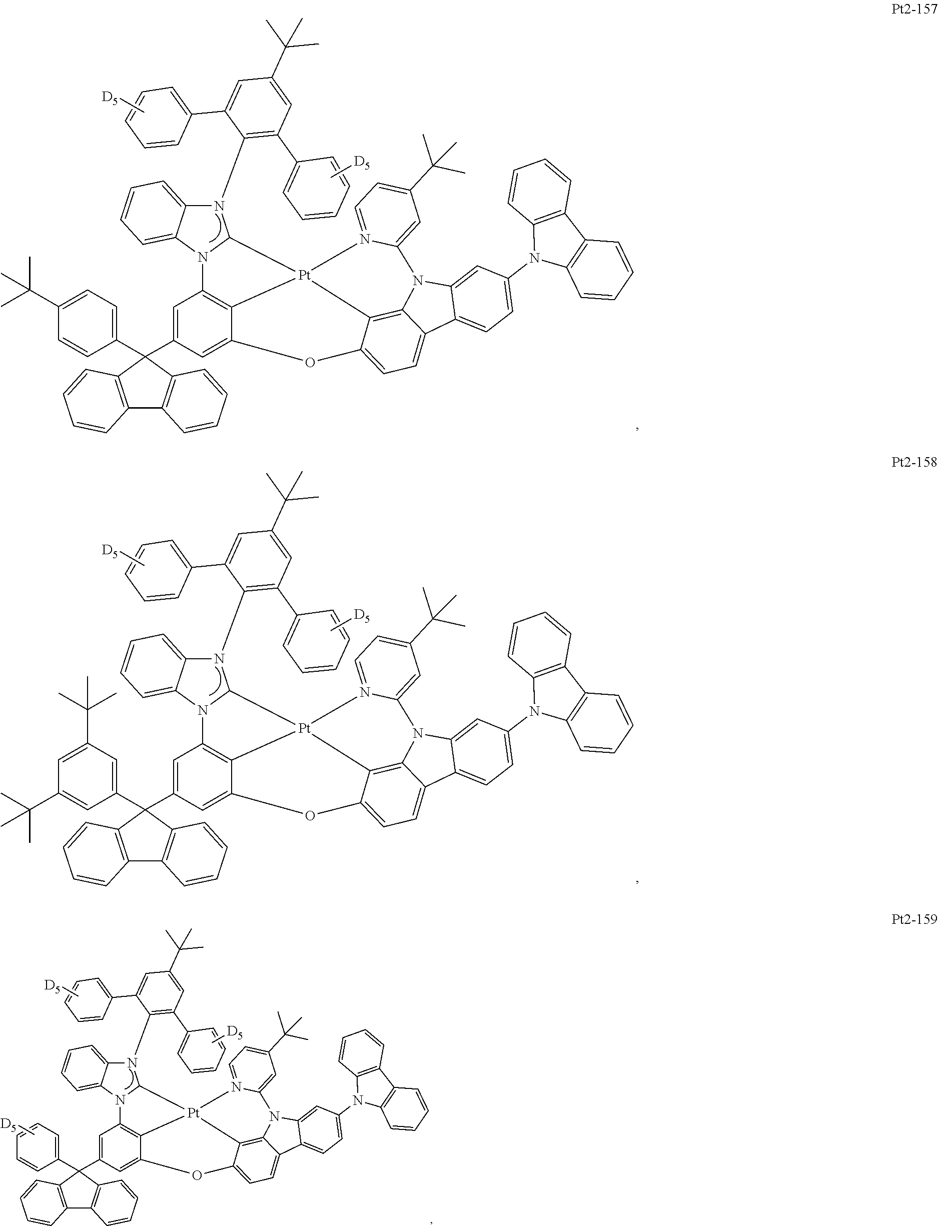

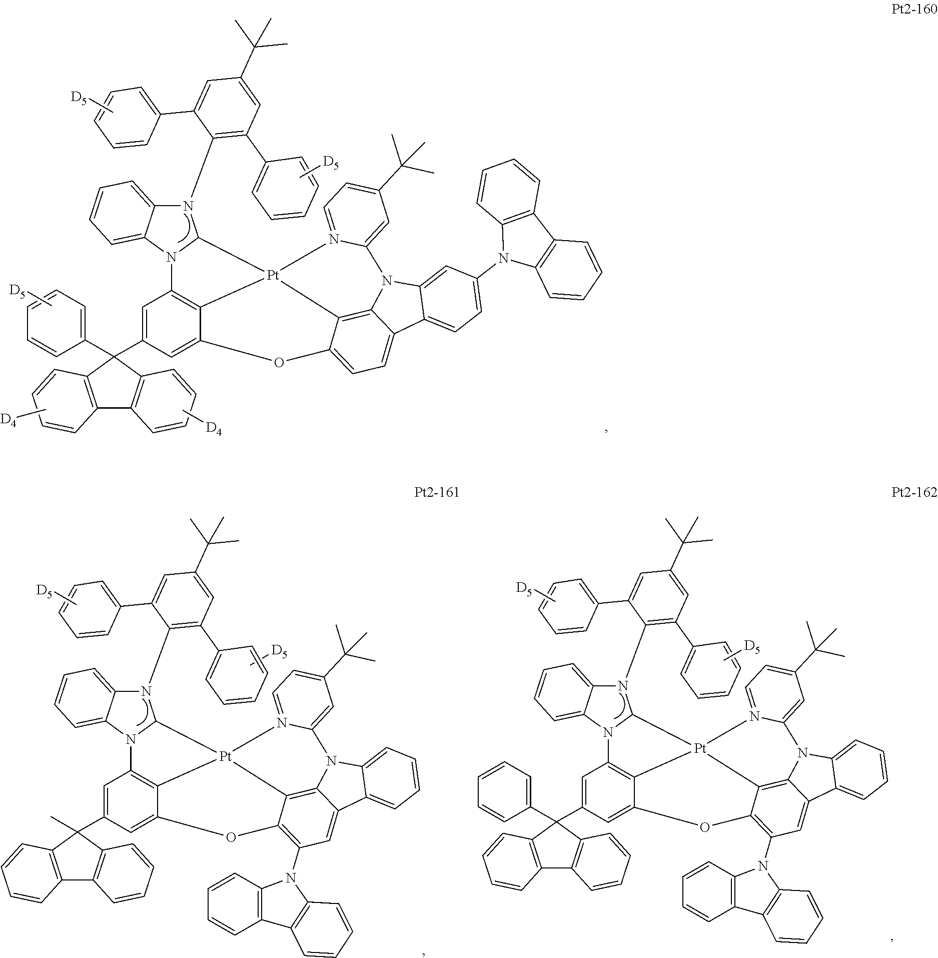

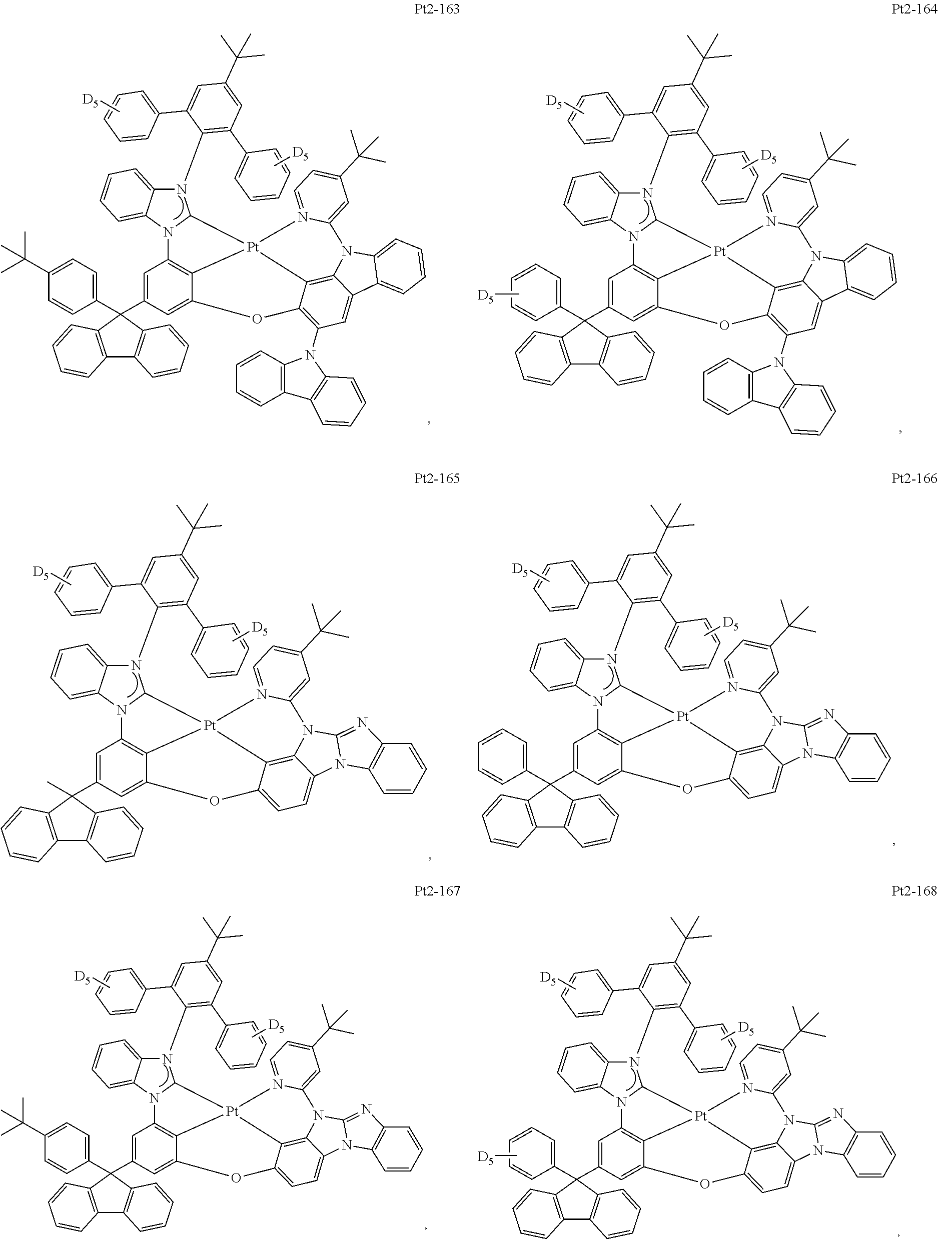

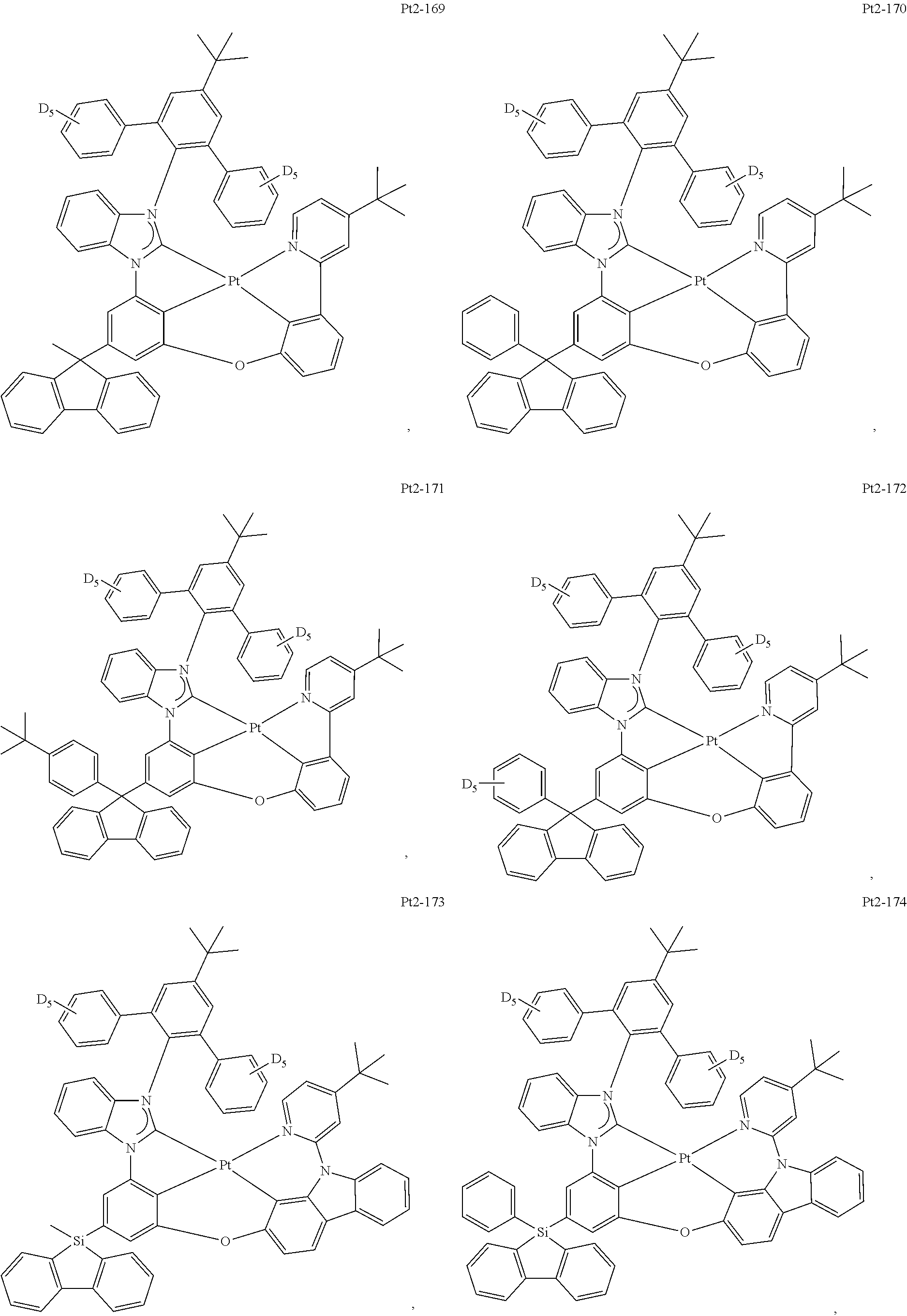

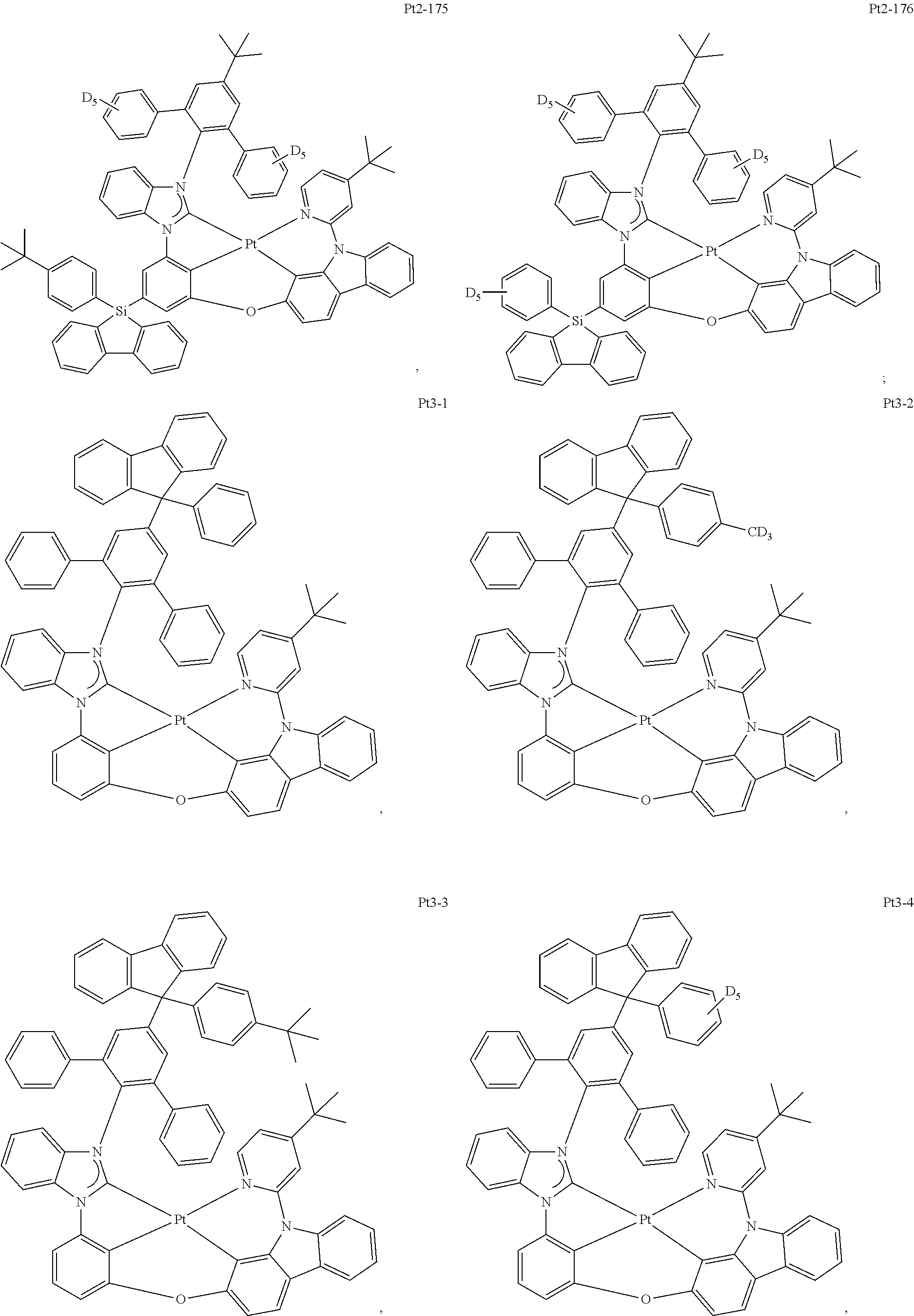

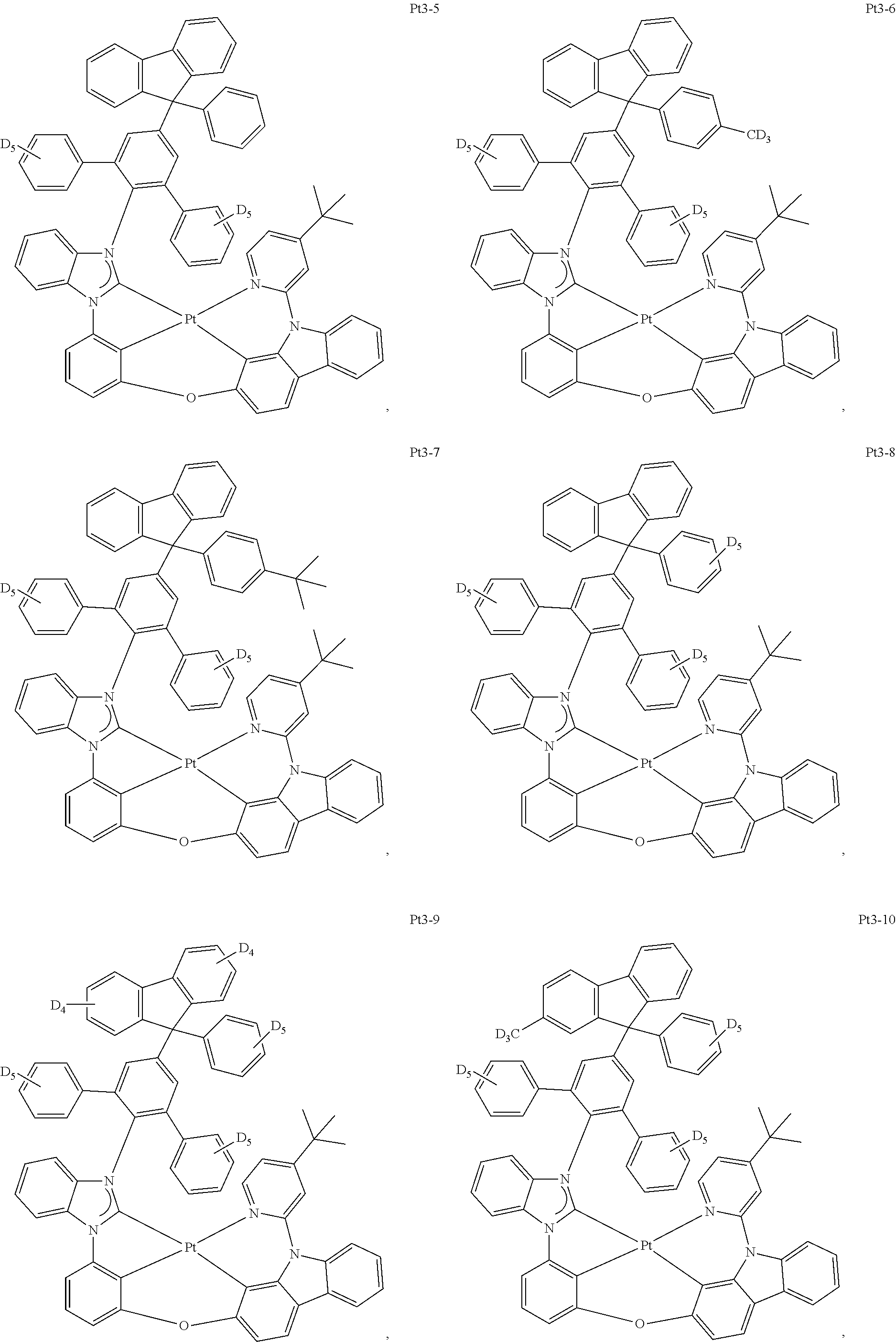

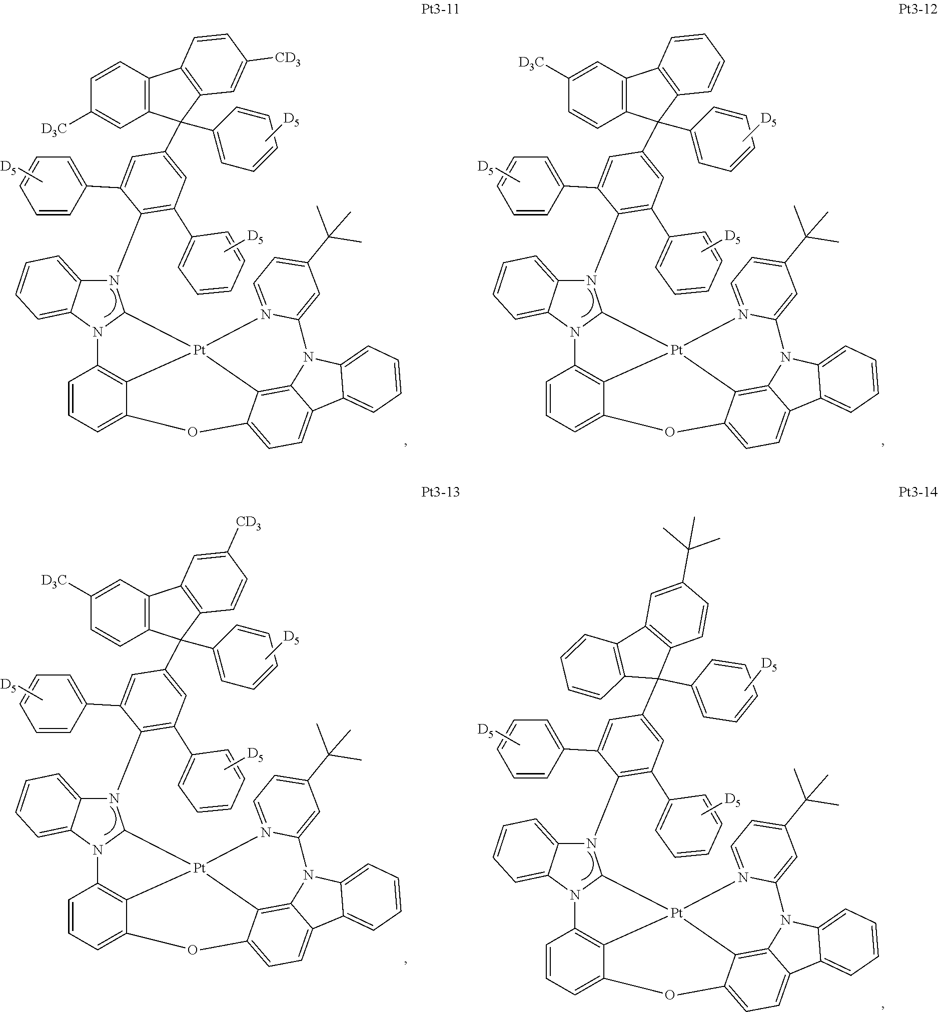

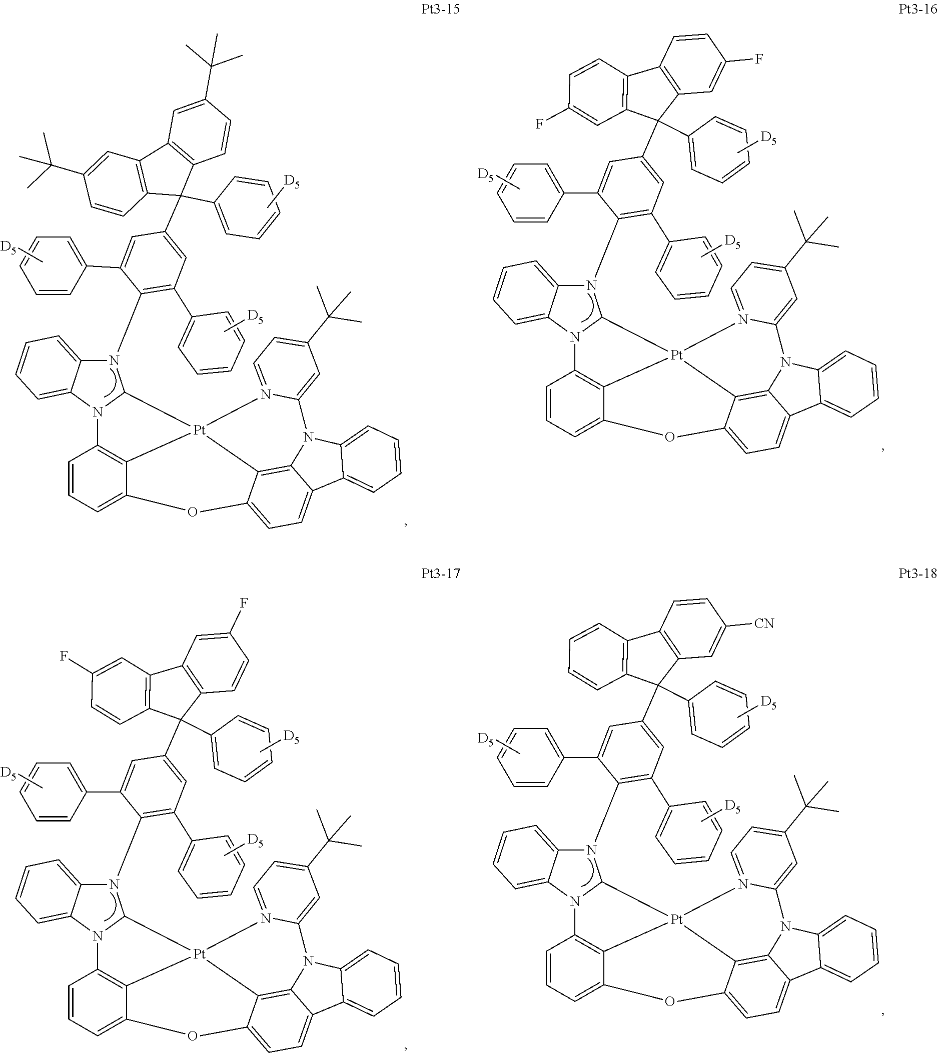

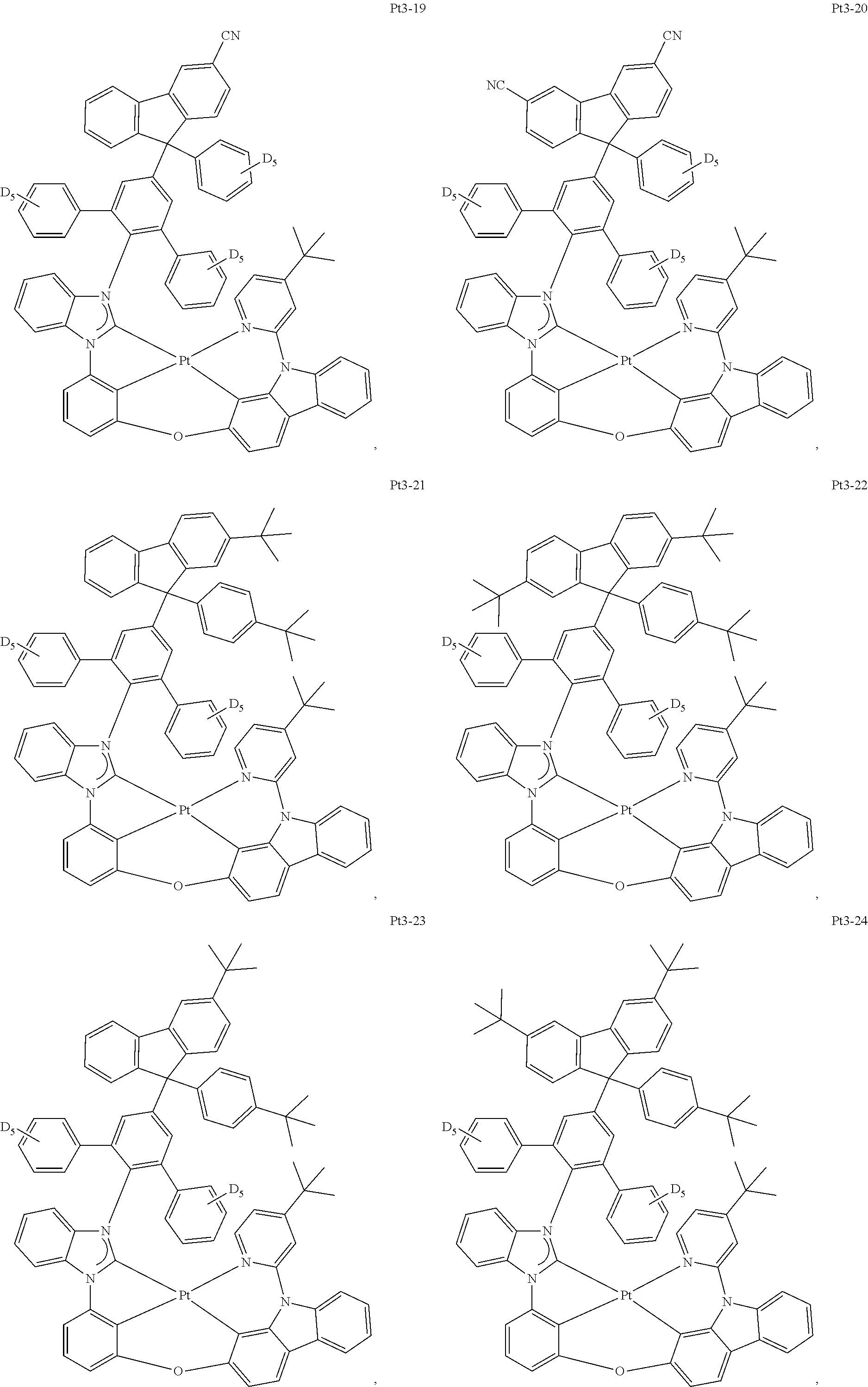

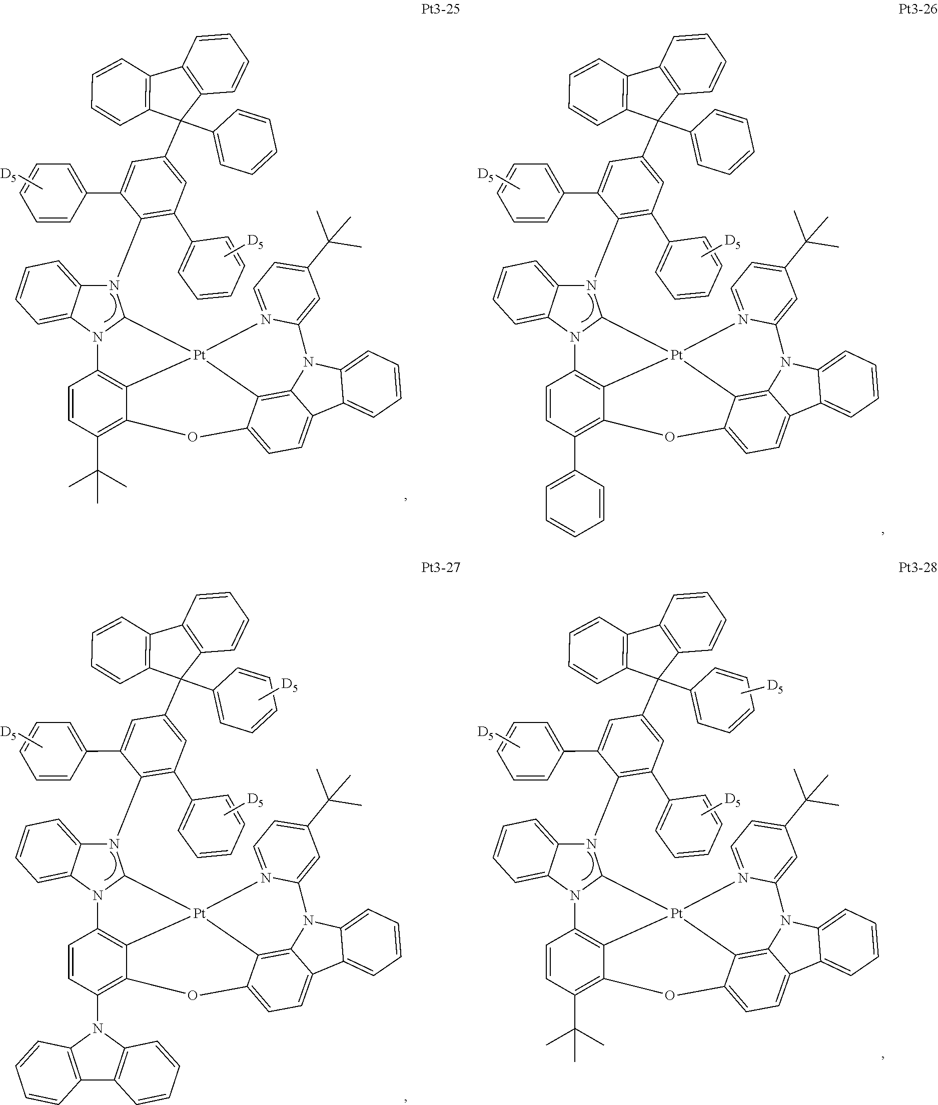

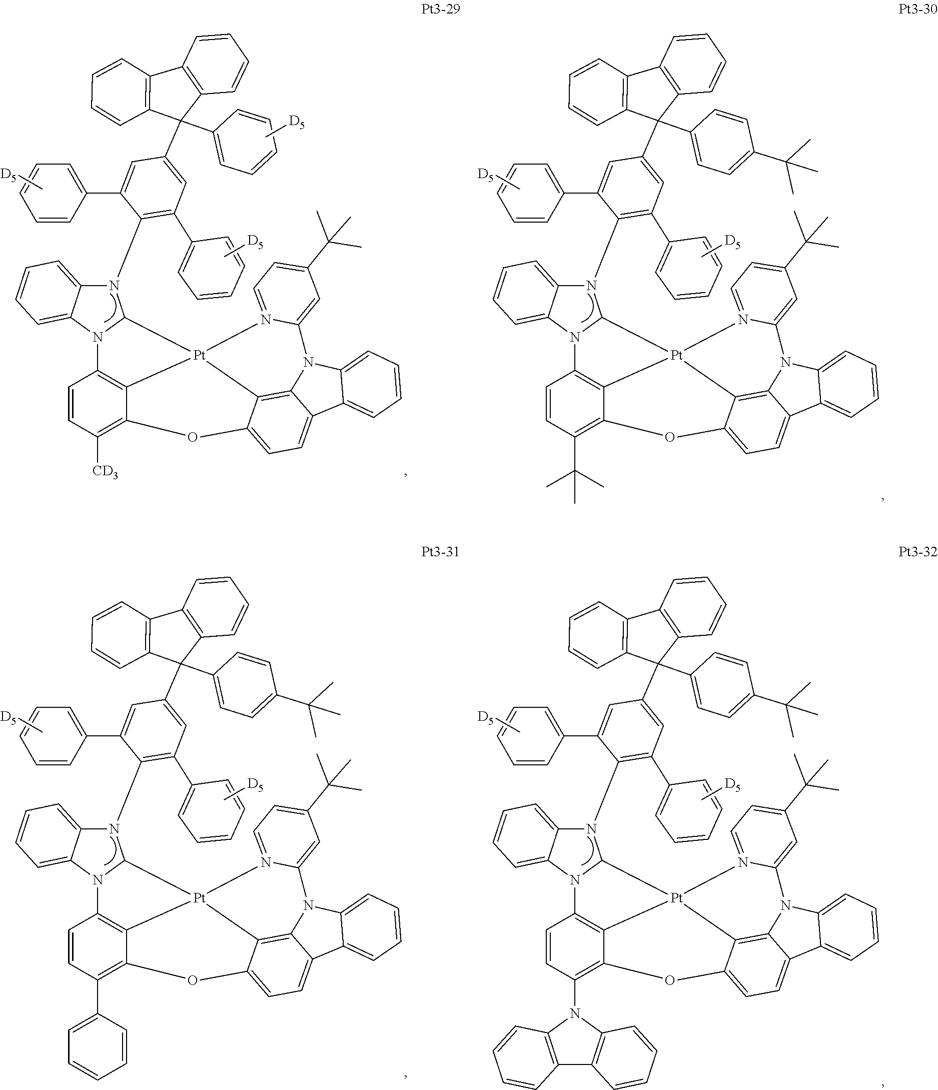

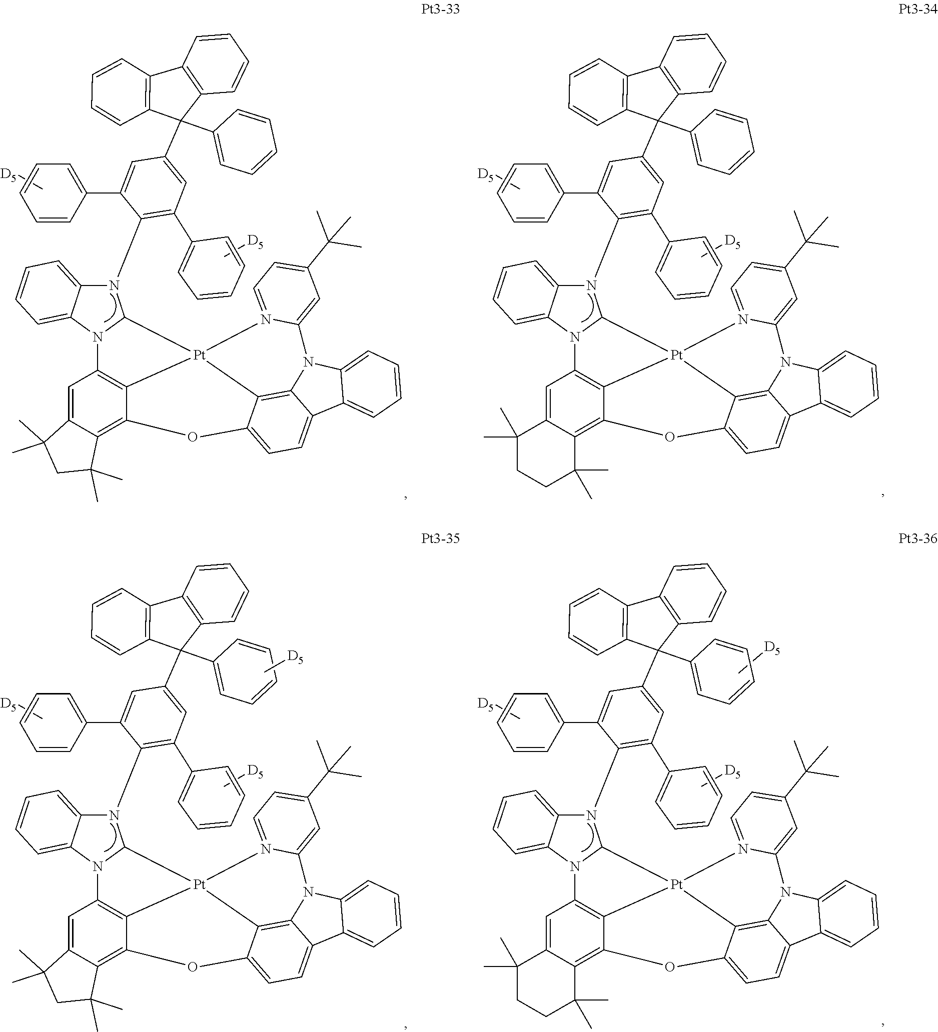

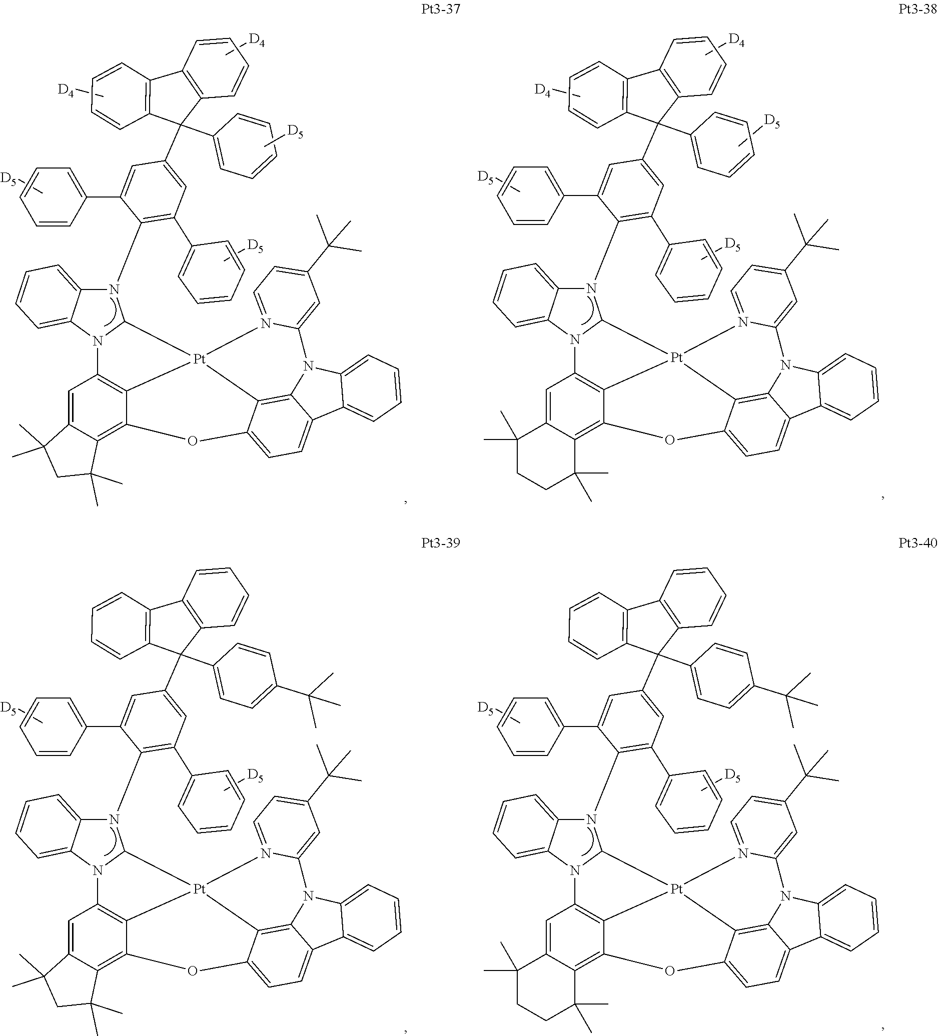

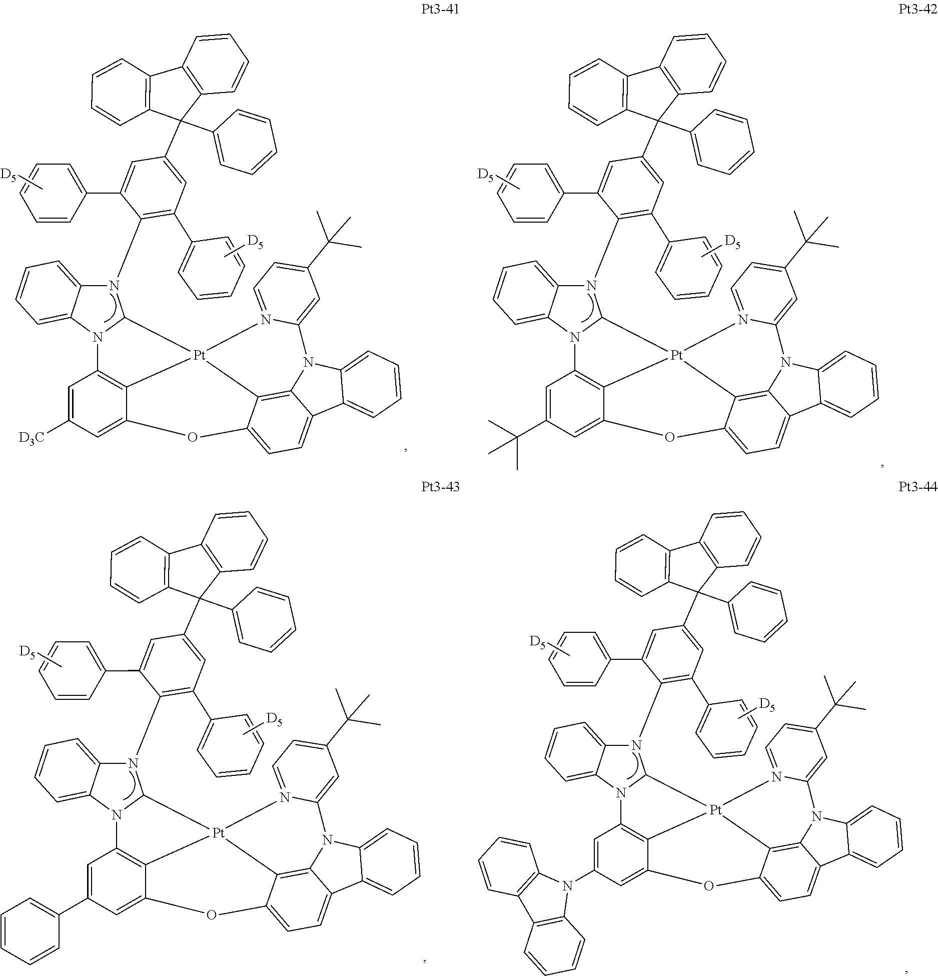

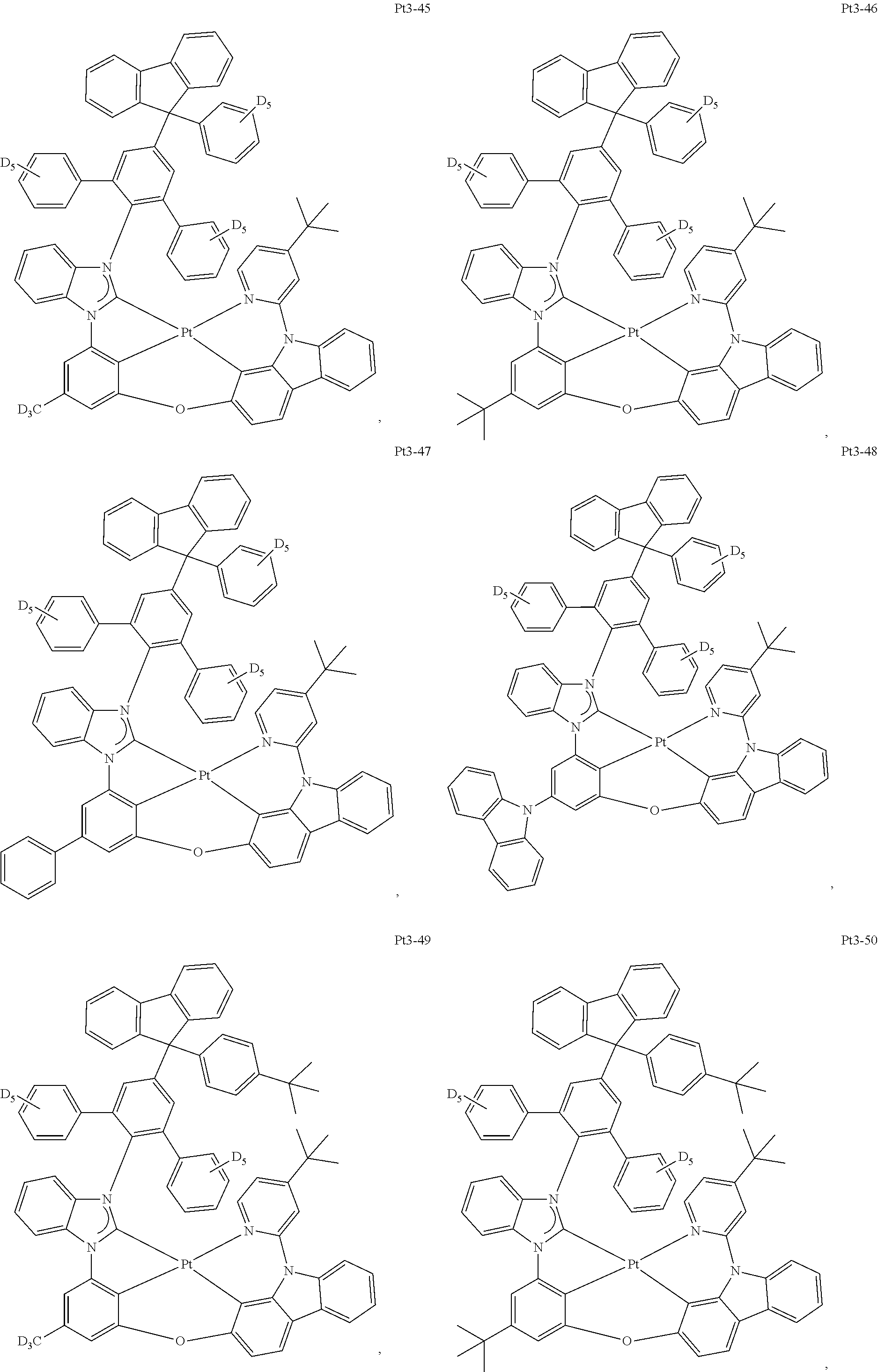

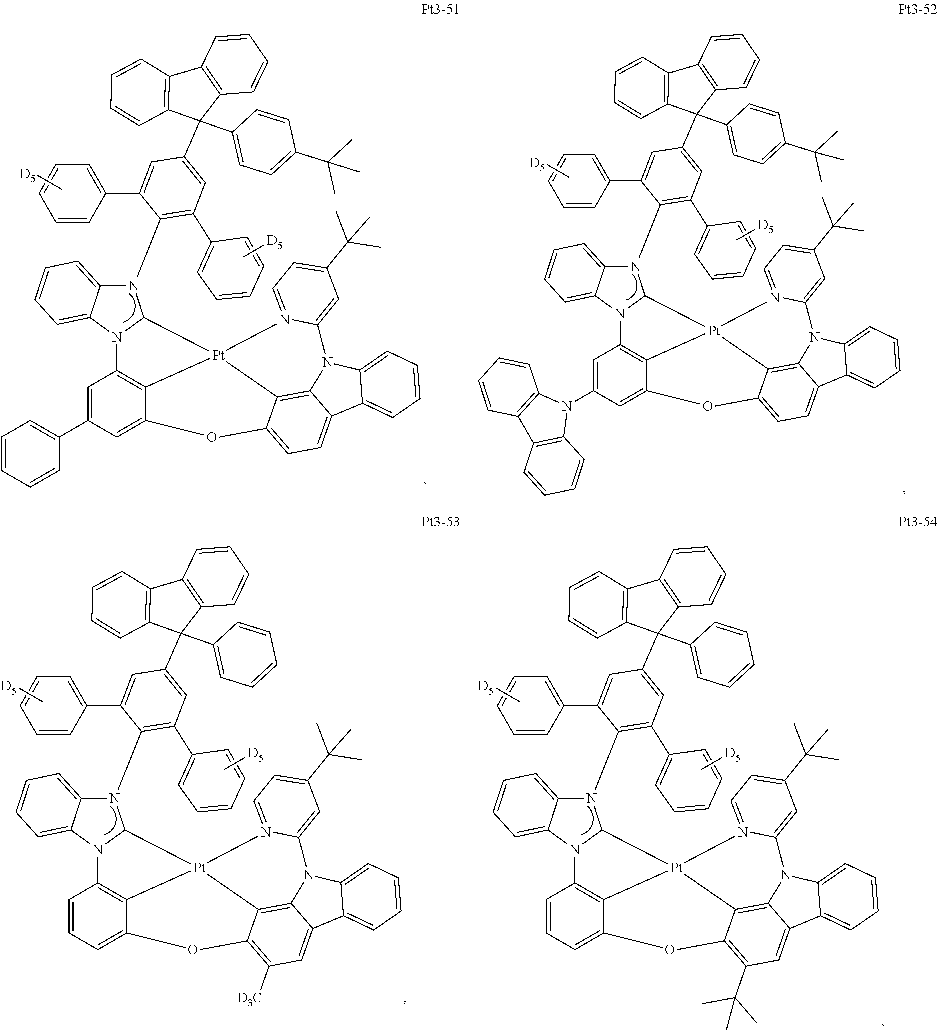

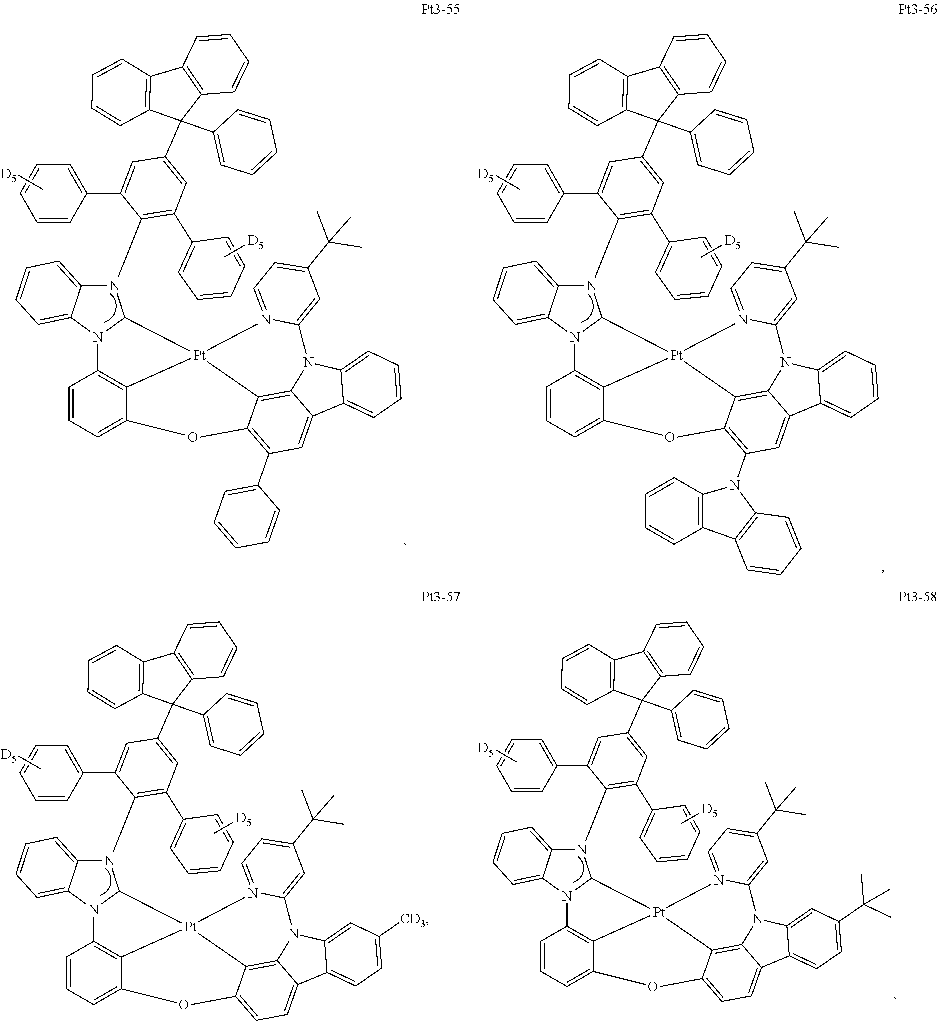

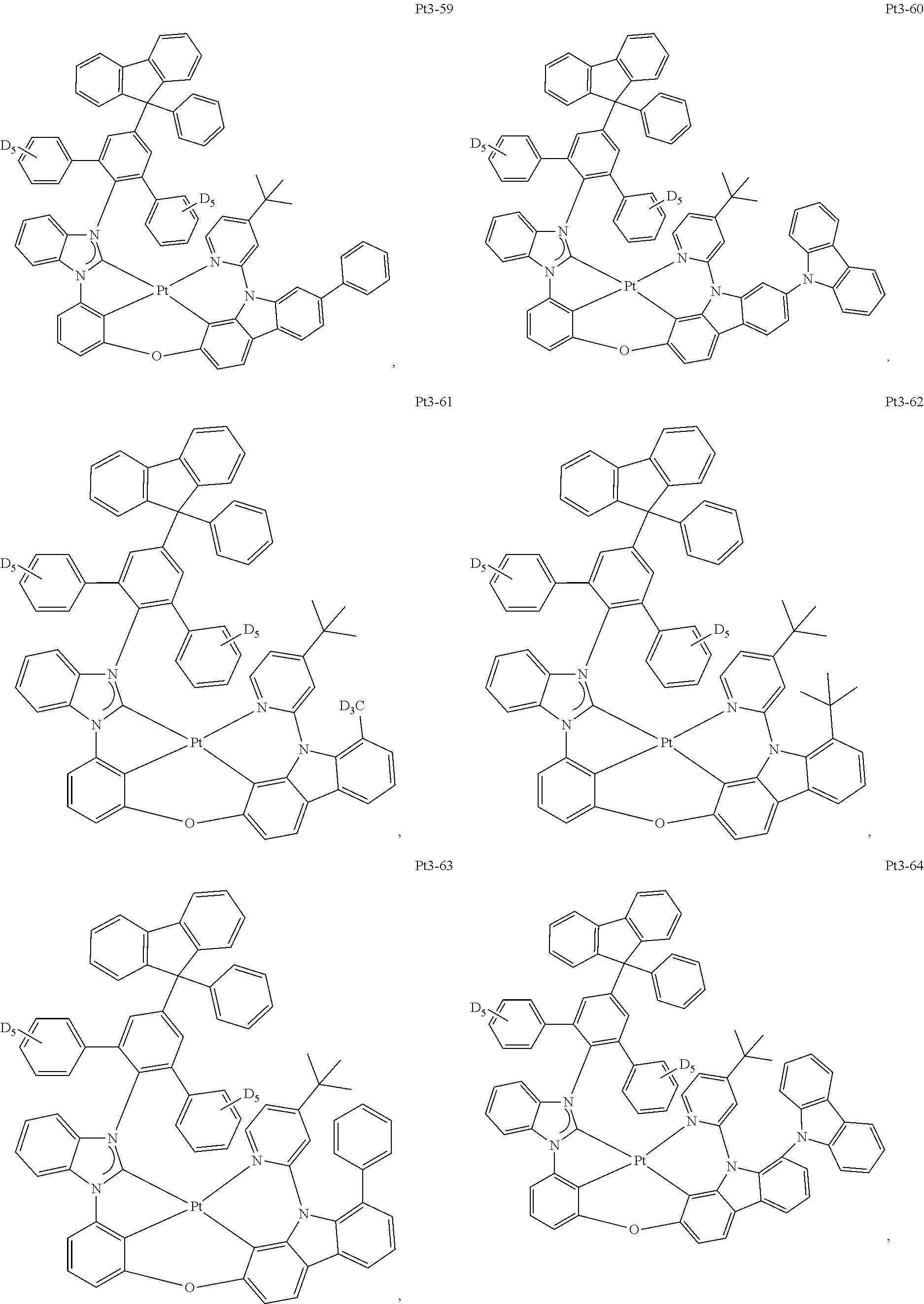

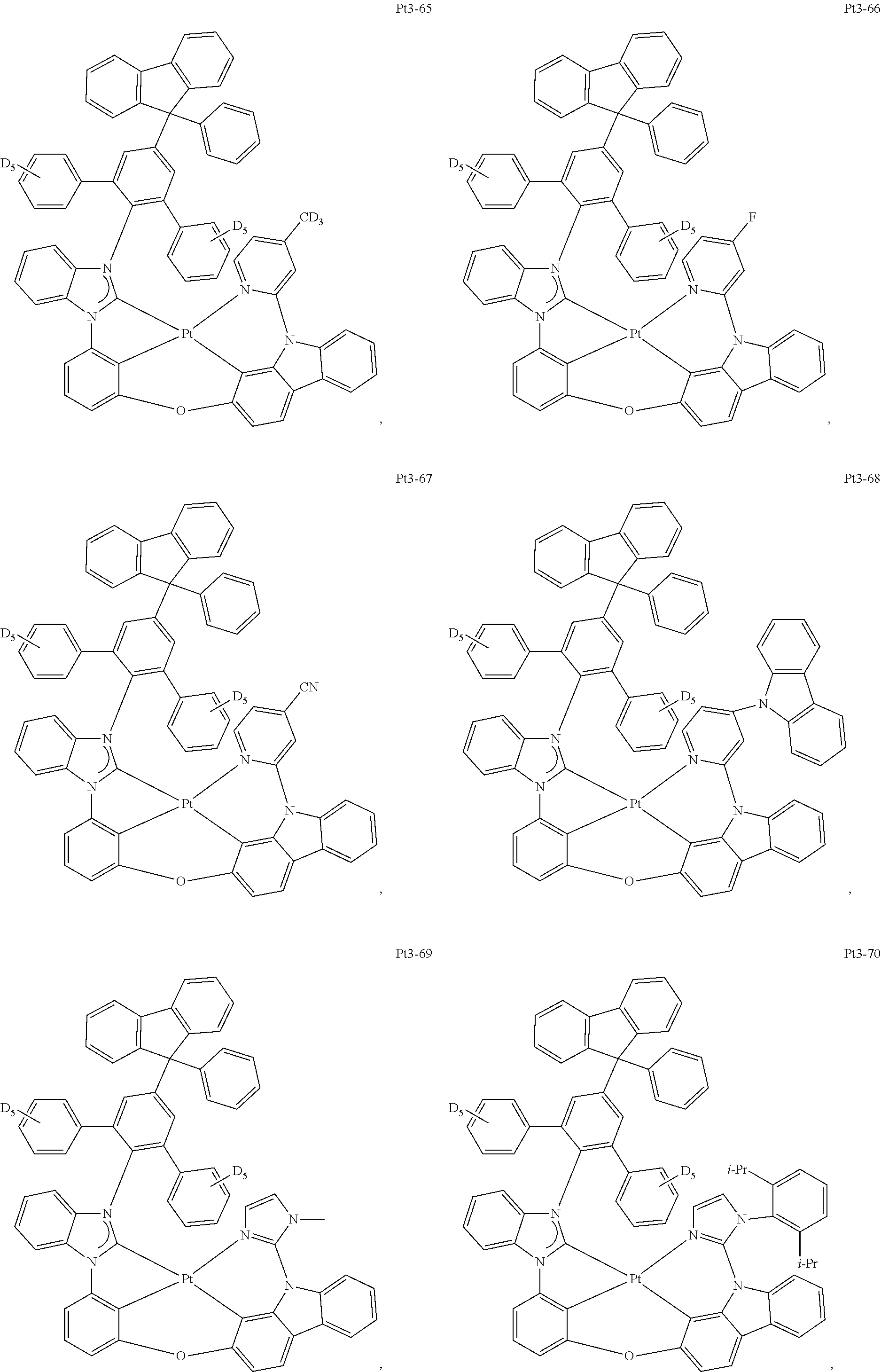

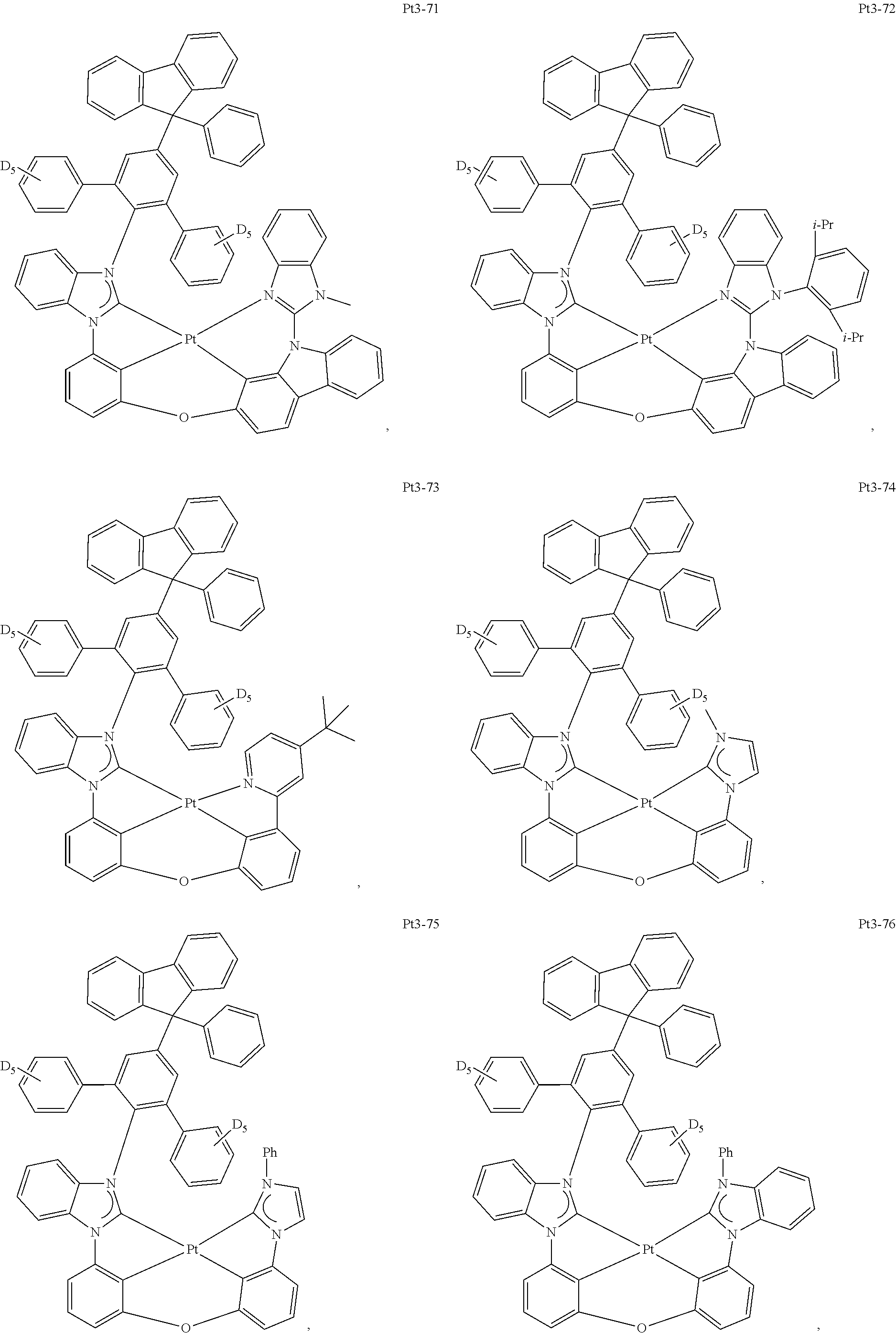

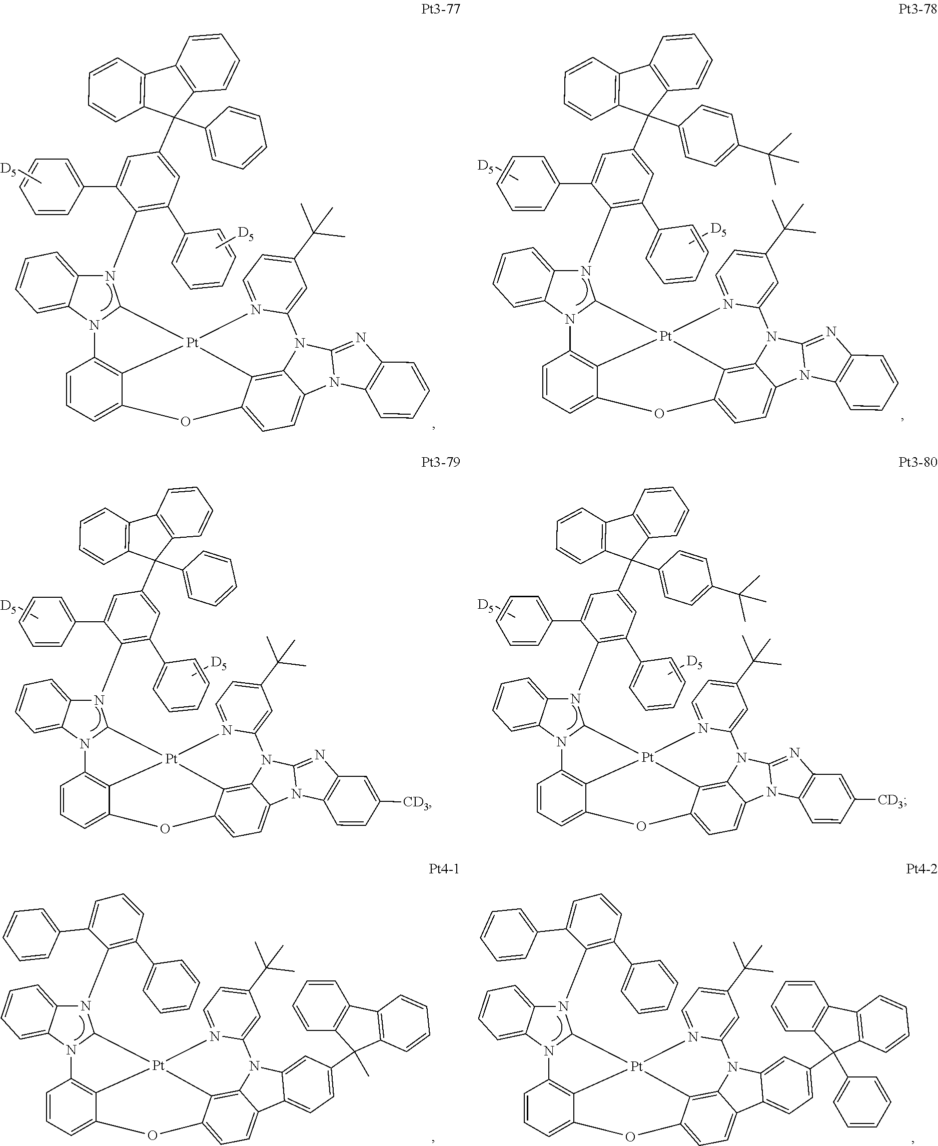

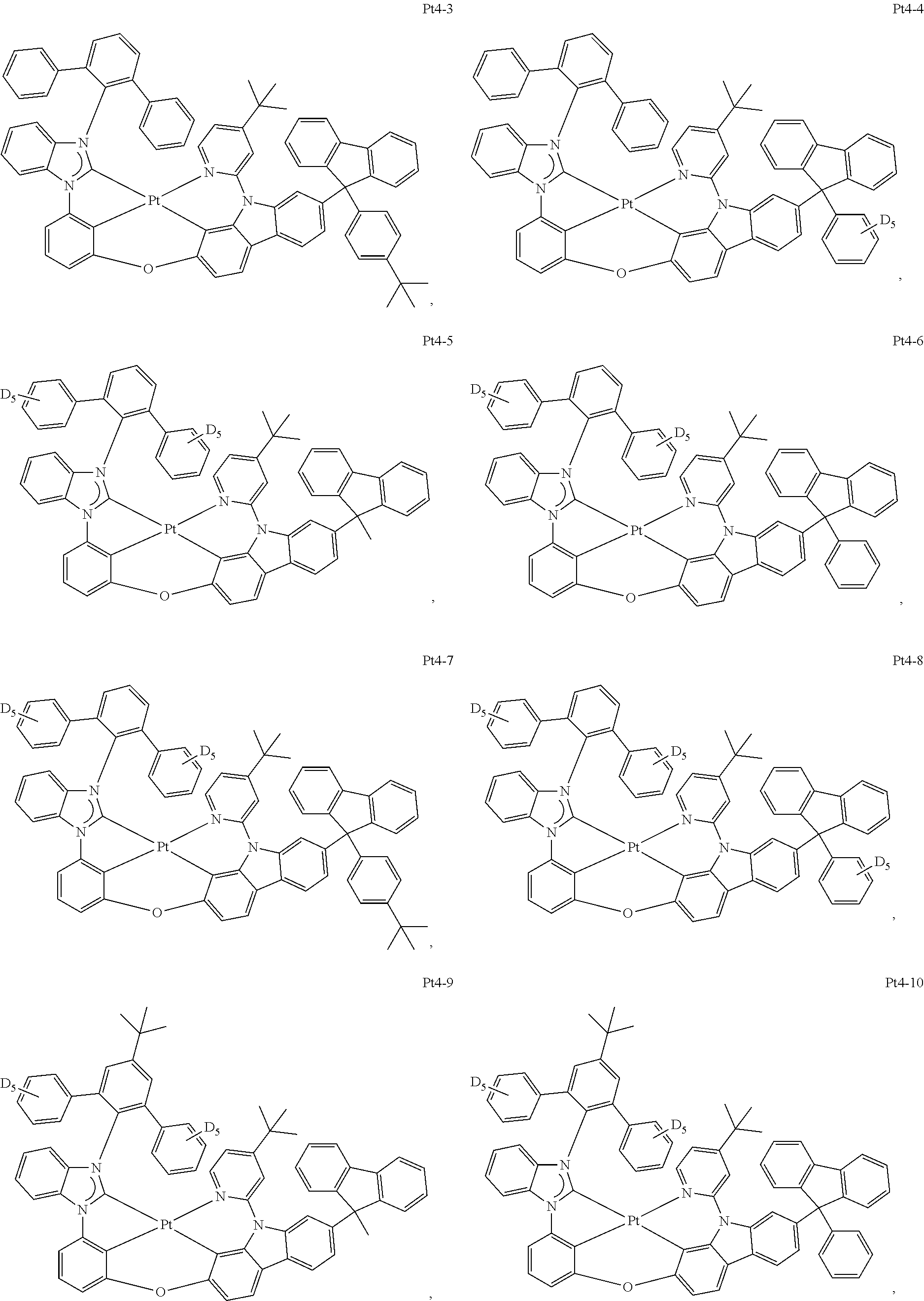

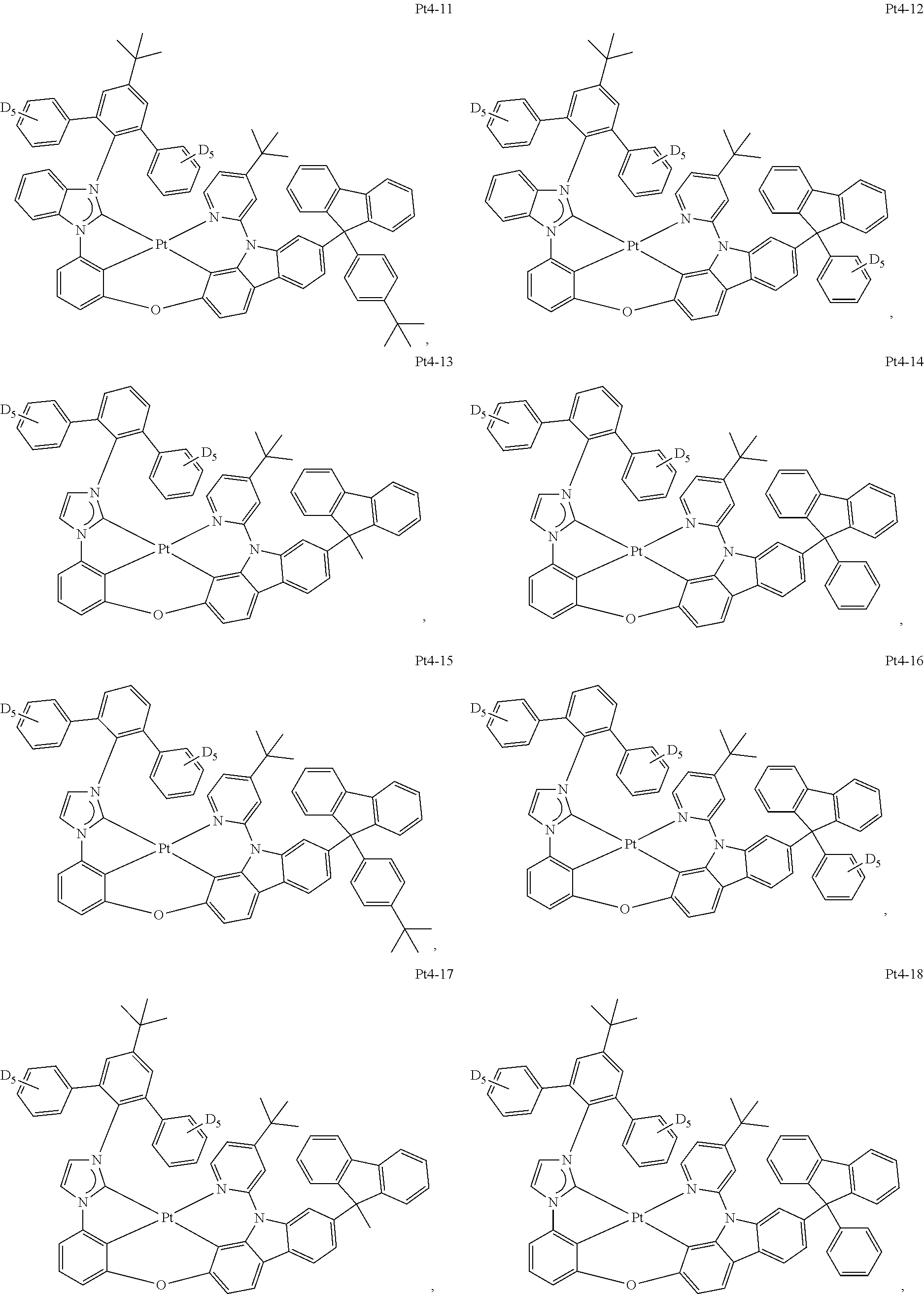

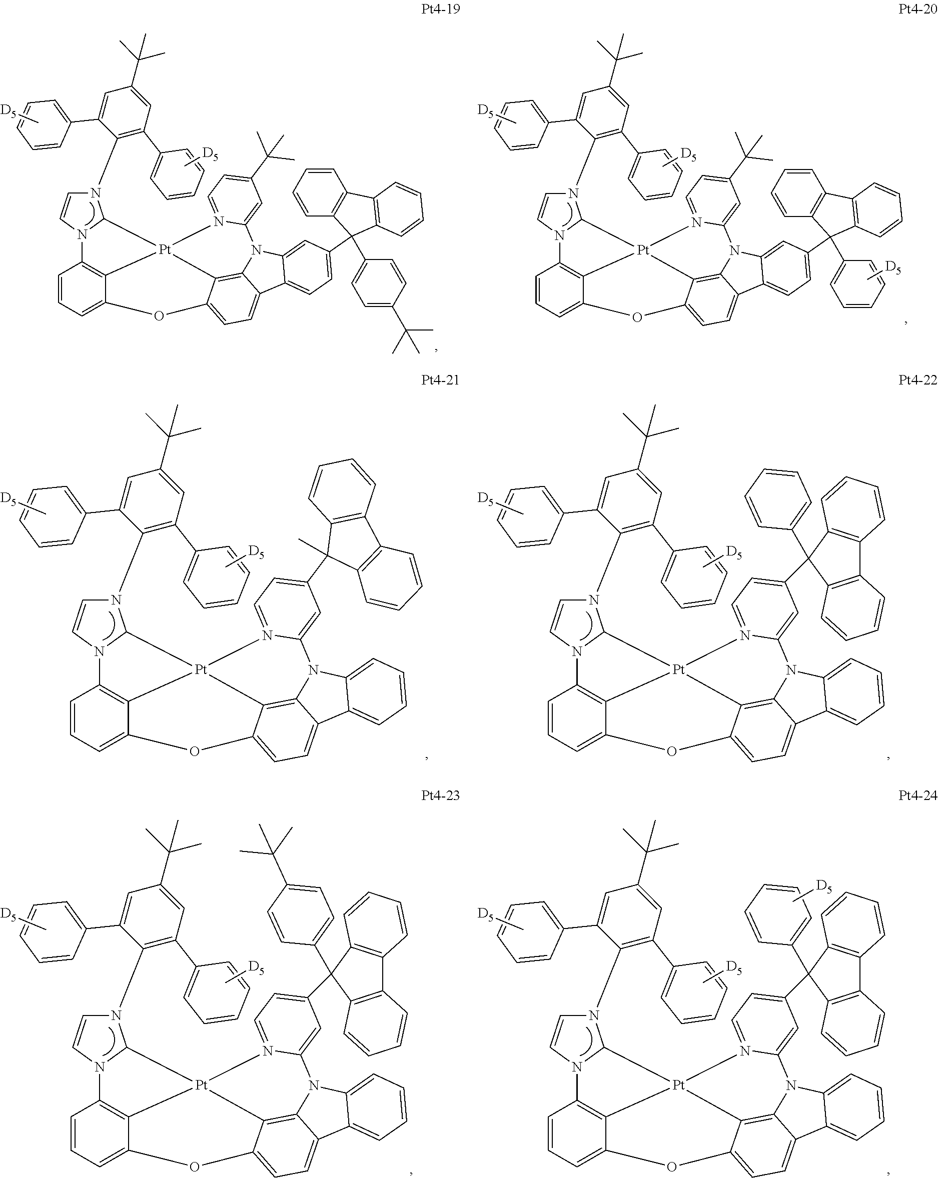

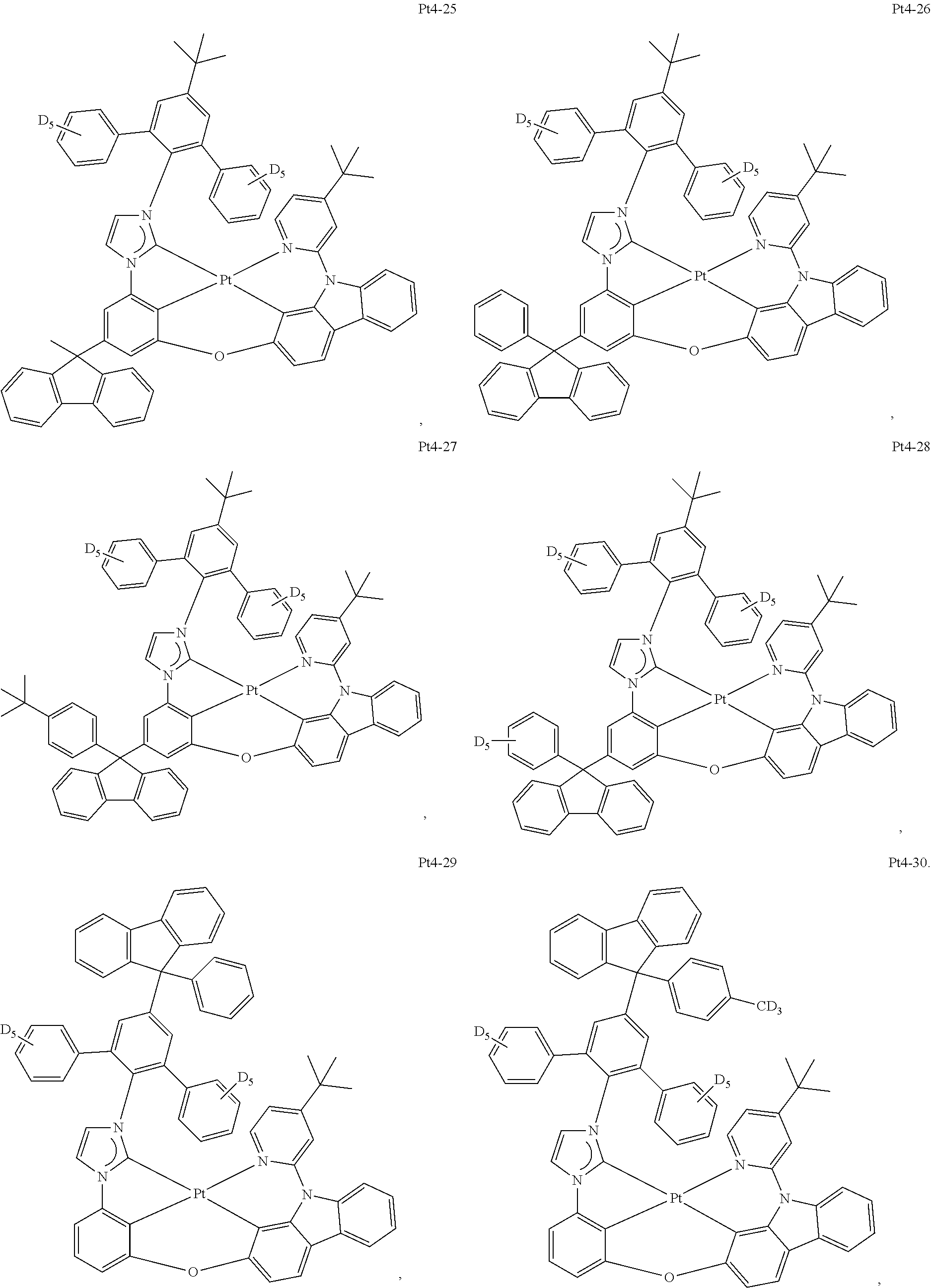

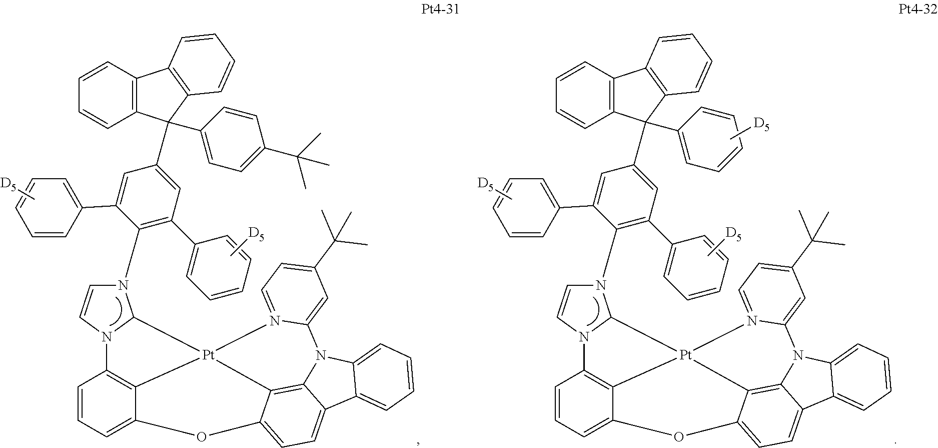

16. An organic electroluminescent device, comprising:
an anode,
a cathode, and
an organic layer disposed between the anode and the cathode, wherein the organic layer comprises the compound of claim 1.

17. The organic electroluminescent device of claim 16, wherein the organic layer is a light-emitting layer and the compound is a light-emitting material.

18. The organic electroluminescent device of claim 16, wherein the device emits blue light or white light.

19. The organic electroluminescent device of claim 17, wherein the light-emitting layer comprises at least one host material; preferably, the light-emitting layer comprises at least two host materials; more preferably, the host material comprises a chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

20. A compound composition, comprising the compound of claim 1.
